(19) United States
(12) Patent Application Publication
(10) Pub. No.: US 2025/0234699 A1
(43) Pub. Date: Jul. 17, 2025

(54) LIGHT-EMITTING DEVICE, AND ELECTRONIC APPARATUS AND ELECTRONIC EQUIPMENT INCLUDING THE LIGHT-EMITTING DEVICE

(71) Applicant: Samsung Display Co., LTD., Yongin-si (KR)

(72) Inventors: Jungho Choi, Yongin-si (KR); Jiyoung Moon, Yongin-si (KR); Kayoung Lee, Yongin-si (KR); Changmin Lee, Yongin-si (KR)

(73) Assignee: Samsung Display Co., LTD., Yongin-si (KR)

(21) Appl. No.: 18/809,701

(22) Filed: Aug. 20, 2024

(30) Foreign Application Priority Data
Jan. 16, 2024 (KR) 10-2024-0006752

(51) Int. Cl. H10K 50/15; H10K 50/17; H10K 59/35; H10K 101/40

(52) U.S. Cl. CPC H10K 50/15; H10K 50/17; H10K 59/35; H10K 2101/40

(57) ABSTRACT

A light-emitting device includes a plurality of subpixels. Each of the plurality of subpixels include a first electrode, a second electrode facing the first electrode, and an interlayer between the first electrode and the second electrode. The interlayer includes an emission layer, a hole injection layer arranged between the first electrode and the emission layer, and a hole transport layer arranged between the hole injection layer and the emission layer. Hole mobility of the hole transport layer is greater than hole mobility of the hole injection layer, and highest occupied molecular orbital (HOMO) energy of the hole transport layer is less than or equal to HOMO energy of the hole injection layer. The HOMO energy is measured by cyclic voltammetry and expressed as a negative number.

### CROSS-REFERENCE TO RELATED APPLICATION(S)

This application claims priority to and benefits of Korean Patent Application No. 10-2024-0006752 under 35 U.S.C. § 119, filed on Jan. 16, 2024, in the Korean Intellectual Property Office (KIPO), the entire contents of which are incorporated herein by reference.

### BACKGROUND

### 1. Technical Field

Embodiments relate to a light-emitting device, and an electronic apparatus and electronic equipment that include the light-emitting device.

### 2. Description of the Related Art

Light-emitting devices are self-emissive devices which have wide viewing angles, high contrast ratios, short response times, and excellent characteristics in terms of luminance, driving voltage, and response speed.

In a light-emitting device, a first electrode is arranged on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as the holes and electrons, recombine in the emission layer to produce excitons. The excitons transition from an excited state to a ground state, thereby generating light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a light-emitting device, and an electronic apparatus and electronic equipment that include the light-emitting device.

Additional aspects will be set forth in part in the description which follows and, in part, will be apparent from the description, or may be learned by practice of the embodiments of the disclosure.

### According to Embodiments,

a light-emitting device may include a plurality of subpixels,
wherein the plurality of subpixels may include a first pixel emitting first light, a second pixel emitting second light, and a third pixel emitting third light,
the first light, the second light, and the third light may have different maximum emission wavelengths from each other,
each of the plurality of subpixels may include
a first electrode,
a second electrode facing the first electrode, and
an interlayer between the first electrode and the second electrode,
the interlayer may include an emission layer, a hole injection layer arranged between the first electrode and the emission layer, and a hole transport layer arranged between the hole injection layer and the emission layer, hole mobility of the hole transport layer may be greater than hole mobility of the hole injection layer, and highest occupied molecular orbital (HOMO) energy of the hole transport layer may be less than or equal to HOMO energy of the hole injection layer. The HOMO energy may be measured by cyclic voltammetry and expressed as a negative number.

In an embodiment, a difference between the HOMO energy of the hole transport layer and the HOMO energy of the hole injection layer may be in a range of about 0 eV to about 0.3 eV.

In an embodiment, a current density of a hole-only device including the hole transport layer and not including the hole injection layer may be lower than a current density of a hole-only device including the hole injection layer and not including the hole transport layer at a same driving voltage.

In an embodiment, the first light may be red light, the second light may be green light, and the third light may be blue light.

In an embodiment, the hole injection layer may further include a p-dopant.

In an embodiment, the emission layer may be separated for each of the plurality of subpixels.

### According to Embodiments,

a light-emitting device may include a plurality of subpixels,
wherein the plurality of subpixels may include a first pixel emitting first light, a second pixel emitting second light, and a third pixel emitting third light,
the first light, the second light, and the third light may have different maximum emission wavelengths from each other,
each of the plurality of subpixels may include
a first electrode,
a second electrode facing the first electrode, and
an interlayer between the first electrode and the second electrode,
the interlayer may include an emission layer, a hole injection layer arranged between the first electrode and the emission layer, and a hole transport layer arranged between the hole injection layer and the emission layer, and
hole mobility of the hole transport layer may be greater than hole mobility of the hole injection layer, and a color crosstalk (CCT) of the light-emitting device may be in a range of 0 to 5, the CCT being calculated by Equation 1:

$$CCT ( \% ) = \frac{{Lum}_{1 + 2 + 3} - ( {Lum}_{1} + {Lum}_{2} + {Lum}_{3} )}{{Lum}_{1 + 2 + 3}} \times 100 \qquad [ Equation 1 ]$$

### In Equation 1,

Lum₁₊₂₊₃ may be a luminance of white light of a specific gradation in case that all of the first pixel, the second pixel, and the third pixel emit light so that the light-emitting device emits the white light of the specific gradation, wherein the first pixel emits the first light having a first luminance under a first driving condition, the second pixel emits the second light having a second luminance under a second driving condition, and the third pixel emits the third light having a third luminance under a third driving condition,

Lum₁ may be a luminance of the first light emitted by the light-emitting device in case that the second pixel and the third pixel do not emit light and the first pixel emits light under the first driving condition,

Lum₂ may be a luminance of the second light emitted by the light-emitting device in case that the first pixel and the third pixel do not emit light and the second pixel emits light under the second driving condition, and

Lum₃ may be a luminance of the third light emitted by the light-emitting device in case that the first pixel and the second pixel do not emit light and the third pixel emits light under the third driving condition.

In an embodiment, the specific gradation may be one of a first gradation level to a tenth gradation level among 256 gradation levels.

In an embodiment, the white light may have a luminance in a range of about 0.2 nit to about 0.6 nit at the specific gradation.

In an embodiment, the light-emitting device may have a resolution in a range of about 100 pixels per inch (PPI) to about 1,000 PPI.

In an embodiment, HOMO energy of the hole transport layer may be less than or equal to HOMO energy of the hole injection layer. The HOMO energy may be measured by cyclic voltammetry and expressed as a negative number.

In an embodiment, the interlayer may further include
m emitting units that are stacked each other, and
m−1 charge generation units each arranged between adjacent ones of the m emitting units,
m may be an integer of 2 or more,
a first emitting unit to an m^{th} emitting unit may be sequentially stacked from a side of the first electrode,
a first charge generation unit to an m−1^{th} charge generation unit may be sequentially stacked from the side of the first electrode,
the first emitting unit may include the emission layer, the hole injection layer, and the hole transport layer,
each of the first charge generation unit to the m−1^{th} charge generation unit may include a p-type charge generation layer and an n-type charge generation layer, and
the light-emitting device may further include a color conversion unit on the second electrode.
In an embodiment, a second emitting unit to the m^{th} emitting unit may include a second hole transport layer to an m^{th} hole transport layer, respectively,
the p-type charge generation layers of the first charge generation unit to the m−1^{th} charge generation unit may be in direct contact with the second hole transport layer to the m^{th} hole transport layer, respectively, and
hole mobility of each of the second hole transport layer to the m^{th} hole transport layer may be greater than hole mobility of each of the p-type charge generation layers, and
HOMO energy of each of the second hole transport layer to the m^{th} hole transport layer may be less than or equal to HOMO energy of each of the p-type charge generation layers.

### According to Embodiments,

a light-emitting device may include a plurality of subpixels,
wherein the plurality of subpixels may include a first pixel emitting first light, a second pixel emitting second light, and a third pixel emitting third light,
the first light, the second light, and the third light may have different maximum emission wavelengths from each other,
each of the plurality of subpixels may include
a first electrode,
a second electrode facing the first electrode,
an interlayer between the first electrode and the second electrode, and
a color conversion unit on the second electrode,
wherein the interlayer may include
m emitting units that are stacked each other, and
m−1 charge generation units each arranged between adjacent ones of the m emitting units,
m may be an integer of 2 or more,
a first emitting unit to an m^{th} emitting unit may be sequentially stacked from a side of the first electrode,
a first charge generation unit to an m−1^{th} charge generation unit may be sequentially stacked from the side of the first electrode,
the first emitting unit to the m^{th} emitting unit may include a first hole transport layer to an m^{th} hole transport layer, respectively,
each of the first charge generation unit to the m−1^{th} charge generation unit may include a p-type charge generation layer and an n-type charge generation layer,
the p-type charge generation layers of the first charge generation unit to the m−1^{th} charge generation unit may be in direct contact with the second hole transport layer to the m^{th} hole transport layer, respectively, and
hole mobility of each of the second hole transport layer to the m^{th} hole transport layer may be greater than hole mobility of each of the p-type charge generation layers, and
HOMO energy of each of the second hole transport layer to the m^{th} hole transport layer may be less than or equal to HOMO energy of each of the p-type charge generation layers.

In an embodiment, a color crosstalk (CCT) of the light-emitting device may be in a range of 0 to 5, the CCT being calculated by Equation 1:

$$CCT ( \% ) = \frac{{Lum}_{1 + 2 + 3} - ( {Lum}_{1} + {Lum}_{2} + {Lum}_{3} )}{{Lum}_{1 + 2 + 3}} \times 100 \qquad [ Equation 1 ]$$

### In Equation 1,

Lum₁₊₂₊₃, Lum₁, Lum₂, and Lum₃ are each as defined herein.

In an embodiment, at least one of the m emitting units may emit light having a maximum emission wavelength in a range of about 410 nm to about 490 nm.

In an embodiment, at least one of the m emitting units may emit light having a maximum emission wavelength in a range of about 490 nm to about 580 nm.

In an embodiment, m may be 4, for example, the light-emitting device may include four emitting units,
three of the m emitting units may emit light having a maximum emission wavelength in a range of about 410 nm to about 490 nm, and
one of the m emitting units may emit light having a maximum emission wavelength in a range of about 490 nm to about 580 nm.

According to embodiments, an electronic apparatus may include the light-emitting device.

In an embodiment, the electronic apparatus may further include a thin-film transistor,
the thin-film transistor may include a source electrode and a drain electrode, and
the first electrode of the light-emitting device may be electrically connected to at least one of the source electrode and the drain electrode of the thin-film transistor.

According to embodiments, electronic equipment may include the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view illustrating a structure of a light-emitting device according to an embodiment;

FIG. 2 is a schematic cross-sectional view illustrating a structure of a light-emitting device according to an embodiment;

FIG. 3 is a schematic cross-sectional view illustrating a structure of a light-emitting device according to an embodiment;

FIG. 4 is a schematic cross-sectional view illustrating a structure of an electronic apparatus according to an embodiment;

FIG. 5 is a schematic cross-sectional view illustrating a structure of an electronic apparatus according to an embodiment;

FIGS. 6, 7, 8A, 8B, and 8C are each a schematic view illustrating the structure of electronic equipment according to an embodiment;

FIG. 9 is a current density versus voltage graph measured for hole-only devices including Compounds A and B;

FIG. 10 is a current density versus voltage graph measured for hole-only devices including Compounds C, D, and E;

FIG. 11 is a graph showing ranges of specific resistance converted from lateral current measured for test patterns of Example 1 and Comparative Example 1;

FIG. 12 is a graph showing ranges of specific resistance converted from lateral current measured for test patterns of Example 2 and Comparative Example 2;

FIG. 13 is a graph showing ranges of specific resistance converted from lateral current measured for test patterns of Example 3 and Comparative Example 3; and

FIG. 14 is a graph showing ranges of specific resistance converted from lateral current measured for test patterns of Example 4 and Comparative Example 4.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

Hereinafter, embodiments will be described in detail with reference to the accompanying drawings. Like reference numerals in the drawings refer to like components, and redundant descriptions thereof will be omitted. Sizes of components in the drawings may be exaggerated for clarity and convenience of explanation. The embodiments described below are merely illustrative, and various modifications may be made to these embodiments.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

The term “interlayer” as used herein refers to a single layer and/or all of a plurality of layers arranged between a first electrode and a second electrode, or between an anode and a cathode, of a light-emitting device.

The term “common layer” as used herein refers to a layer that extends horizontally in a stacked structure of a light-emitting device and is shared with adjacent pixels. Layers of a charge transport region, such as a hole injection layer, a hole transport layer, an electron transport layer, an electron injection layer, an electron blocking layer, and a hole blocking layer, and a second electrode may be formed as a common layer. An emission layer may be separated for each subpixel to emit different colors, or may be formed as a common layer emitting the same color.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

### A Light-Emitting Device According to an Embodiment May Include

multiple subpixels,
wherein the subpixels may include a first pixel emitting first light, a second pixel emitting second light, and a third pixel emitting third light,
the first light, the second light, and the third light may have different maximum emission wavelengths from each other,
each of the subpixels may include:
a first electrode;
a second electrode facing the first electrode; and
an interlayer between the first electrode and the second electrode, and
the interlayer may include: an emission layer, a hole injection layer arranged between the first electrode and the emission layer; and a hole transport layer arranged between the hole injection layer and the emission layer.

The first electrode may be separated for each subpixel.

The light-emitting device may satisfy Conditions i and ii:

### Condition i

the hole mobility of the hole transport layer may be greater than the hole mobility of the hole injection layer; and

### Condition ii

the highest occupied molecular orbital (HOMO) energy of the hole transport layer may be less than or equal to the HOMO energy of the hole injection layer, wherein the HOMO energy is measured by cyclic voltammetry and expressed as a negative number.

In case that the light-emitting device is driven, holes (h+) may be injected from the first electrode, may move to the emission layer through the hole injection layer and the hole transport layer, and may be recombined in the emission layer with electrons injected from the second electrode, thereby generating light. In order for adjacent pixels to operate independently from each other, holes injected from the first electrode may move only in a vertical direction (toward the emission layer). However, since the hole injection layer and the hole transport layer are formed as a common layer, holes injected from the first electrode may also move in a horizontal direction, and horizontal movement components of the holes may form lateral leakage current to adjacent pixels. As the resolution increases, a gap between pixels, for example, a gap between first electrodes, may decrease, and the lateral leakage current may increase. In case that lateral leakage current occurs, there may be a difference in luminance, resulting in a decrease in color gamut reproducibility and/or efficiency.

In the embodiment, provided is a method of further improving vertical movement of holes to reduce lateral leakage current, and to this end, the hole transport layer has higher hole mobility than the hole injection layer. In case that the hole mobility of the hole transport layer is higher than the hole mobility of the hole injection layer, the resistance of the hole transport layer may be lower than the resistance of the hole injection layer, and thus, vertical movement of holes from the first electrode to the emission layer, for example, vertical current, may be improved, and horizontal lateral leakage current may be reduced or eliminated.

In an embodiment, since the HOMO energy of the hole transport layer is between the HOMO level of the hole injection layer and the HOMO level of the emission layer, the energy barrier for injection of holes from the hole injection layer to the emission layer may be lowered. For example, the HOMO level of the hole transport layer may be lower than or equal to the HOMO level of the hole injection layer. For example, the difference between the HOMO level of the hole injection layer and the HOMO level of the hole transport layer may be in a range of about 0 eV to 0.3 eV. For example, in case that the HOMO level of the hole transport layer is −5.3 eV, the HOMO level of the hole injection layer may be in a range of about −5.0 eV to about −5.3 eV.

Table 1 shows the hole mobility and HOMO level of some hole transport compounds. The HOMO energy is measured by cyclic voltammetry and expressed as a negative number. For example, in case that a compound of the hole injection layer is 2-TNATA, TAPC, which has higher hole mobility than 2-TNATA and lower HOMO level than 2-TNATA, may be used as a compound of the hole transport layer.

TABLE 1

| Compound | Hole mobility (V · s/cm²) | HOMO (eV) |
|---|---|---|
| TAPC | 2.45 × 10⁻³ | −5.5 |
| 2-TNATA | 6.40 × 10⁻⁵ | −5.1 |
| NPB | 2.18 × 10⁻⁴ | −5.4 |
| TPD | 1.40 × 10⁻³ | −5.4 |
| TBBD | 1.74 × 10⁻² | −5.3 |

The compounds in Table 1 are provided for comparison of hole mobility and HOMO energy, and compounds that may be used in the hole injection layer and hole transport layer of the light-emitting device are not limited to the compounds shown in Table 1. In an embodiment, the compounds of the hole injection layer and the hole transport layer may be selected from compounds that may be included in a hole transport region described herein, to satisfy the conditions of hole mobility and/or HOMO level described above.

The hole mobility relationship between the hole transport layer and the hole injection layer may be inferred by comparing graphs of current density versus driving voltage obtained for hole-only devices including the hole transport layer or the hole injection layer. A graph of current density versus driving voltage shows a J shape in which the current density gradually increases as the driving voltage increases, and the amount of increase in current density increases from a certain voltage.

In an embodiment, a current density of a hole-only device including the hole transport layer may be lower than a current density of a hole-only device including the hole injection layer at a same driving voltage. For example, a current density of a hole-only device including the hole transport layer and not including the hole injection layer may be lower than a current density of a hole-only device including the hole injection layer and not including the hole transport layer at a same driving voltage. At a same driving voltage, the current density of the hole-only device including the hole transport layer may be greater than the current density of the hole-only device including the hole injection layer, and from this, it may be inferred that the hole transport layer may have greater hole mobility than the hole injection layer. It may be also inferred that the hole transport layer may have a lower resistance than the hole injection layer.

In an embodiment, the hole transport layer may further include a p-dopant. Details on the p-dopant are the same as described herein.

In an embodiment, the thickness of the hole injection layer may be in a range of about 10 Å to about 100 Å. For example, the thickness of the hole injection layer may be in a range of about 20 Å to about 80 Å. For example, the thickness of the hole injection layer may be in a range of about 30 Å to about 70 Å. In an embodiment, the thickness of the hole transport layer may be in a range of about 100 Å to about 700 Å. For example, the thickness of the hole transport layer may be in a range of about 150 Å to about 650 Å. For example, the thickness of the hole transport layer may be in a range of about 200 Å to about 600 Å.

### A Light-Emitting Device According to an Embodiment May Include

multiple subpixels,
wherein the subpixels may include a first pixel emitting first light, a second pixel emitting second light, and a third pixel emitting third light,
the first light, the second light, and the third light may have different maximum emission wavelengths from each other,
each of the subpixels may include:
a first electrode;
a second electrode facing the first electrode; and
an interlayer between the first electrode and the second electrode,
the interlayer may include: an emission layer; a hole injection layer arranged between the first electrode and the emission layer; and a hole transport layer arranged between the hole injection layer and the emission layer, and

### Conditions i and iii May be Satisfied:

### Condition i

the hole mobility of the hole transport layer may be greater than the hole mobility of the hole injection layer; and

### Condition iii

the color crosstalk (CCT) of the light-emitting device may be in a range of 0 to 5, the CCT being calculated by Equation 1:

$$CCT ( \% ) = \frac{{Lum}_{1 + 2 + 3} - ( {Lum}_{1} + {Lum}_{2} + {Lum}_{3} )}{{Lum}_{1 + 2 + 3}} \times 100 \qquad [ Equation 1 ]$$

### In Equation 1,

Lum₁₊₂₊₃ may be a luminance of white light of a specific gradation in case that all of the first pixel, the second pixel, and the third pixel emit light so that the light-emitting device emits the white light of the specific gradation, wherein the first pixel emits the first light having a first luminance under a first driving condition, the second pixel emits the second light having a second luminance under a second driving condition, and the third pixel emits the third light having a third luminance under a third driving condition,

Lum₁ may be a luminance of the first light emitted by the light-emitting device in case that the second pixel and the third pixel do not emit light and the first pixel emits light under the first driving condition,

Lum₂ may be a luminance of the second light emitted by the light-emitting device in case that the first pixel and the third pixel do not emit light and the second pixel emits light under the second driving condition, and

Lum₃ may be a luminance of the third light emitted by the light-emitting device in case that the first pixel and the second pixel do not emit light and the third pixel emits light under the third driving condition.

Condition i may be the same as described herein.

The light-emitting device according to an embodiment may have enhanced vertical component current from the first electrode and a color crosstalk (CCT) value, expressed by Equation 1, of less than 5. The CCT may be obtained from the difference between the luminance of white light, which is emitted in case that all pixels of the light-emitting device emit light, and the sum of respective luminances of lights of specific colors, which are mixed to form the white light, in case that only pixels of the specific colors emit light. It is expected that the smaller the CCT, which is the difference between the luminance of white light and the sum of the luminances of lights of individual colors, the smaller the lateral leakage current between pixels.

In order for the light-emitting device to emit white light, respective pixels of the light-emitting device may emit light of colors that form the white light. For example, the first pixel may be a red pixel, the second pixel may be a green pixel, the third pixel may be a blue pixel, the first light may be red light, the second light may be green light, and the third light may be blue light. In another embodiment, mixed light of the first light, the second light, and the third light may be white light, wherein each light may have a different color from red light, green light, or blue light.

In case that Lum₁₊₂₊₃ in Equation 1 is a luminance of white light at a specific gradation and the light-emitting device emits white light having the above luminance, a driving condition of the first pixel, a driving condition of the second pixel, and a driving condition of the third pixel may be different, and contributions of respective colors in forming the white light may also be different. The driving condition of each pixel may include, for example, driving voltage or driving current. In case that white light is emitted, the driving condition under which the light-emitting device of the first pixel emits light may be also the driving condition that the light-emitting device of the second pixel and the third pixel emit light. Lum₁ may be a luminance of the first light emitted from the first pixel under the above driving condition but with the second pixel and the third pixel off in calculating the CCT. Lum₂ and Lum₃ may be defined in the same manner as Lum₁.

In case that lateral leakage current exists, under the same driving condition (driving voltage or driving current), the luminance of the first light in white light, which is emitted in case that the first pixel and pixels of other colors all emit light, may be different from the luminance of the first light in case that the first pixel is driven alone and the pixels of other colors do not emit light. Like the first light, the luminance of each of the second light and the third light in case that each of the second pixel and the third pixel is driven alone under the same driving condition as that in white light may be different from the luminance of each of the second light and the third light in the white light. Under the same driving condition, in case that the luminance of each of the first light, the second light, and the third light in the white light is different from the luminance of each of the first light, the second light, and the third light alone, the CCT may not be 0, and as the difference in luminance increases, the value of CCT may increase.

As described above, Lum₁₊₂₊₃ may be a luminance of white light of a specific gradation, which is emitted by the light-emitting device. A gradation may be a degree to which a gradual change in brightness is expressed in levels. For example, a lower gradation among all gradations may be rendered darker and may be a lower luminance. For example, the CCT expressed by Equation 1 with respect to the luminance of one of a first gradation to a tenth gradation, or one of the first gradation to the fifth gradation, among gradations of 256 levels, may be in a range of 0 to 5, in a range of 0 to 4, or in a range of 0 to 3. For example, the CCT expressed by Equation 1 with respect to the luminance of the fourth gradation among the gradations of 256 levels may be in a range of 0 to 5, in a range of 0 to 4, or in a range of 0 to 3. In another embodiment, the CCT expressed by Equation 1 with respect to white light having a luminance in a range of about 0.1 nit to about 1.0 nit, about 0.1 nit to about 0.8 nit, or about 0.2 nit to about 0.6 nit, which is emitted by the light-emitting device, may be in a range of 0 to 5, in a range of 0 to 4, or in a range of 0 to 3.

In an embodiment, the light-emitting device may have a resolution in a range of about 100 pixels per inch (PPI) to about 1,000 PPI. For example, the light-emitting device may have a resolution in a range of about 100 PPI to about 500 PPI. For example, the light-emitting device may have a resolution in a range of about 120 PPI to about 300 PPI. For example, the light-emitting device may have a resolution in a range of about 140 PPI to about 200 PPI.

The light-emitting device may further satisfy Condition ii as described above. For example, the HOMO energy of the hole transport layer may be less than or equal to the HOMO energy of the hole injection layer.

In an embodiment, the first light may be red light, the second light may be green light, and the third light may be blue light.

In an embodiment, the emission layer may be separated for each subpixel. For example, the interlayer of the light-emitting device may include only one emitting unit.

In an embodiment, the interlayer may include multiple stacked emitting units, and charge generation units between adjacent emitting units, and the light-emitting device may be a tandem light-emitting device. Each of the emitting units may include a hole transport region, an emission layer, and an electron transport region, and each of the charge generation units may include a p-type charge generation layer and an n-type charge generation layer.

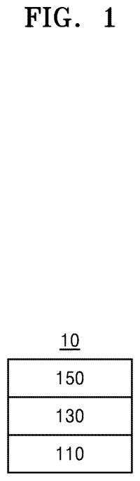

### [Description of FIG. 1]

FIG. 1 is a schematic cross-sectional view of a light-emitting device 10 according to an embodiment. The light-emitting device 10 may include a first electrode 110, an interlayer 130, and a second electrode 150.

Hereinafter, the structure of the light-emitting device 10 according to an embodiment and a method of manufacturing the light-emitting device 10 are described with reference to FIG. 1.

### [First Electrode 110]

In FIG. 1, a substrate may be further included under the first electrode 110 or on the second electrode 150. In an embodiment, the substrate may be a glass substrate or a plastic substrate. In an embodiment, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. In case that the first electrode 110 is an anode, a material for forming the first electrode 110 may be a high-work function material that facilitates the injection of holes.

The first electrode 110 may be a reflective electrode, a transflective electrode, or a transmissive electrode. In case that the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In an embodiment, in case that the first electrode 110 is a transflective electrode or a reflective electrode, a material for forming the first electrode 110 may include magnesium (Mg), silver (Ag), aluminum (AI), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. In an embodiment, the first electrode 110 may have a three-layer structure of ITO/Ag/ITO.

### [Interlayer 130]

The interlayer 130 may be arranged on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include, in addition to various organic materials, a metal-containing compound such as an organometallic compound, an inorganic material such as quantum dots, or the like.

In an embodiment, the interlayer 130 may include two or more emitting units stacked between the first electrode 110 and the second electrode 150, and at least one charge generation unit arranged between the two adjacent emitting units. In case that the interlayer 130 includes the two or more emitting units and at least one charge generation unit as described above, the light-emitting device 10 may be a tandem light-emitting device.

### [Hole Transport Region in Interlayer 130]

The hole transport region may include a hole injection layer, a hole transport layer, an emission auxiliary layer, an electron blocking layer, or any combination thereof.

In an embodiment, the hole transport region may have a multi-layer structure including a hole injection layer/hole transport layer structure, a hole injection layer/hole transport layer/emission auxiliary layer structure, or a hole injection layer/hole transport layer/electron blocking layer structure, wherein constituent layers of each structure may be stacked from the first electrode 110 in its respective stated order, but the structure of the hole transport region is not limited thereto.

The hole transport region may include a compound represented by Formula 201, a compound represented by Formula 202, or any combination thereof:

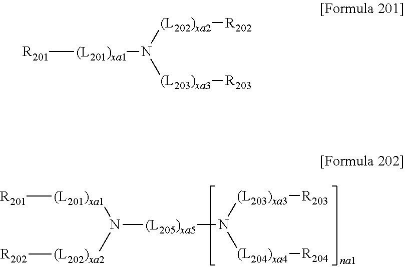

### In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, etc.) unsubstituted or substituted with at least one R₁₀ₐ (e.g., Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In an embodiment, of the compound represented by Formula 201 and the compound represented by Formula 202 may each independently include at least one of groups represented by Formulae CY201 to CY217:

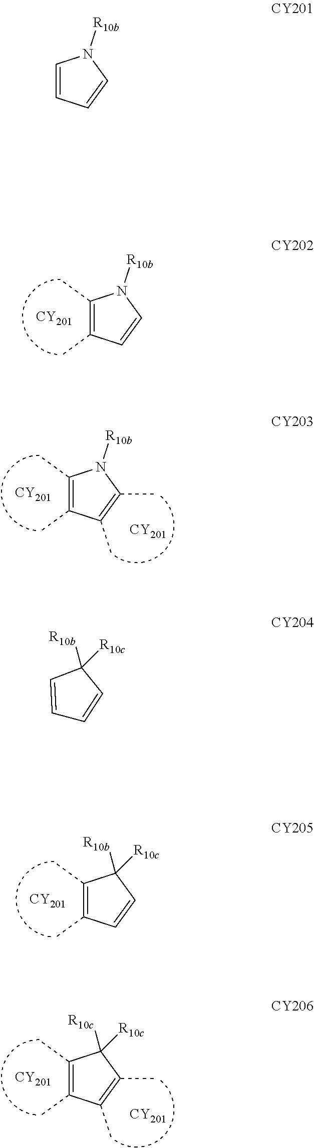

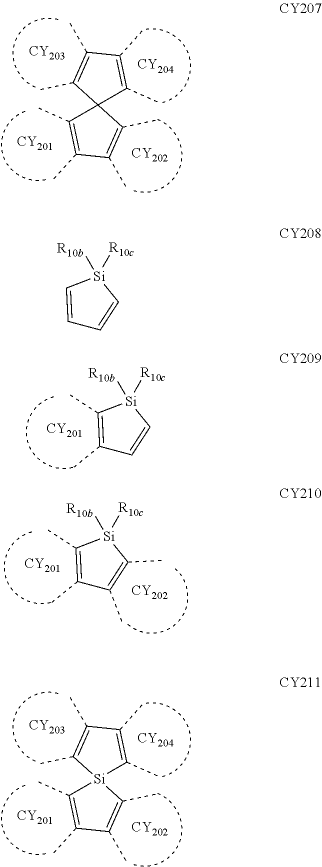

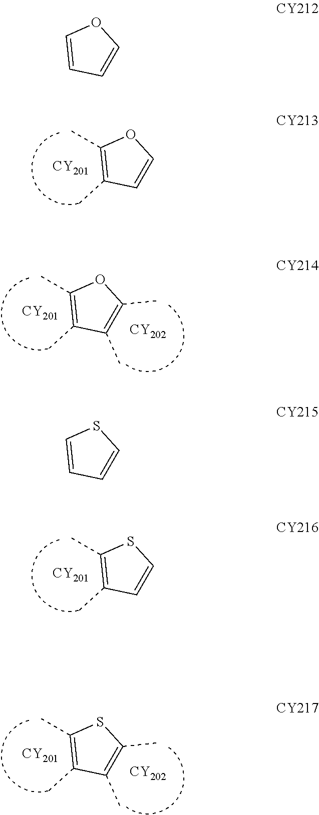

In Formulae CY201 to CY217, R_{10b} and R_{10c} may each be independently the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY201 to ring CY204 may each independently be a benzene group, a naphthalene group, a phenanthrene group, or an anthracene group.

In an embodiment, the compound represented by Formula 201 and the compound represented by Formula 202 may each independently include at least one of groups represented by Formulae CY201 to CY203.

In an embodiment, the compound represented by Formula 201 may include at least one of groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, the compound represented by Formula 201 and the compound represented by Formula 202 may each not include groups represented by Formulae CY201 to CY203.

In an embodiment, the compound represented by Formula 201 and the compound represented by Formula 202 may each not include groups represented by Formulae CY201 to CY203, and may each independently include at least one of groups represented by Formulae CY204 to CY217.

In an embodiment, of the compound represented by Formula 201 and the compound represented by Formula 202 may each not include groups represented by Formulae CY201 to CY217.

In an embodiment, the hole transport region may include: one of Compounds HT1 to HT46; m-MTDATA; TDATA; 2-TNATA; NPB(NPD); β-NPB; TPD; spiro-TPD; spiro-NPB; methylated NPB; TCPC; TAPC; HMTPD; 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate)(PANI/PSS); or any combination thereof:

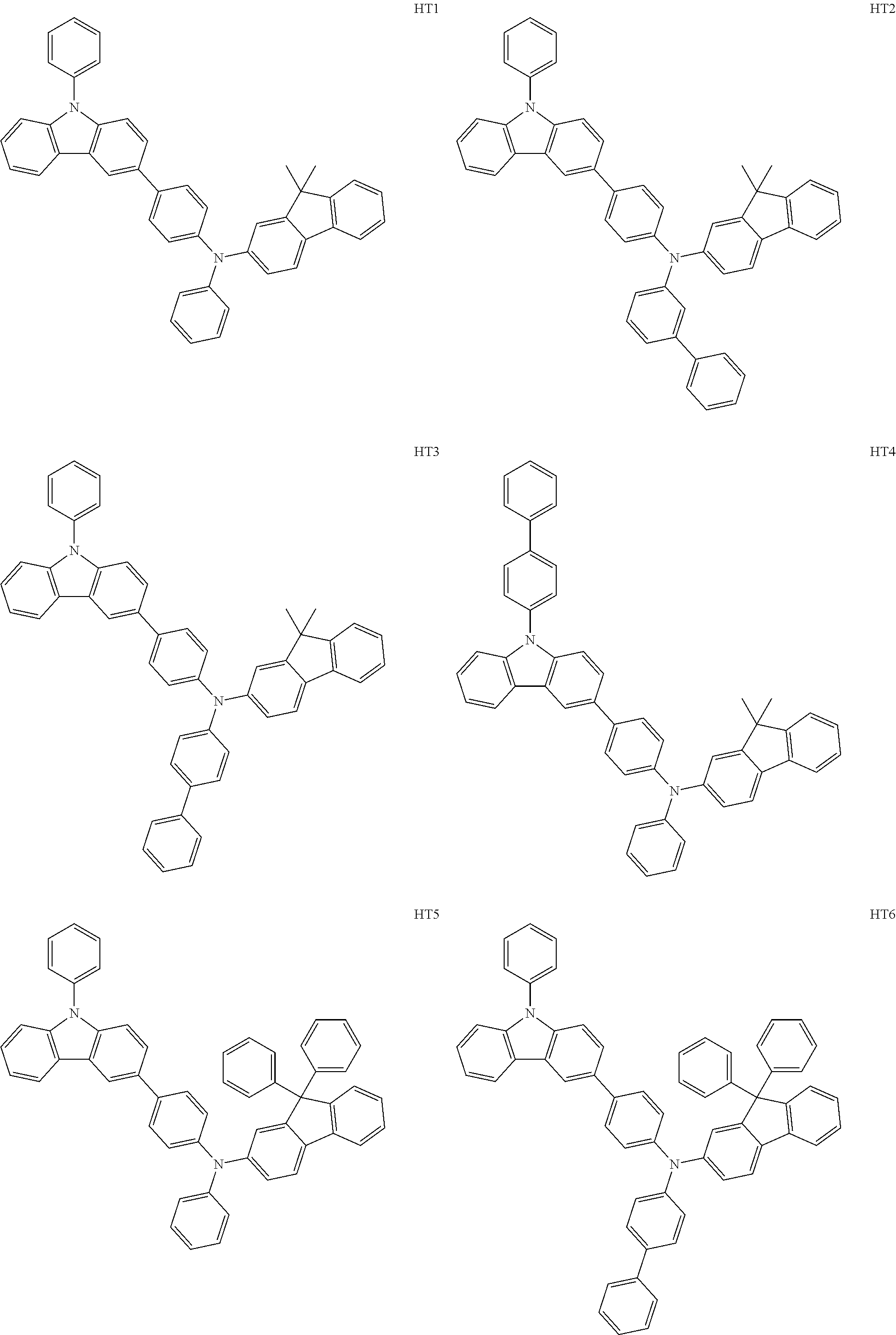

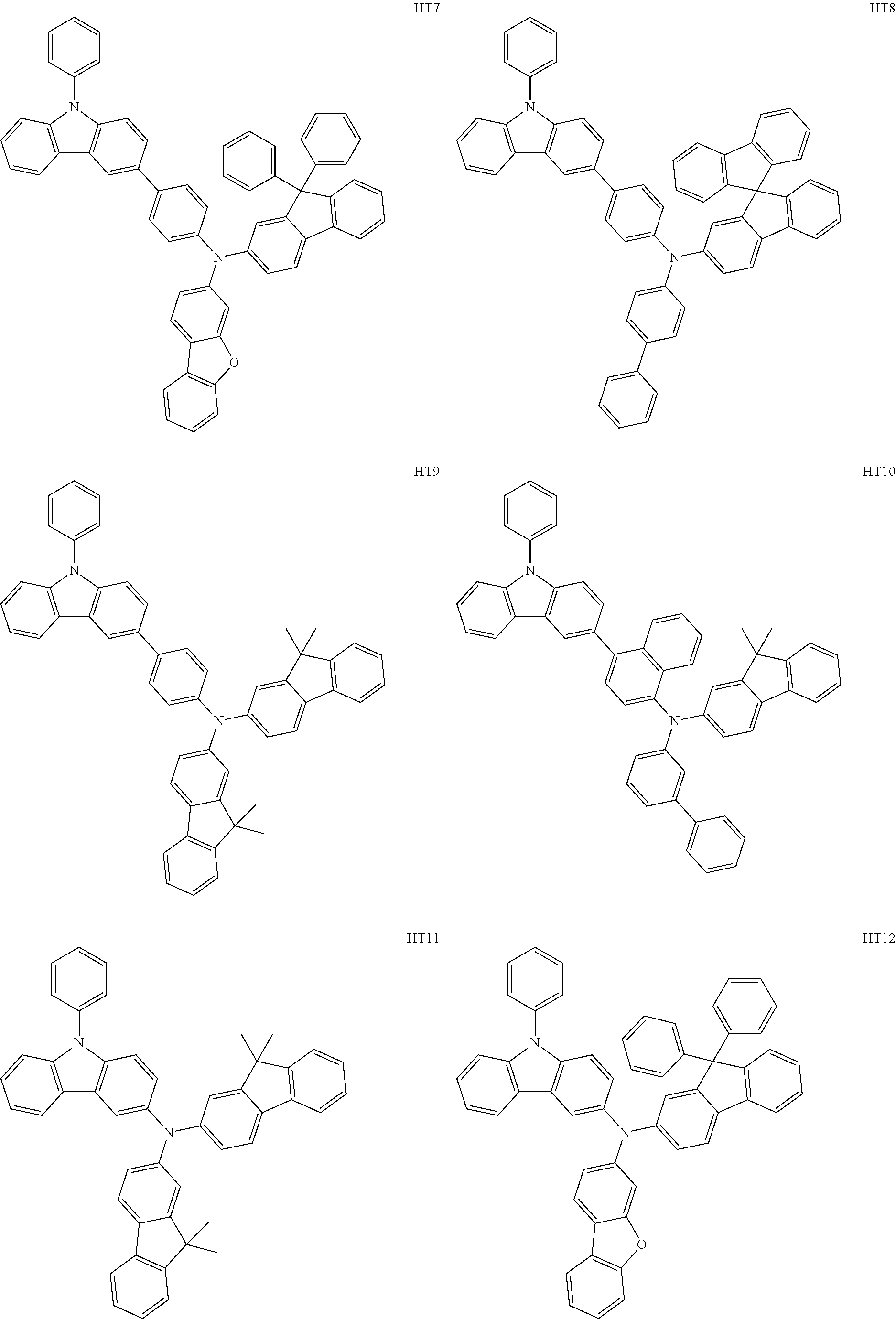

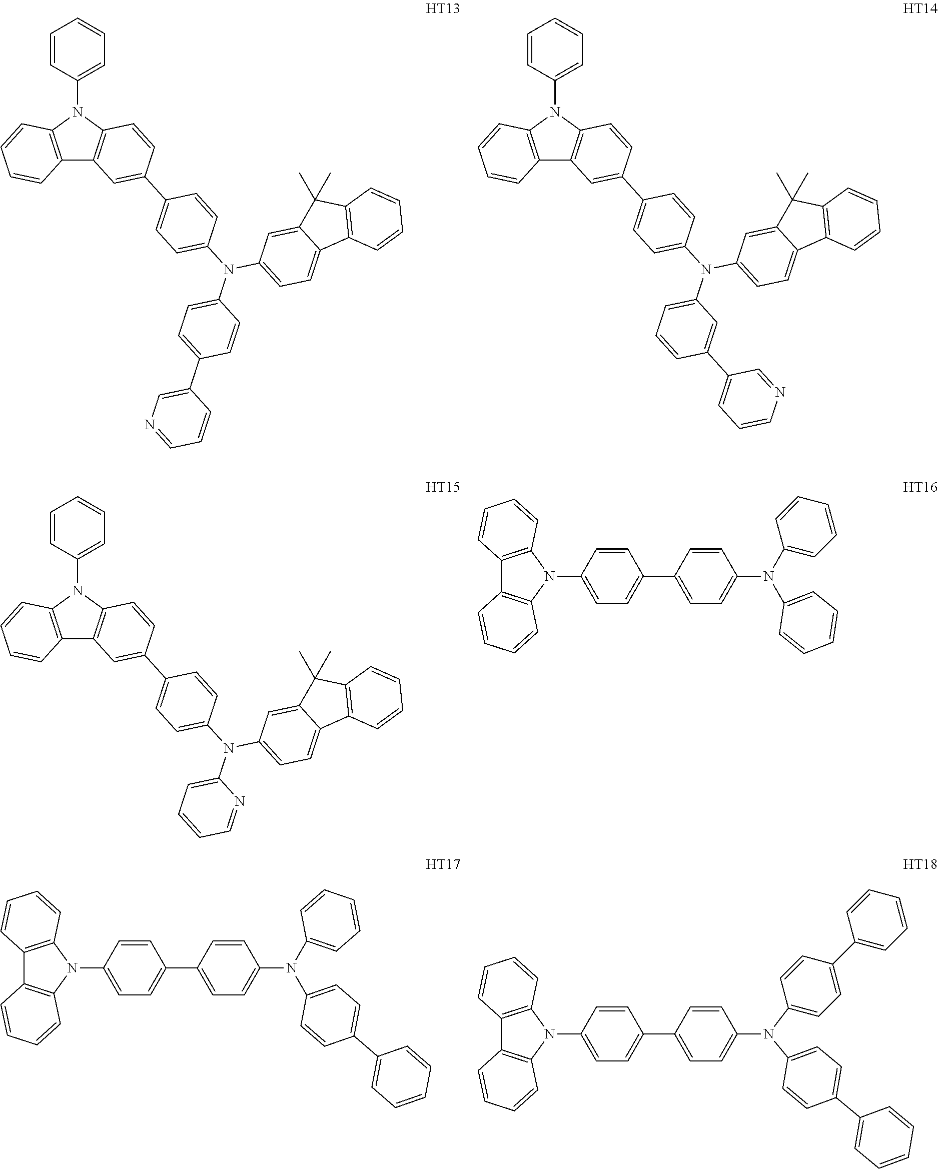 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

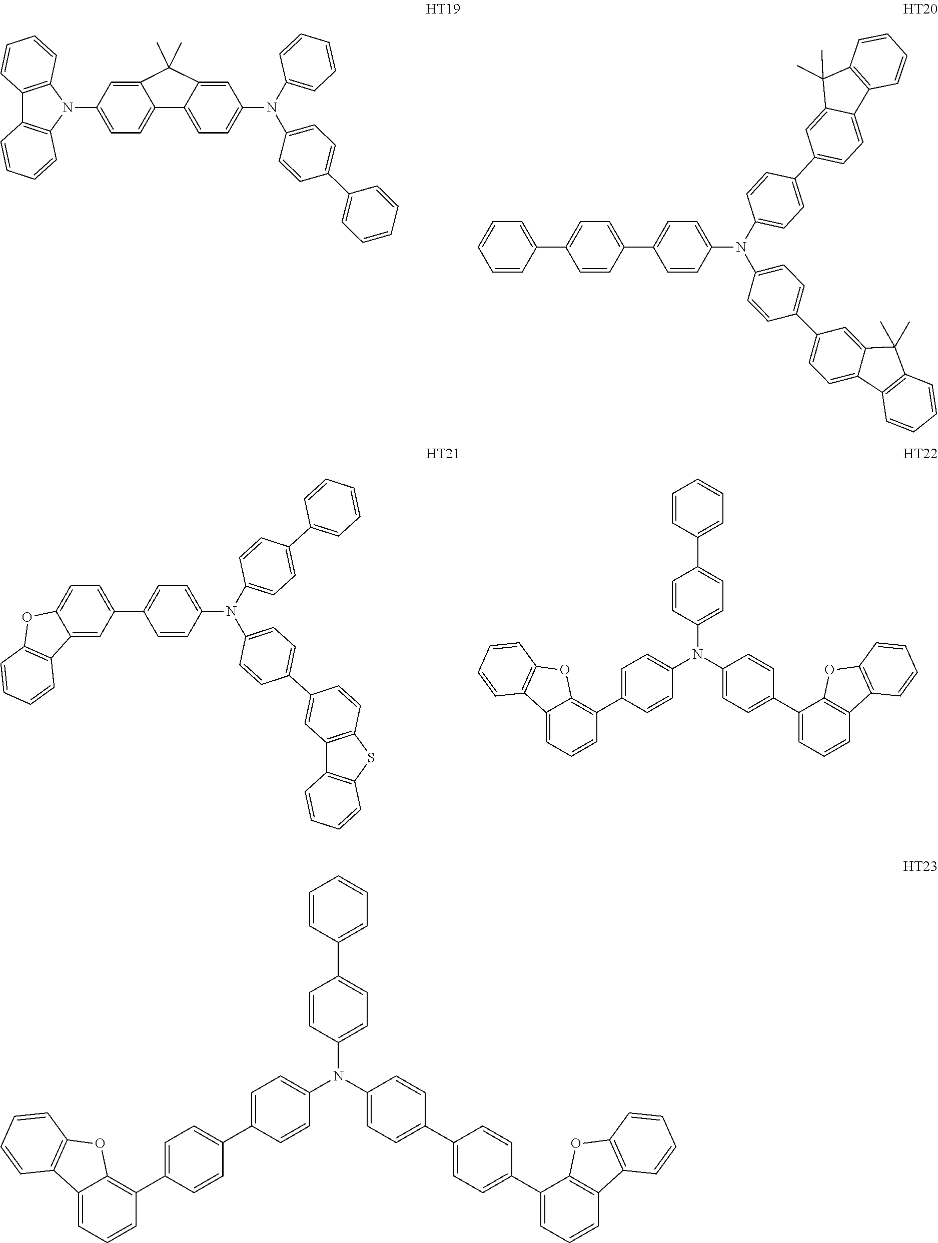 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

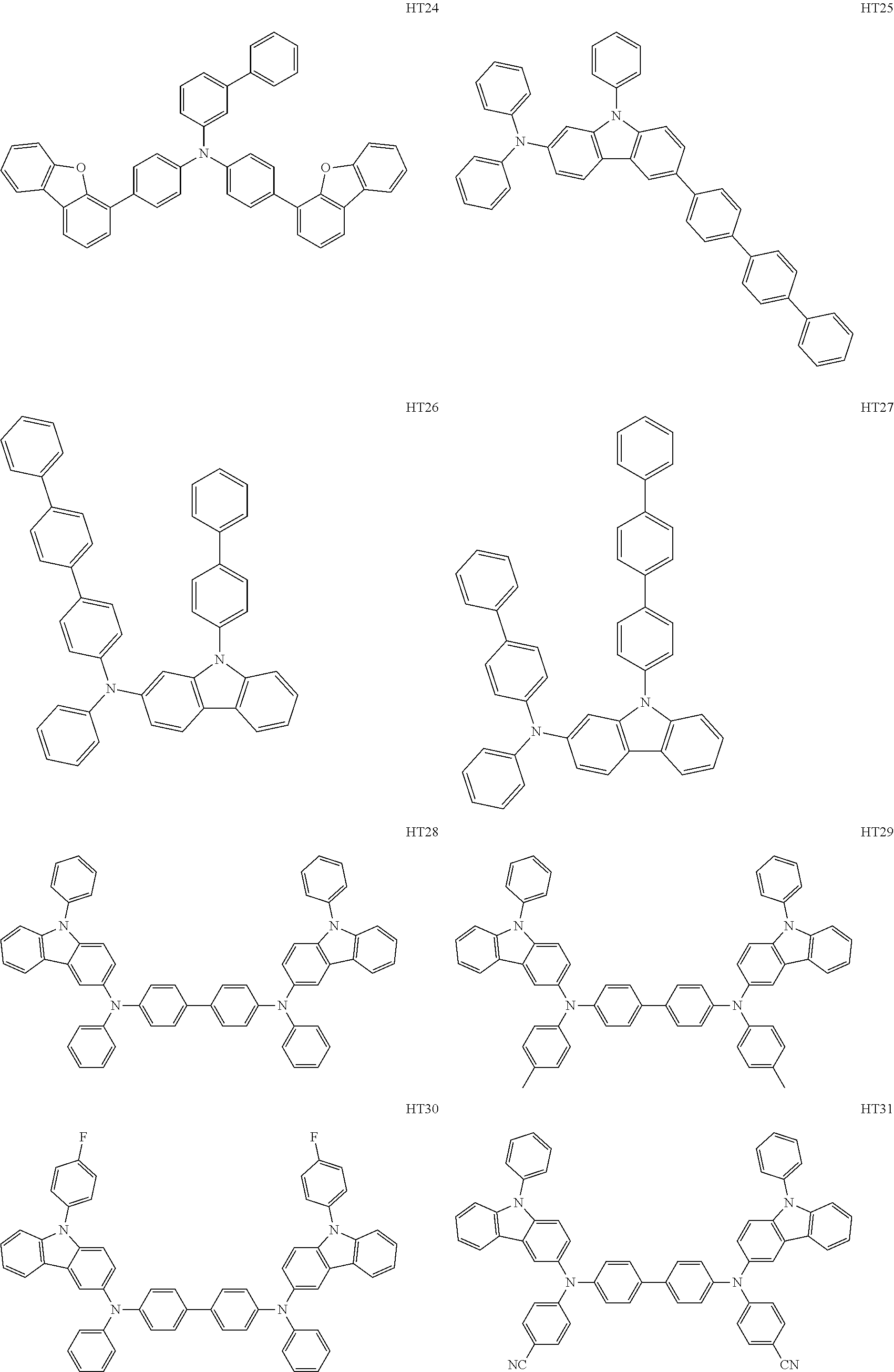

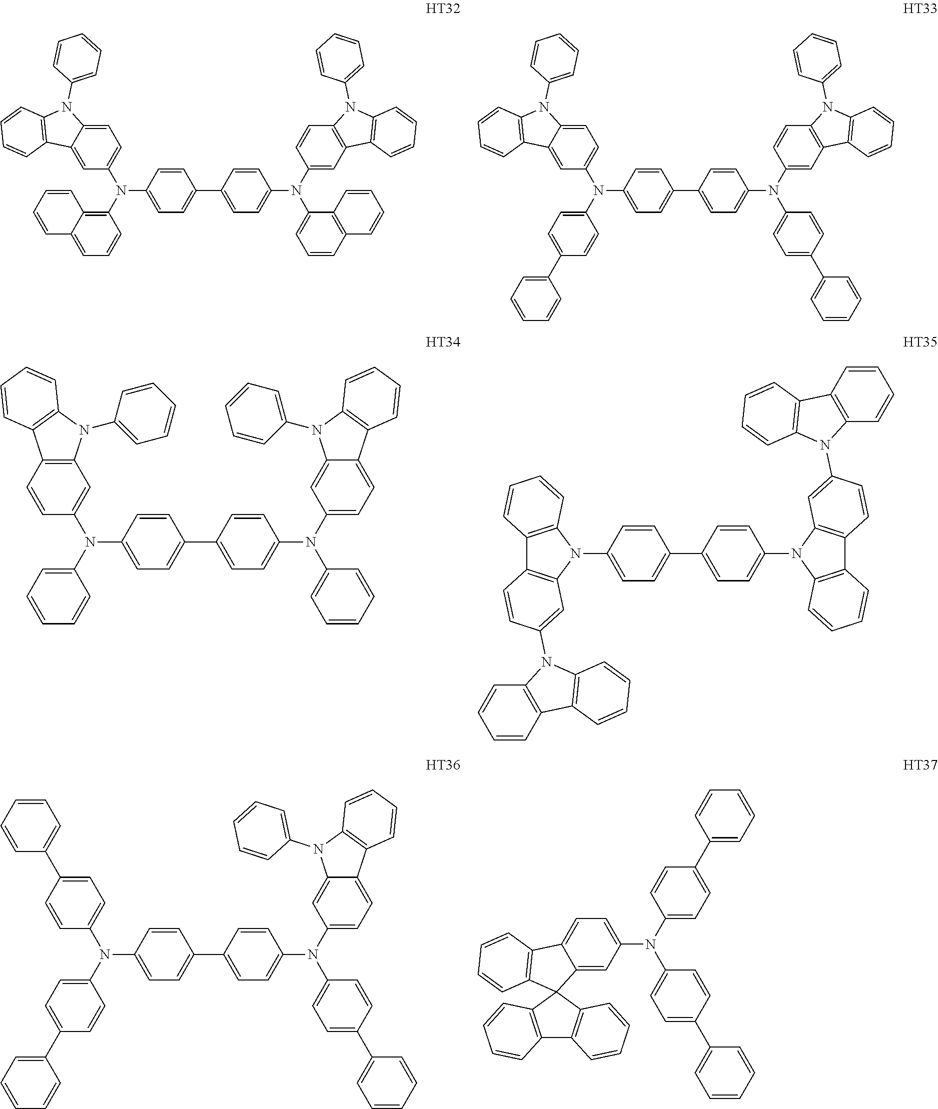

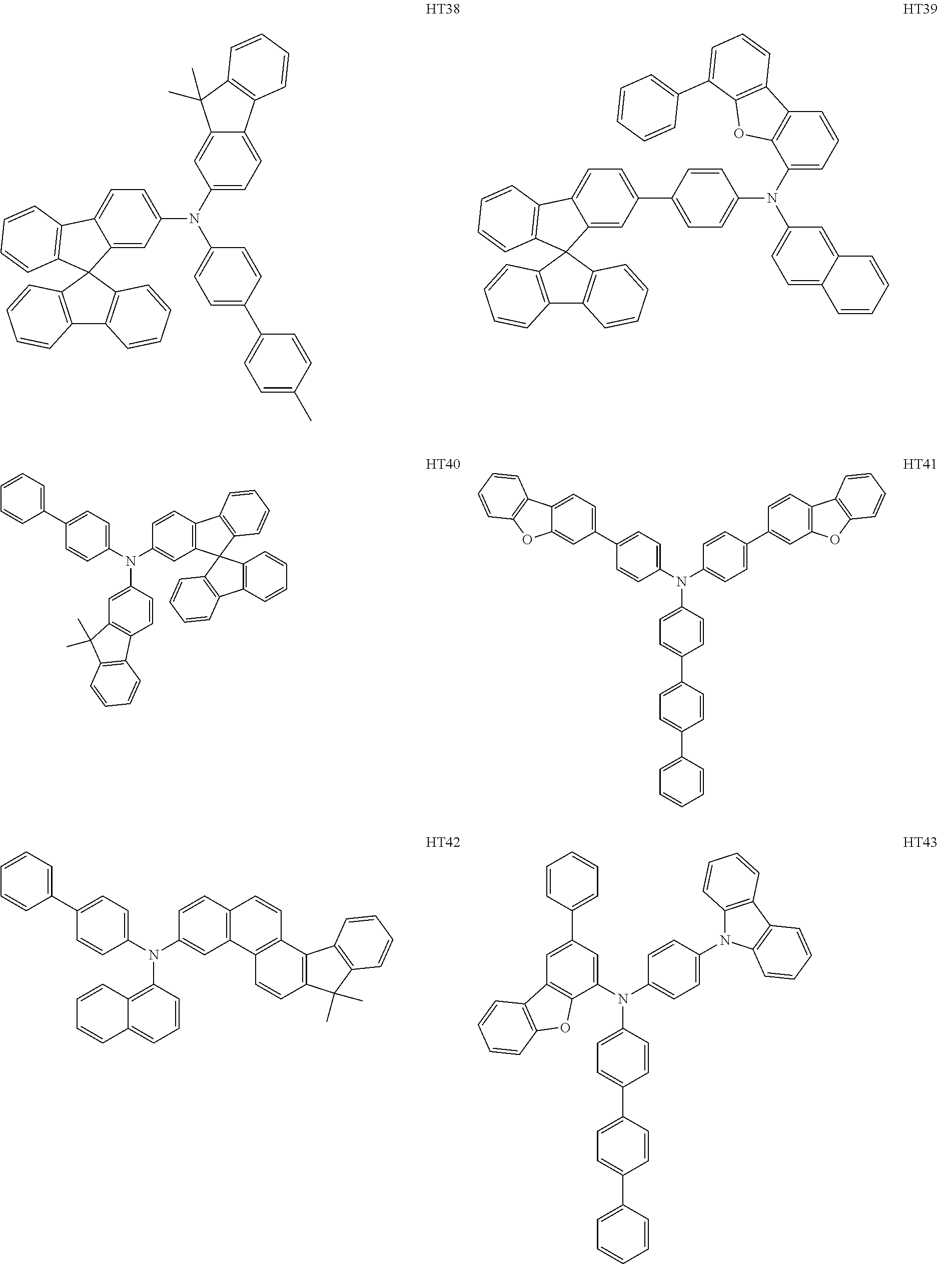

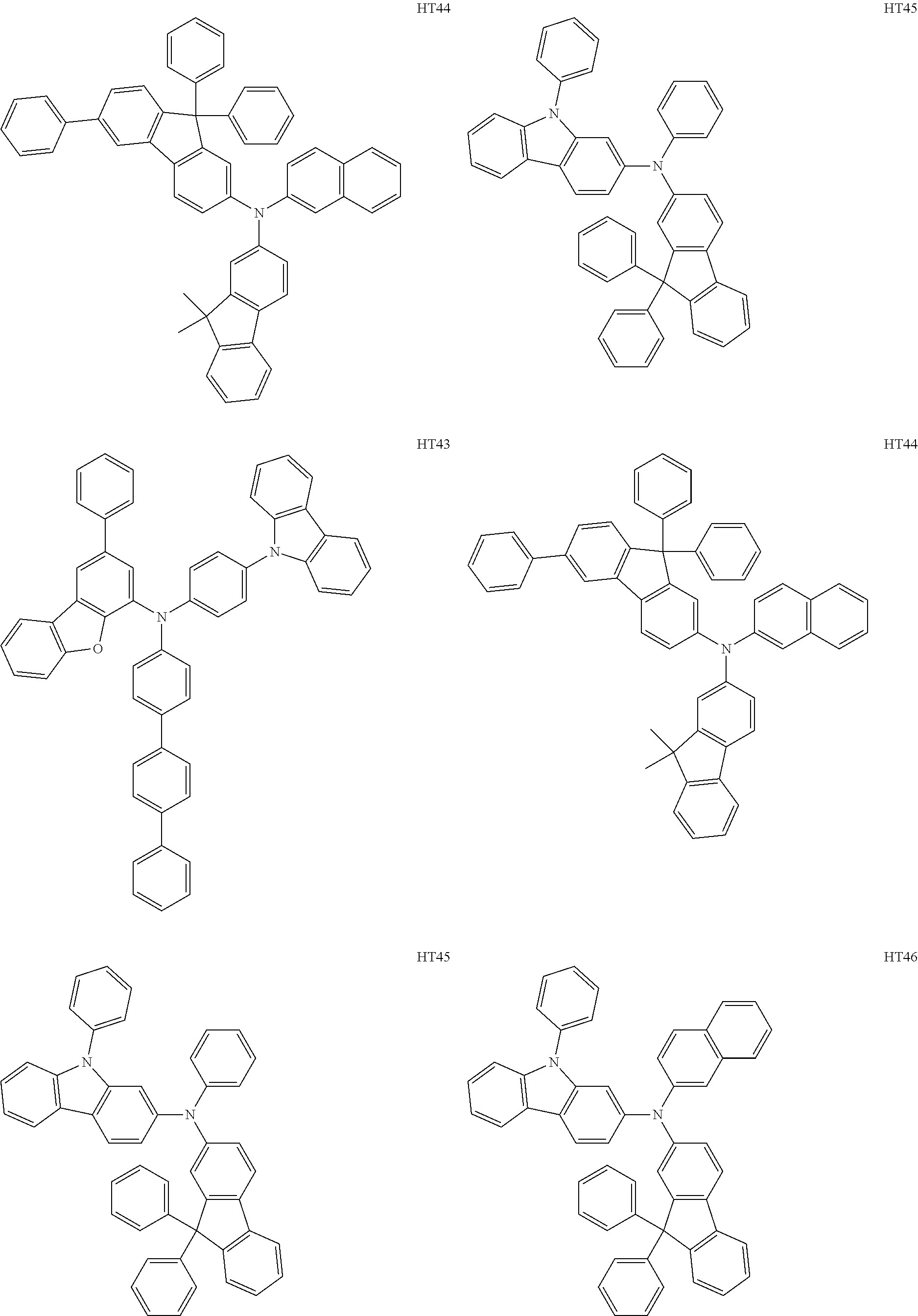

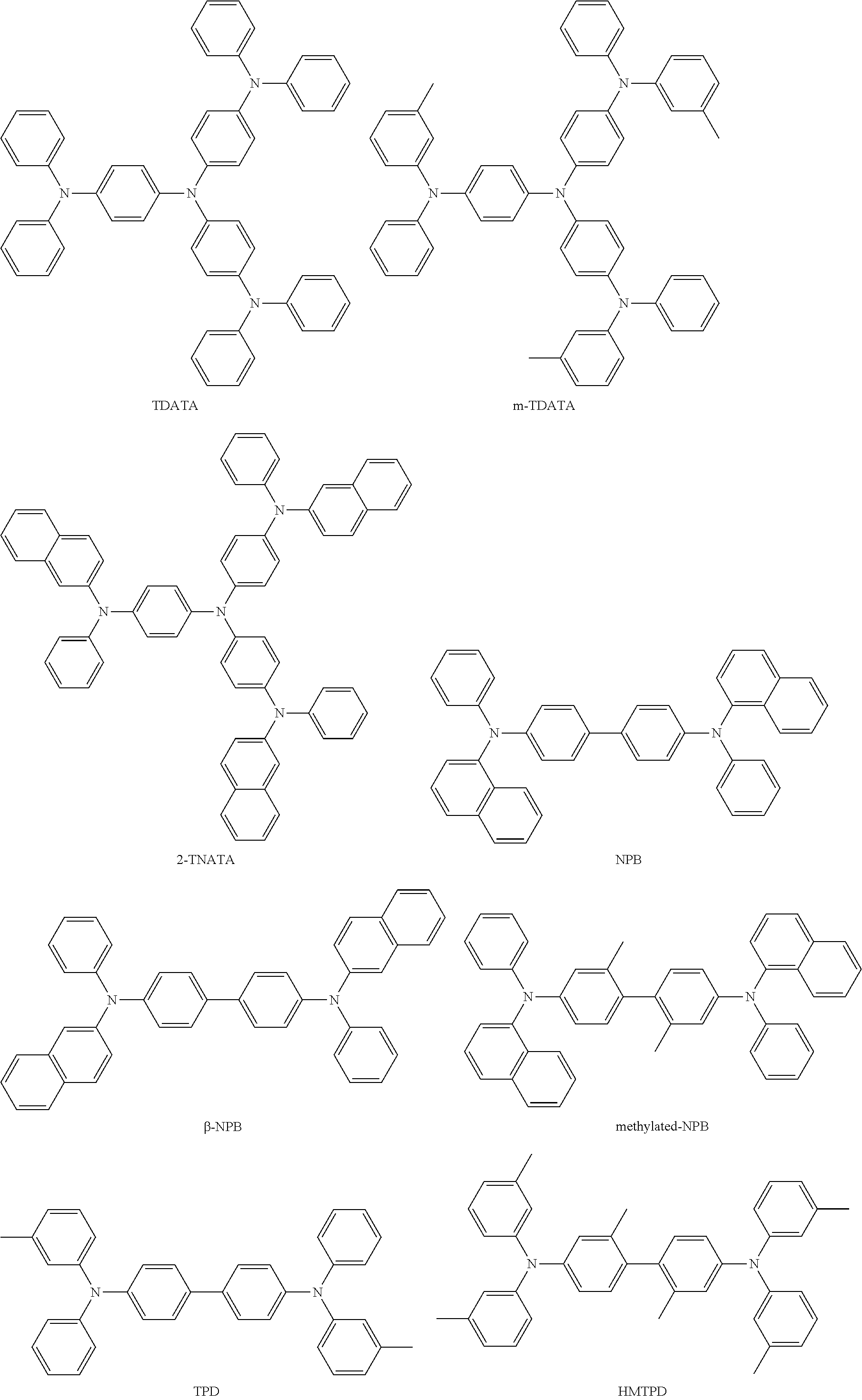

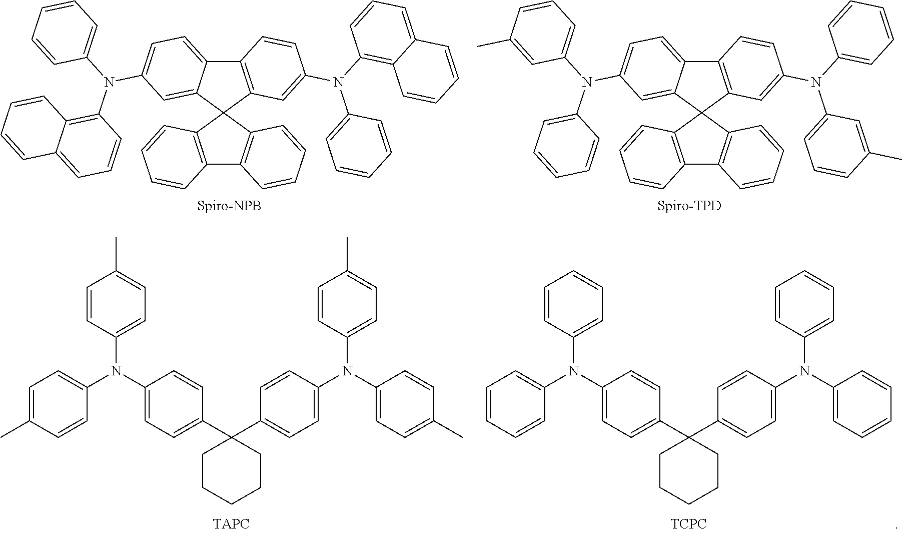

A thickness of the hole transport region may be in a range of about 50 Å to about 10,000 Å. For example, the thickness of the hole transport region may be in a range of about 100 Å to about 4,000 Å. In case that the hole transport region includes a hole injection layer, a hole transport layer, or any combination thereof, the thickness of the hole injection layer may be in a range of about 100 Å to about 9,000 Å, and the thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. In case that the thicknesses of the hole transport region, the hole injection layer, and the hole transport layer are within the ranges described above, satisfactory hole transporting characteristics may be obtained without a substantial increase in driving voltage.

The emission auxiliary layer may increase light emission efficiency by compensating for an optical resonance distance according to a wavelength of light emitted by the emission layer, and the electron blocking layer may block the leakage of electrons from the emission layer to the hole transport region. Materials that may be included in the hole transport region may be included in the emission auxiliary layer and the electron blocking layer.

[p-Dopant]

The hole transport region may further include, in addition to the materials described above, a charge generation material for the improvement of conductive properties. The charge generation material may be uniformly or non-uniformly dispersed in the hole transport region (e.g., in the form of a single layer consisting of the charge generation material).

The charge generation material may be, for example, a p-dopant.

In an embodiment, a lowest unoccupied molecular orbital (LUMO) energy level of the p-dopant may be less than or equal to about −3.5 eV.

In an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

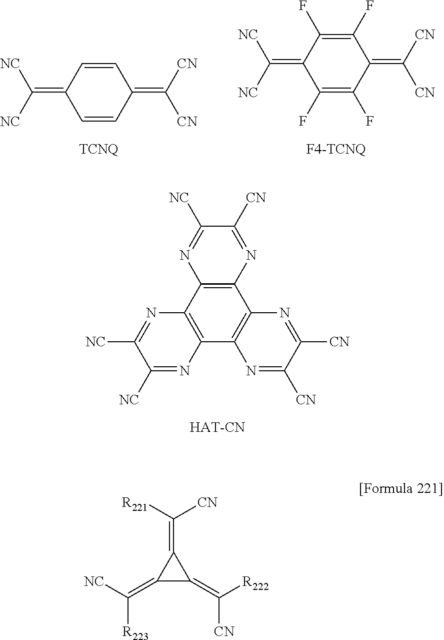

### In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or a combination thereof, and element EL2 may be a non-metal, a metalloid, or a combination thereof.

Examples of a metal may include: an alkali metal (e.g., lithium (Li), sodium (Na), potassium (K), rubidium (Rb), cesium (Cs), etc.); an alkaline earth metal (e.g., beryllium (Be), magnesium (Mg), calcium (Ca), strontium (Sr), barium (Ba), etc.); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (e.g., zinc (Zn), indium (In), tin (Sn), etc.); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of a metalloid may include silicon (Si), antimony (Sb), tellurium (Te), and the like.

Examples of a non-metal may include oxygen (O), halogen (e.g., F, Cl, Br, I, etc.), and the like.

Examples of a compound including element EL1 and element EL2 may include a metal oxide, a metal halide (e.g., a metal fluoride, a metal chloride, a metal bromide, a metal iodide, etc.), a metalloid halide (e.g., a metalloid fluoride, a metalloid chloride, a metalloid bromide, a metalloid iodide, etc.), a metal telluride, or any combination thereof.

Examples of a metal oxide may include tungsten oxide (e.g., WO, W₂O₃, WO₂, WO₃, W₂O₅, etc.), vanadium oxide (e.g., VO, V₂O₃, VO₂, V₂O₅, etc.), molybdenum oxide (e.g., MoO, Mo₂O₃, MoO₂, MoO₃, Mo₂O₅, etc.), rhenium oxide (e.g., ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of a transition metal halide may include a titanium halide (e.g., TiF₄, TiCl₄, TiBr₄, TiI₄, etc.), a zirconium halide (e.g., ZrF₄, ZrCl₄, ZrBr₄, ZrI₄, etc.), a hafnium halide (e.g., HfF₄, HfCl₄, HfBr₄, HfI₄, etc.), a vanadium halide (e.g., VF₃, VCl₃, VBr₃, VI₃, etc.), a niobium halide (e.g., NbF₃, NbCl₃, NbBr₃, NbI₃, etc.), a tantalum halide (e.g., TaF₃, TaCl₃, TaBr₃, TaI₃, etc.), a chromium halide (e.g., CrF₃, CrCl₃, CrBr₃, CrI₃, etc.), a molybdenum halide (e.g., MoF₃, MoCl₃, MoBr₃, MoI₃, etc.), a tungsten halide (e.g., WF₃, WCl₃, WBr₃, WI₃, etc.), a manganese halide (e.g., MnF₂, MnCl₂, MnBr₂, MnI₂, etc.), a technetium halide (e.g., TcF₂, TcCl₂, TcBr₂, TcI₂, etc.), a rhenium halide (e.g., ReF₂, ReCl₂, ReBr₂, ReI₂, etc.), an iron halide (e.g., FeF₂, FeCl₂, FeBr₂, FeI₂, etc.), a ruthenium halide (e.g., RuF₂, RuCl₂, RuBr₂, RuI₂, etc.), an osmium halide (e.g., OsF₂, OSCl₂, OsBr₂, OSI₂, etc.), a cobalt halide (e.g., CoF₂, COCl₂, CoBr₂, CoI₂, etc.), a rhodium halide (e.g., RhF₂, RhCl₂, RhBr₂, RhI₂, etc.), an iridium halide (e.g., IrF₂, IrCl₂, IrBr₂, IrI₂, etc.), a nickel halide (e.g., NiF₂, NiCl₂, NiBr₂, NiI₂, etc.), a palladium halide (e.g., PdF₂, PdCl₂, PdBr₂, PdI₂, etc.), a platinum halide (e.g., PtF₂, PtCl₂, PtBr₂, PtI₂, etc.), a copper halide (e.g., CuF, CuCl, CuBr, CuI, etc.), a silver halide (e.g., AgF, AgCl, AgBr, AgI, etc.), a gold halide (e.g., AuF, AuCl, AuBr, AuI, etc.), and the like.

Examples of a post-transition metal halide may include a zinc halide (e.g., ZnF₂, ZnCl₂, ZnBr₂, ZnI₂, etc.), an indium halide (e.g., InI₃, etc.), a tin halide (e.g., SnI₂, etc.), and the like.

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and the like.

Examples of a metalloid halide may include an antimony halide (e.g., SbCl₅, etc.) and the like.

Examples of a metal telluride may include an alkali metal telluride (e.g., Li₂Te, Na₂Te, K₂Te, Rb₂Te, Cs₂Te, etc.), an alkaline earth metal telluride (e.g., BeTe, MgTe, CaTe, SrTe, BaTe, etc.), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (e.g., ZnTe, etc.), a lanthanide metal telluride (e.g., LaTe, CeTe, PrTe, NdTe, PmTe, EuTe, GdTe, TbTe, DyTe, HoTe, ErTe, TmTe, YbTe, LuTe, etc.), and the like.

As described above, the materials of the hole transport layer and the hole injection layer may be selected so that the hole mobility of the hole transport layer may be greater than the hole mobility of the hole injection layer.

In an embodiment, the materials of the hole transport layer and the hole injection layer may be selected so that the HOMO energy of the hole transport layer may be less than or equal to the HOMO energy of the hole injection layer.

### [Emission Layer in Interlayer 130]

In case that the light-emitting device 10 is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers contact each other or are separated from each other, to emit white light. In embodiments, the emission layer may include two or more materials of a red light-emitting material, a green light-emitting material, and a blue light-emitting material, in which the two or more materials may be mixed with each other in a single layer, to emit white light.

In an embodiment, the emission layer may include a host and a dopant (or an emitter). In an embodiment, the emission layer may further include an auxiliary dopant that promotes energy transfer to a dopant (or to an emitter), in addition to the host and the dopant (or the emitter). In case that the emission layer includes the dopant (or the emitter) and the auxiliary dopant, the dopant (or the emitter) and the auxiliary dopant may be different from each other.

An amount (weight) of the dopant (or the emitter) in the emission layer may be in a range of about 0.01 parts by weight to about 15 parts by weight, based on 100 parts by weight of the host.

In an embodiment, the emission layer may include quantum dots.

In an embodiment, the emission layer may include a delayed fluorescence material. The delayed fluorescence material may act as a host or a dopant in the emission layer.

A thickness of the emission layer may be in a range of about 100 Å to about 1,000 Å. For example, the thickness of the emission layer may be in a range of about 200 Å to about 600 Å. In case that the thickness of the emission layer is within the range described above, excellent luminescence characteristics may be obtained without a substantial increase in driving voltage.

### [Host]

In an embodiment, the host may include a compound represented by Formula 301:

[Ar₃₀₁]_{xb11}-[(L₃₀₁)_{xb1}-R₃₀₁]_{xb21} [Formula 301]

### In Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ are each independently the same as described in connection with Q₁.

In an embodiment, in Formula 301, in case that xb11 is 2 or more, two or more of Ar₃₀₁ may be linked to each other via a single bond.

In an embodiment, the host may include a compound represented by Formula 301-1, a compound represented by Formula 301-2, or any combination thereof:

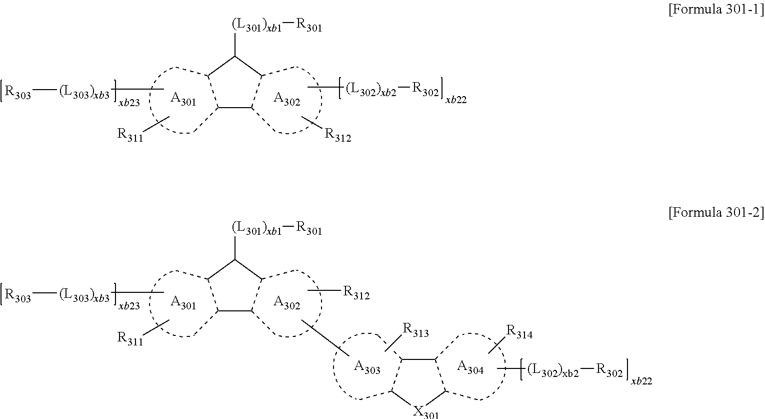

### In Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each the same as described herein,
L₃₀₂ to L₃₀₄ are each independently the same as described in connection with L₃₀₁,
xb2 to xb4 are each independently the same as described in connection with xb1, and
R₃₀₂ to R₃₀₅ and R₃₁₁ to R₃₁₄ may each independently the same as described in connection with R₃₀₁.

In an embodiment, the host may include an alkali earth metal complex, a post-transition metal complex, or any combination thereof. In an embodiment, the host may include a Be complex (e.g., Compound H55), a Mg complex, a Zn complex, or any combination thereof.

In an embodiment, the host may include: one of Compounds H1 to H129; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di-9-carbazolylbenzene (mCP); 1,3,5-tri(carbazol-9-yl)benzene (TCP); or any combination thereof:

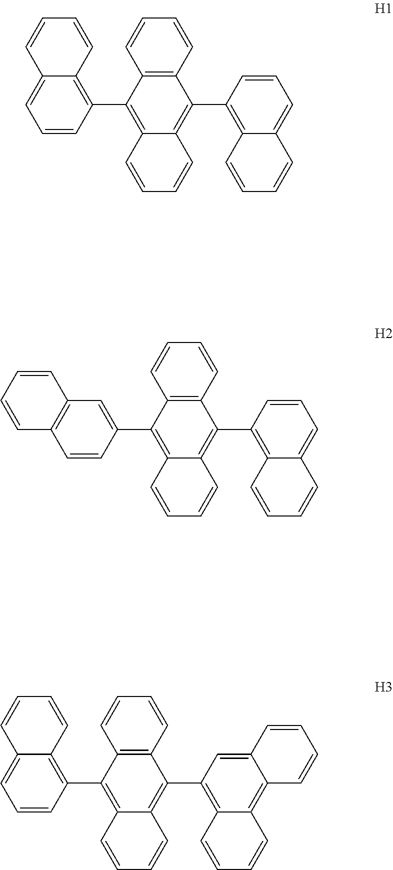

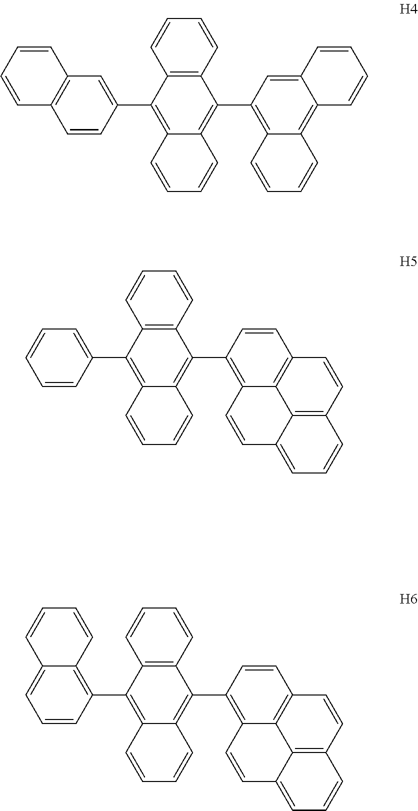

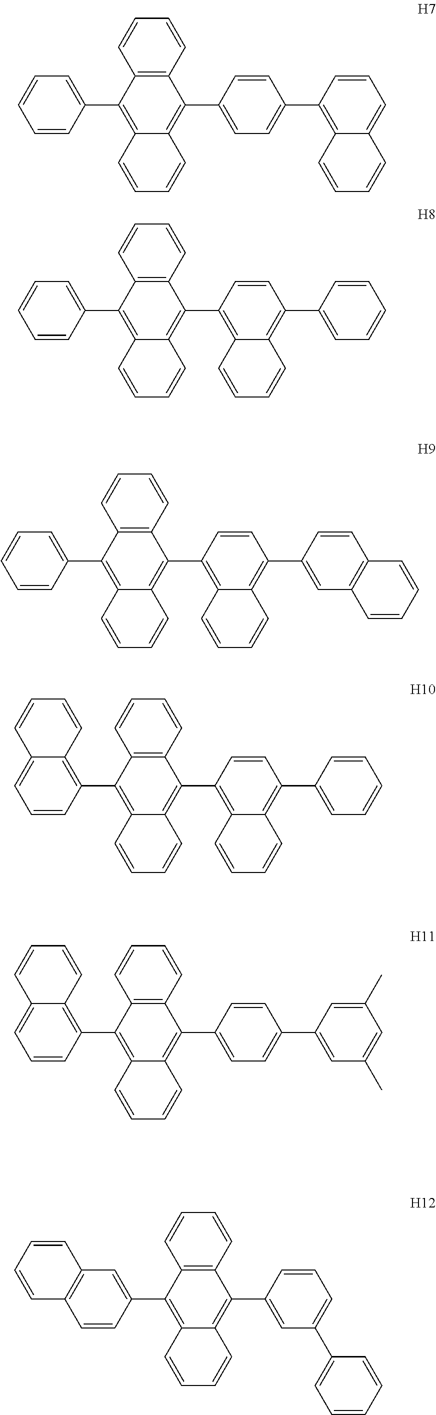

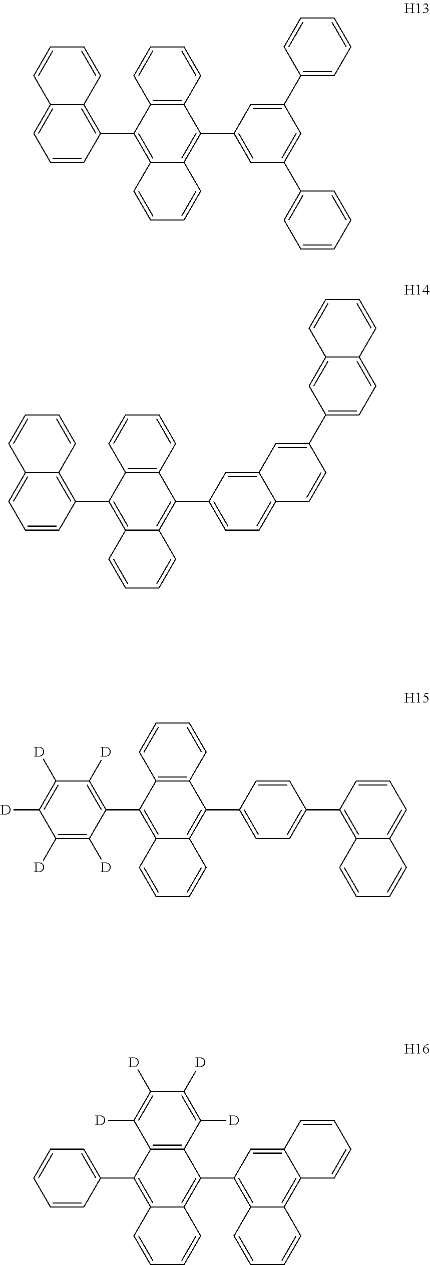

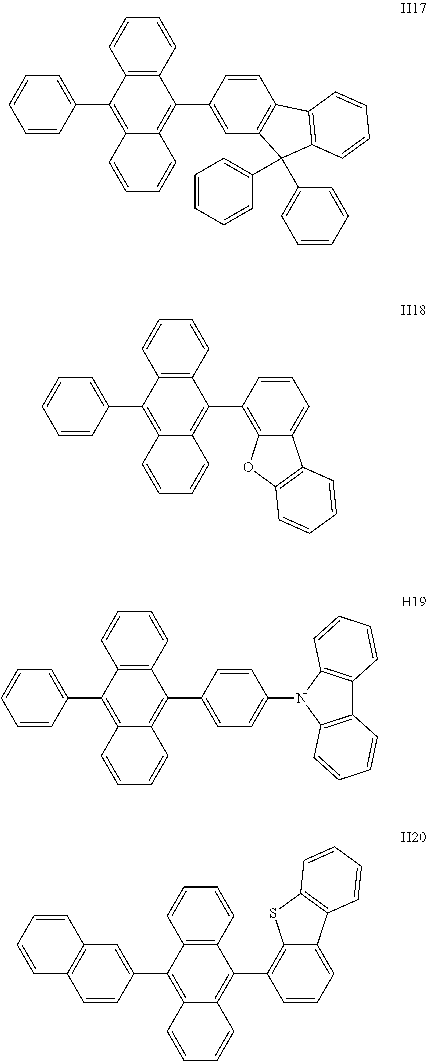

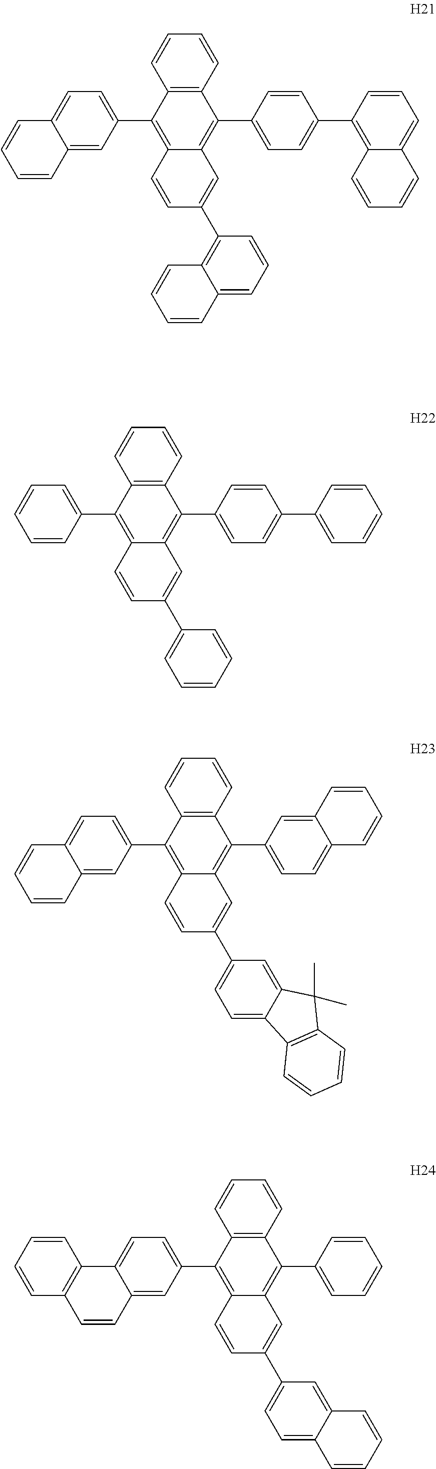

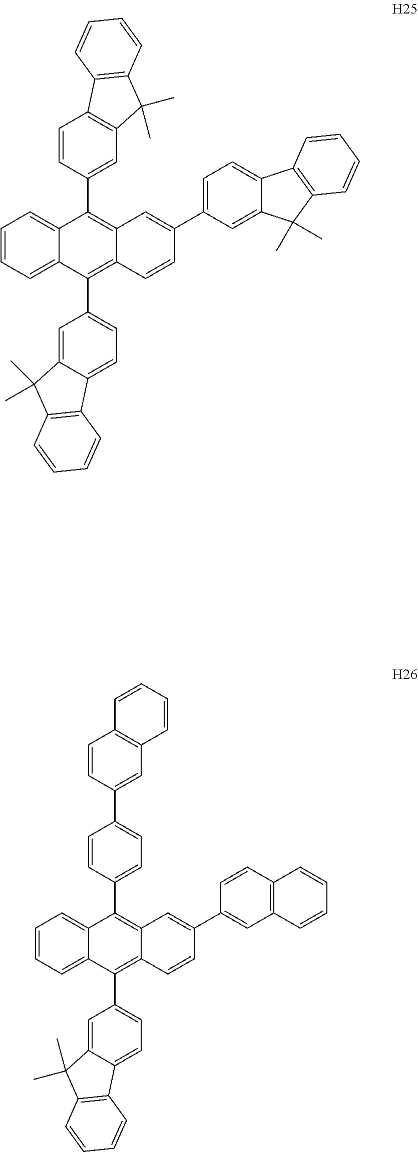

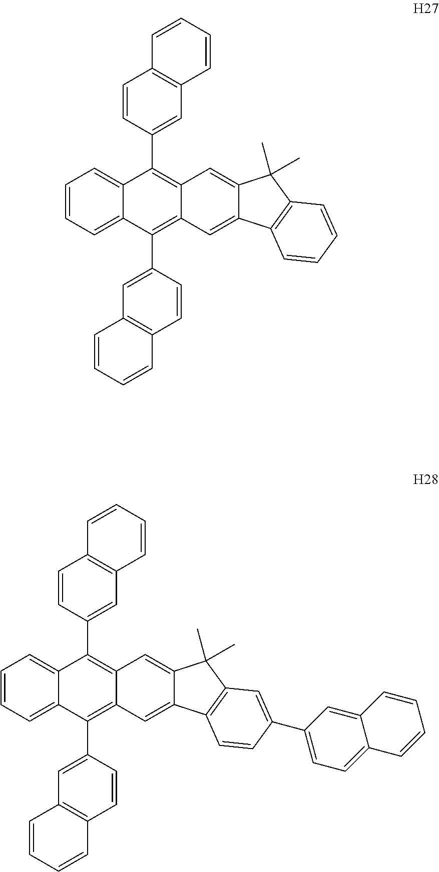

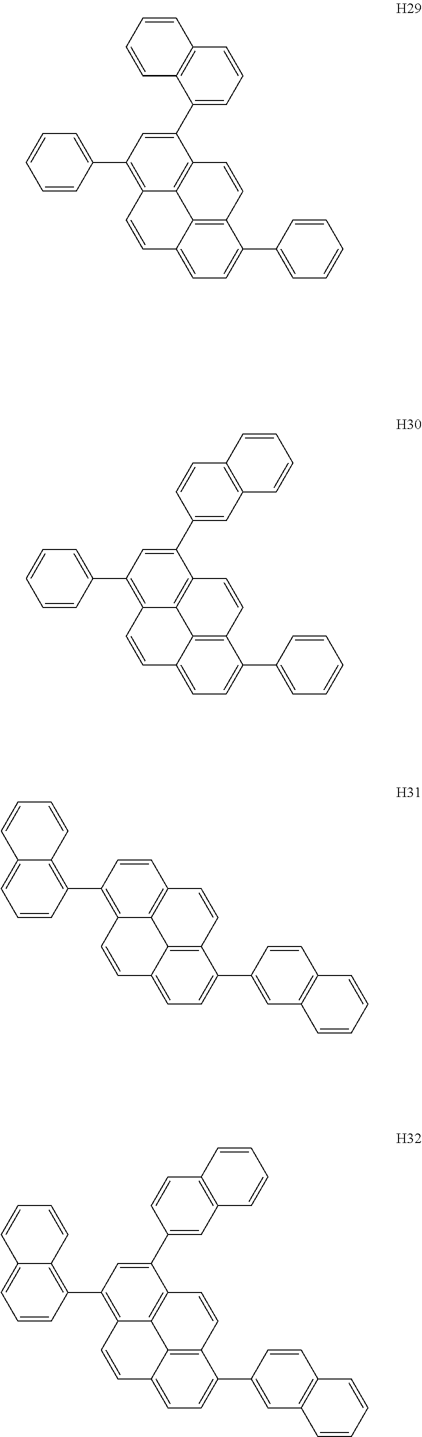

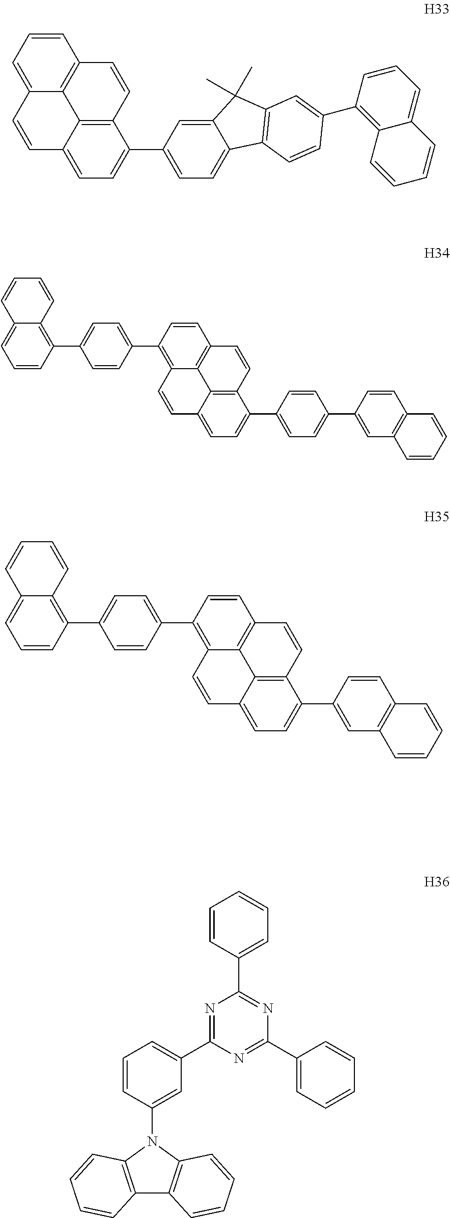

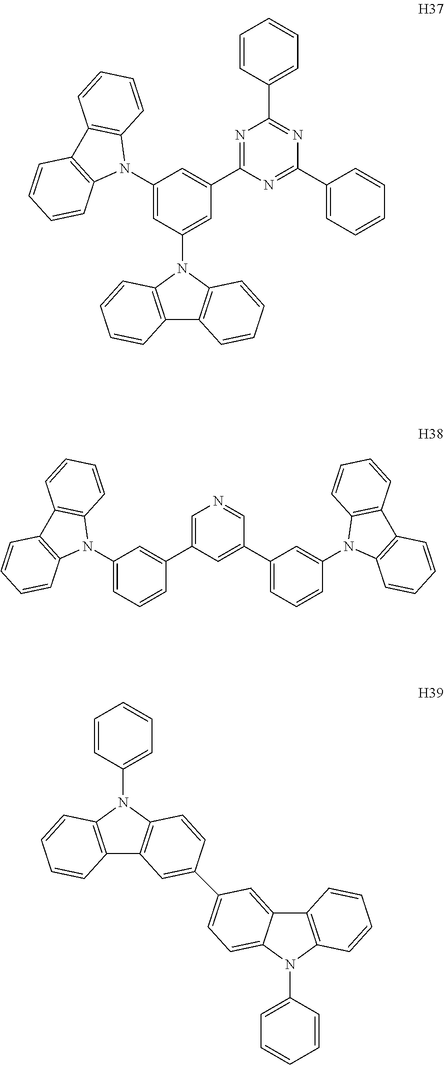 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

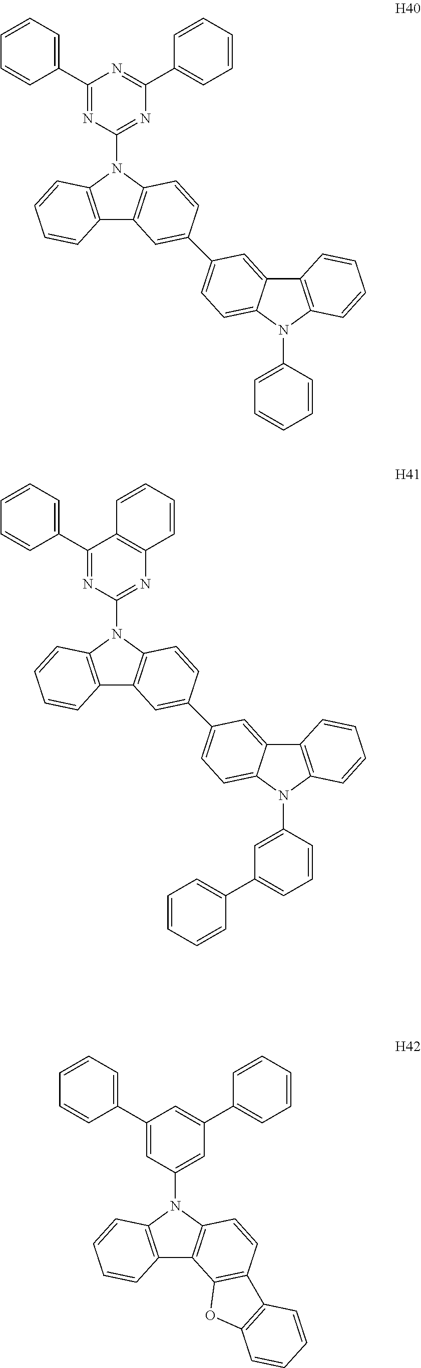 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

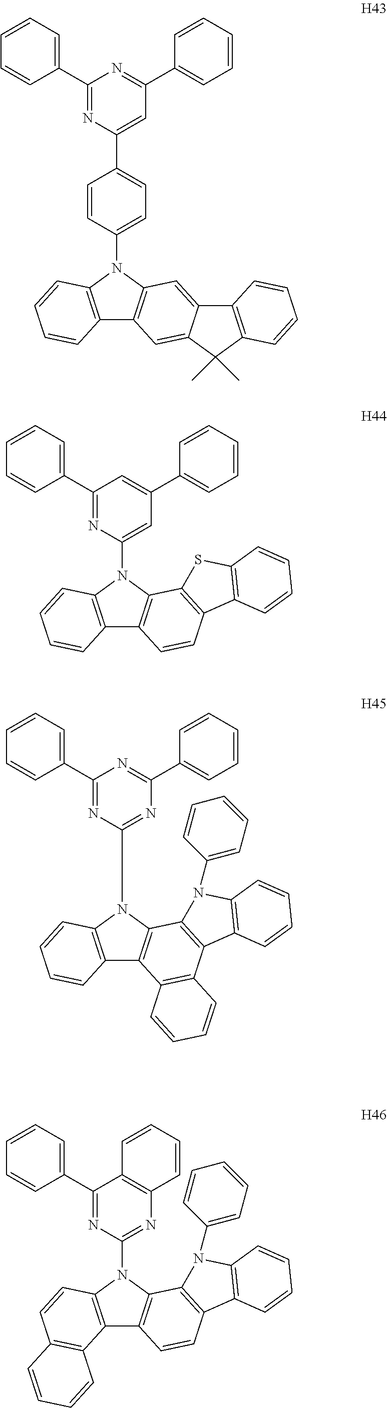 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

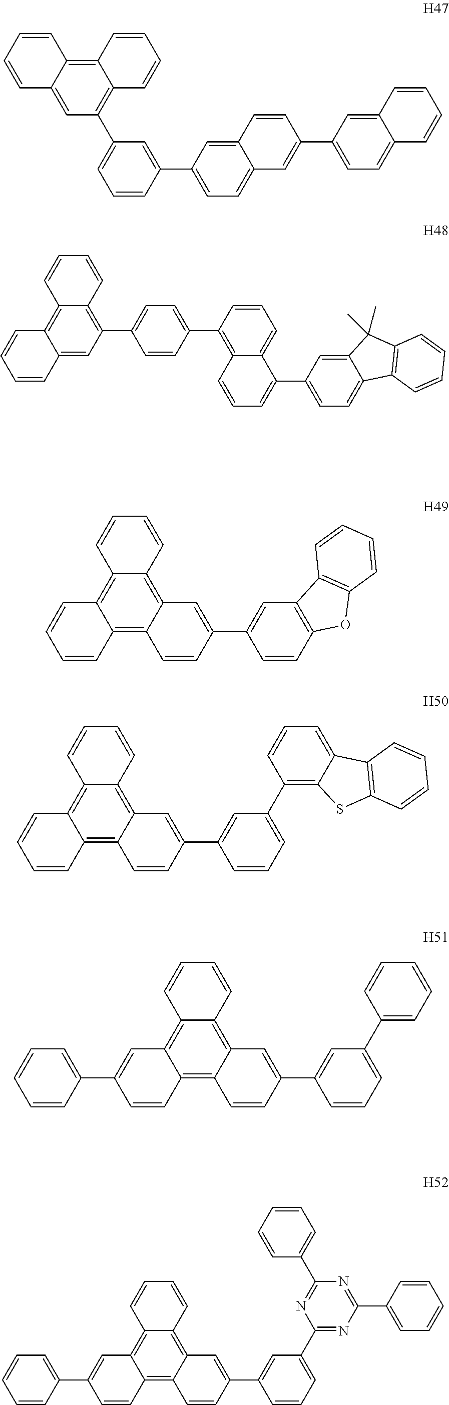

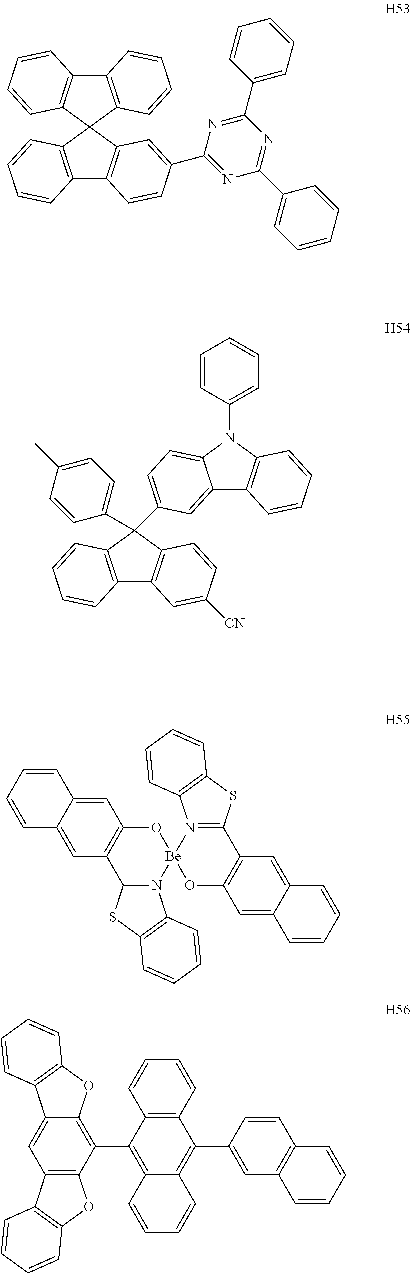

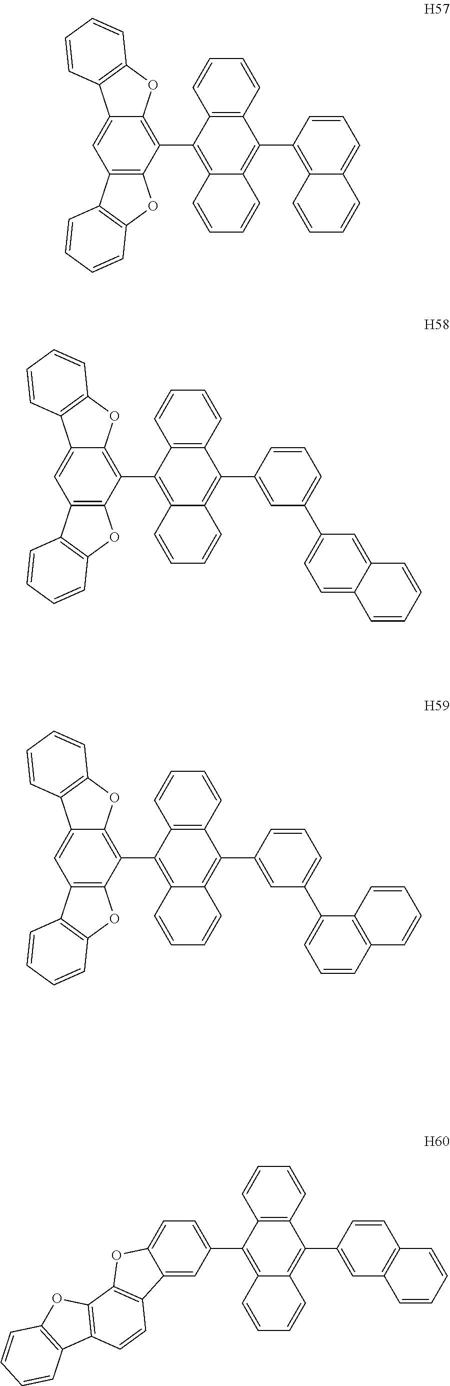 [SMILES: c1ccc2c(-c3c4ccccc4c(-c4c5oc6ccccc6c5cc5c4oc4ccccc45)c4ccccc34)cccc2c1 ; c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1]

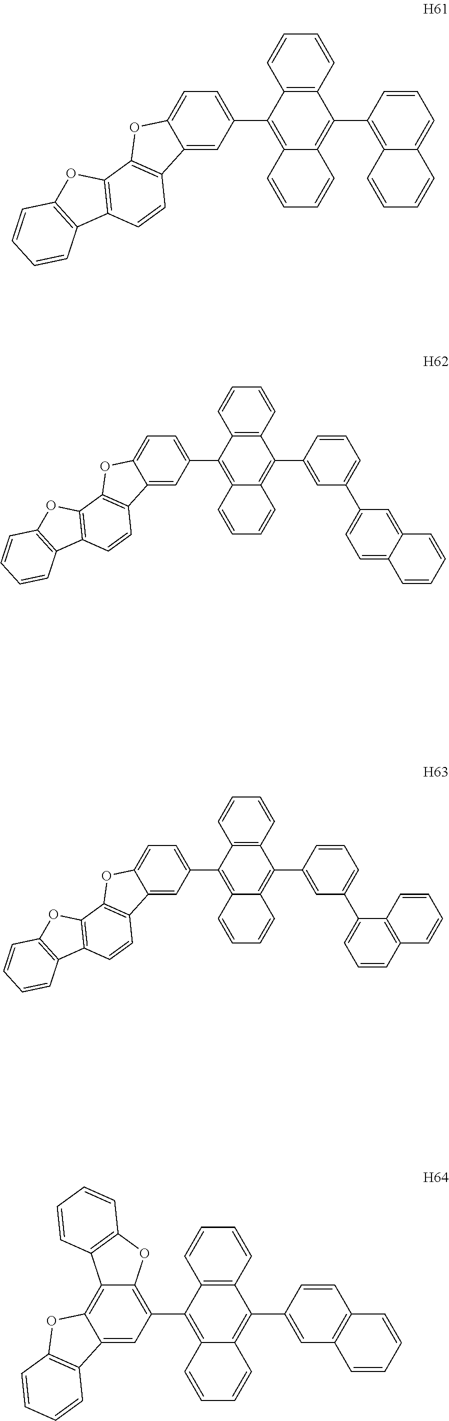 [SMILES: c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

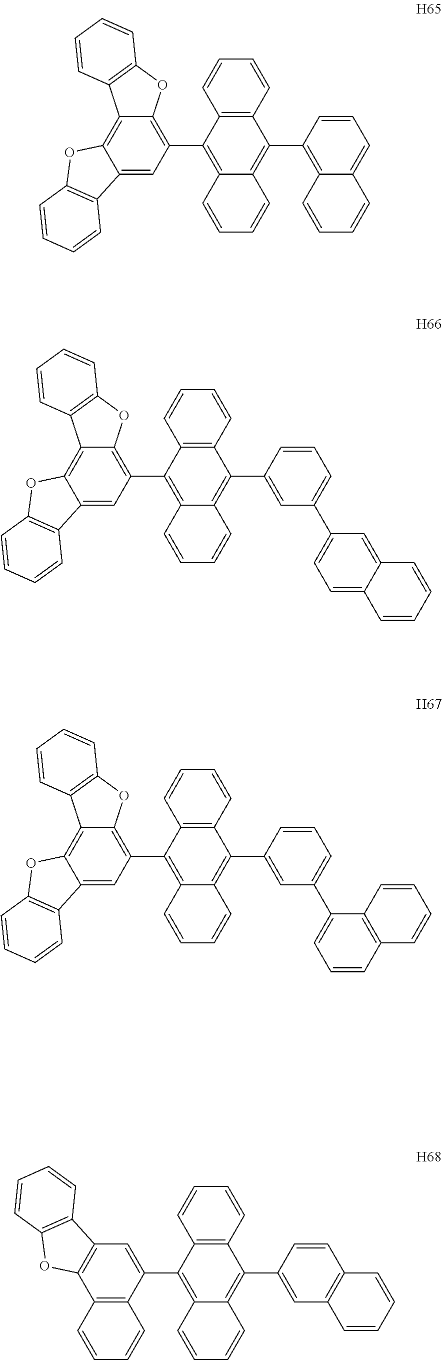 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1]

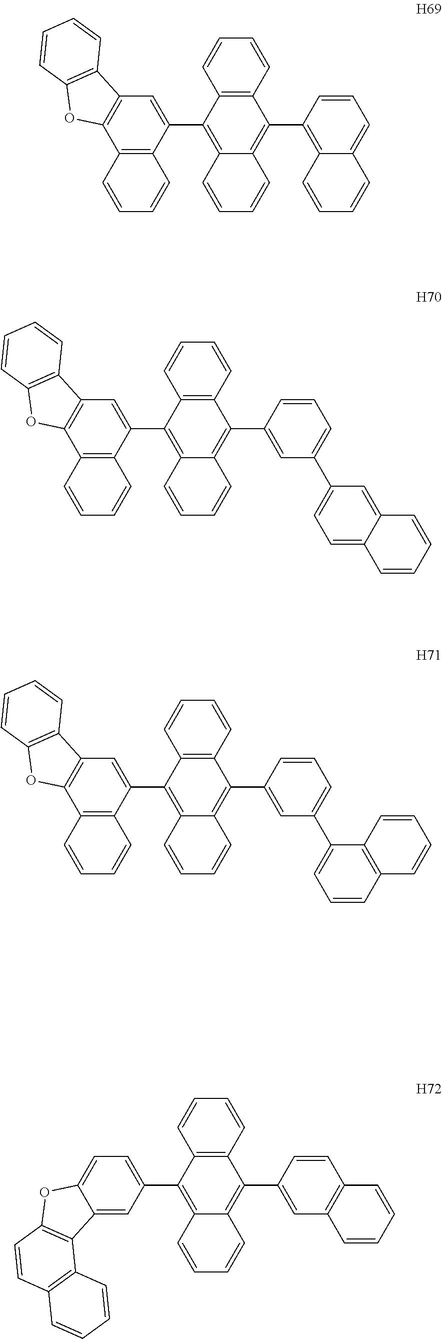 [SMILES: c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1]

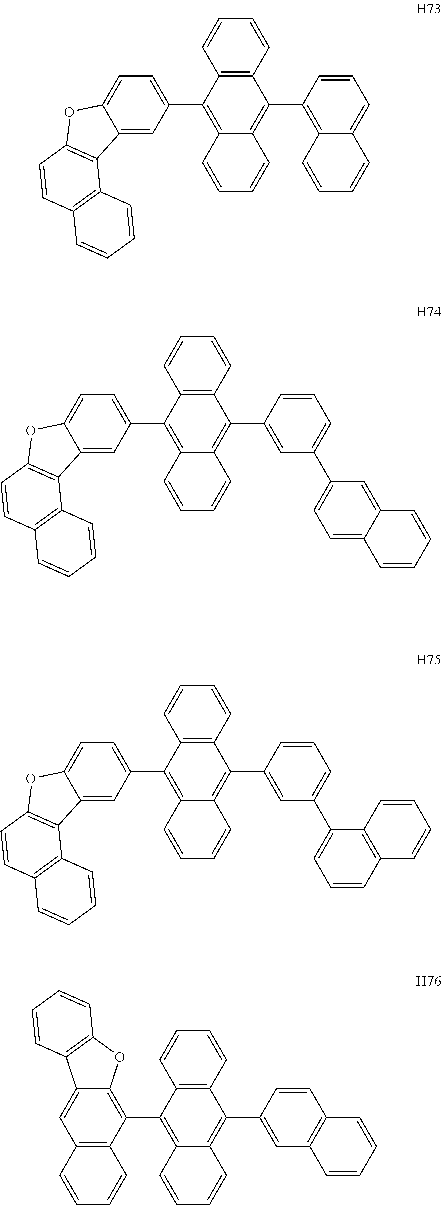 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1]

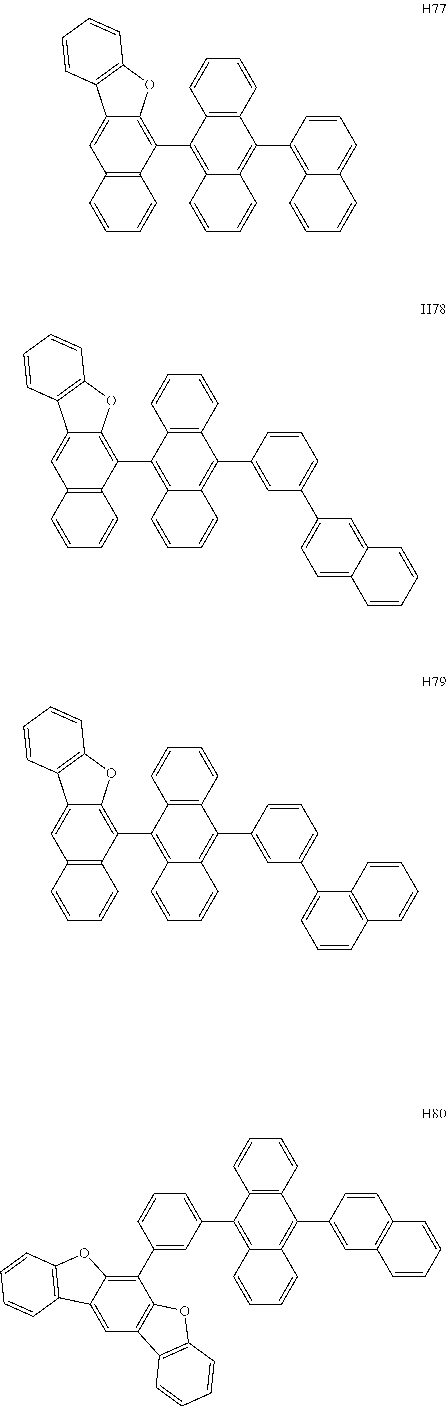 [SMILES: c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1]

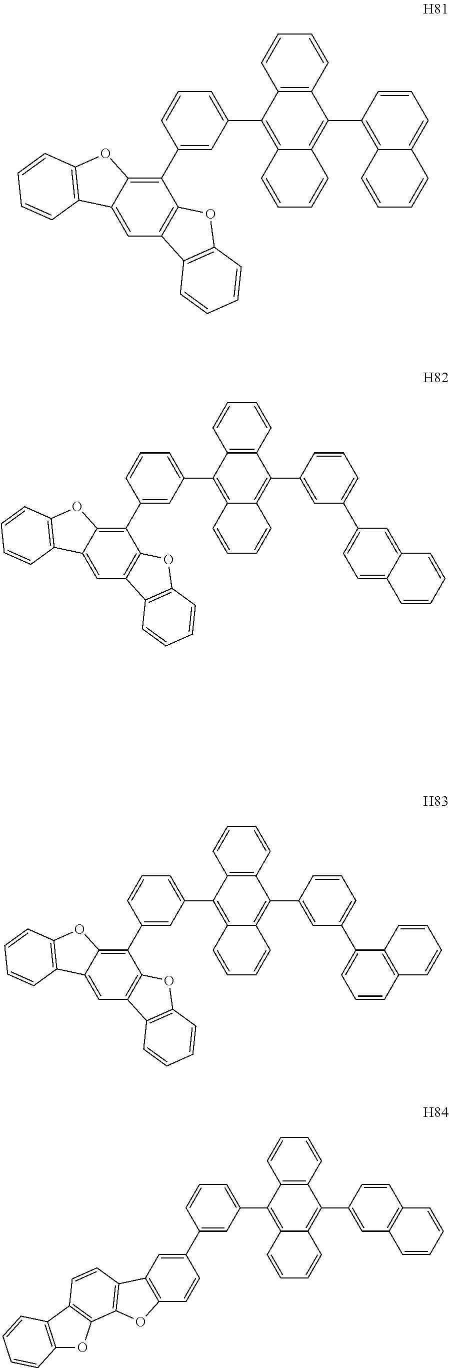 [SMILES: c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1]

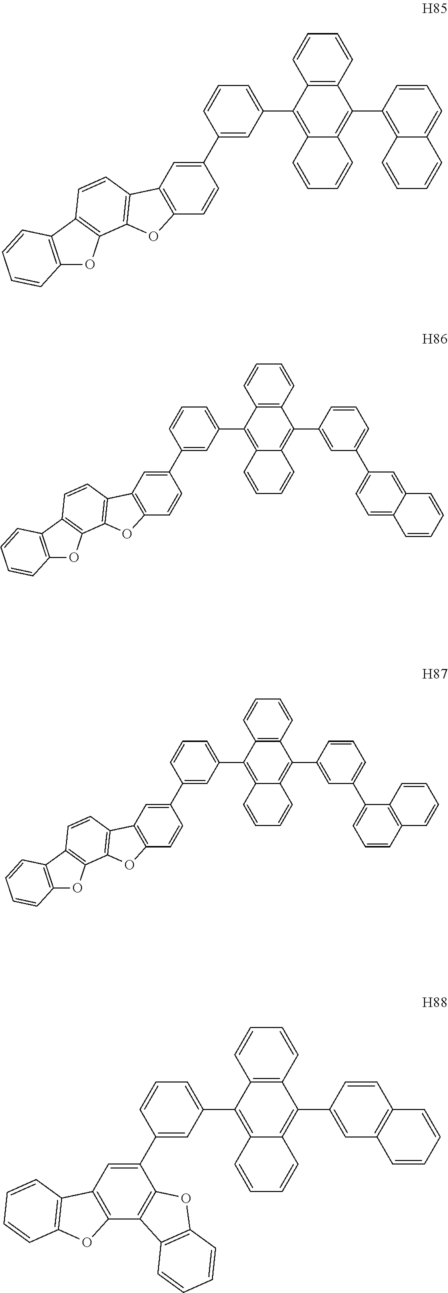 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

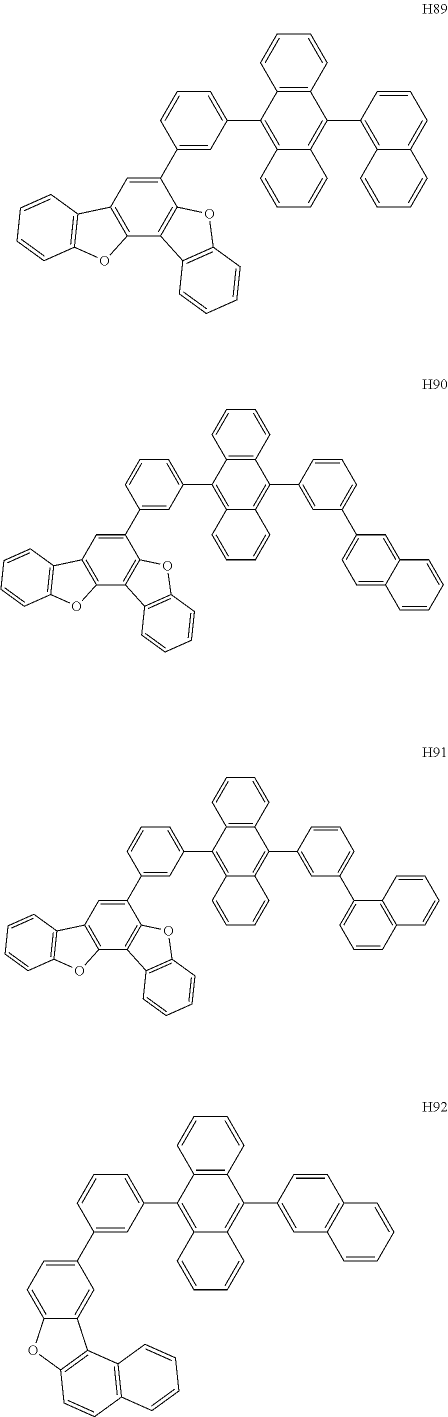 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1]

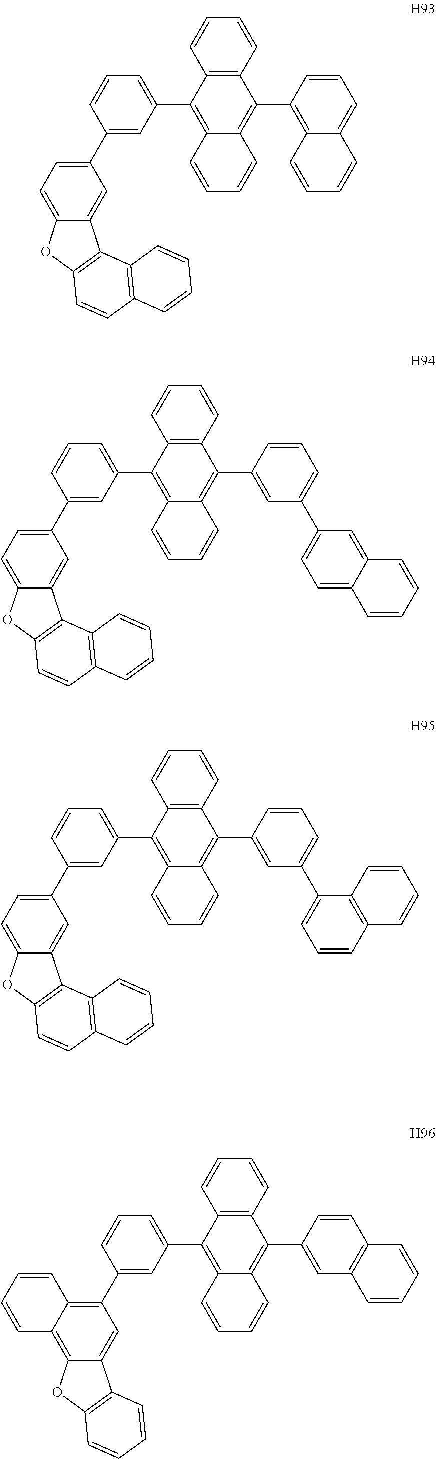 [SMILES: c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1]

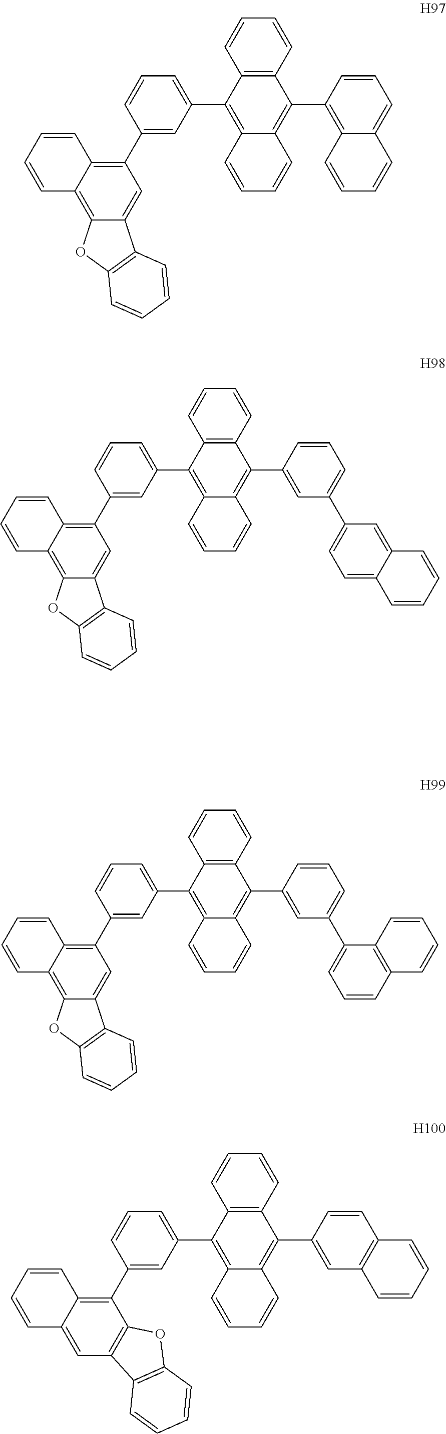 [SMILES: c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1]

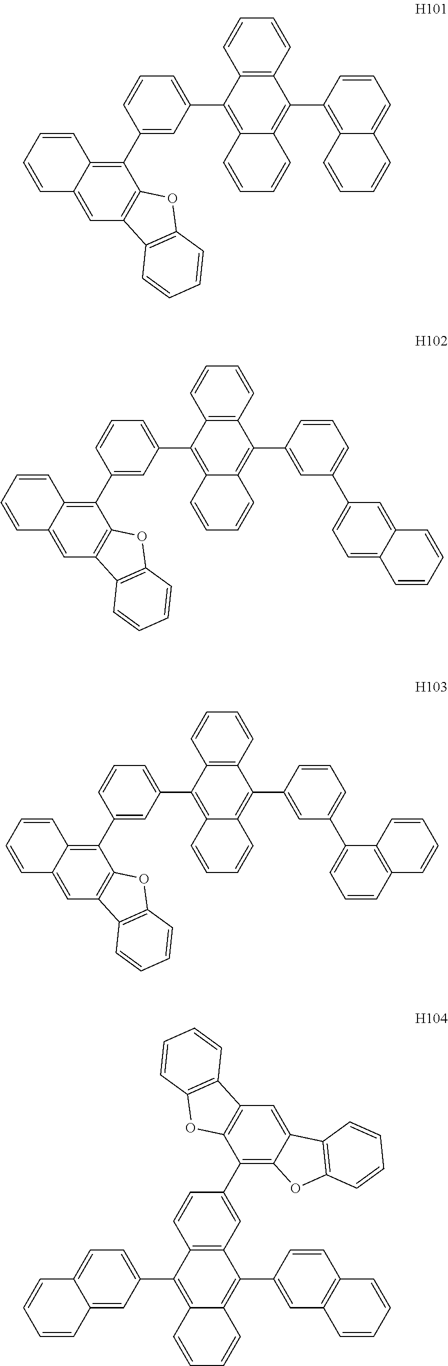 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

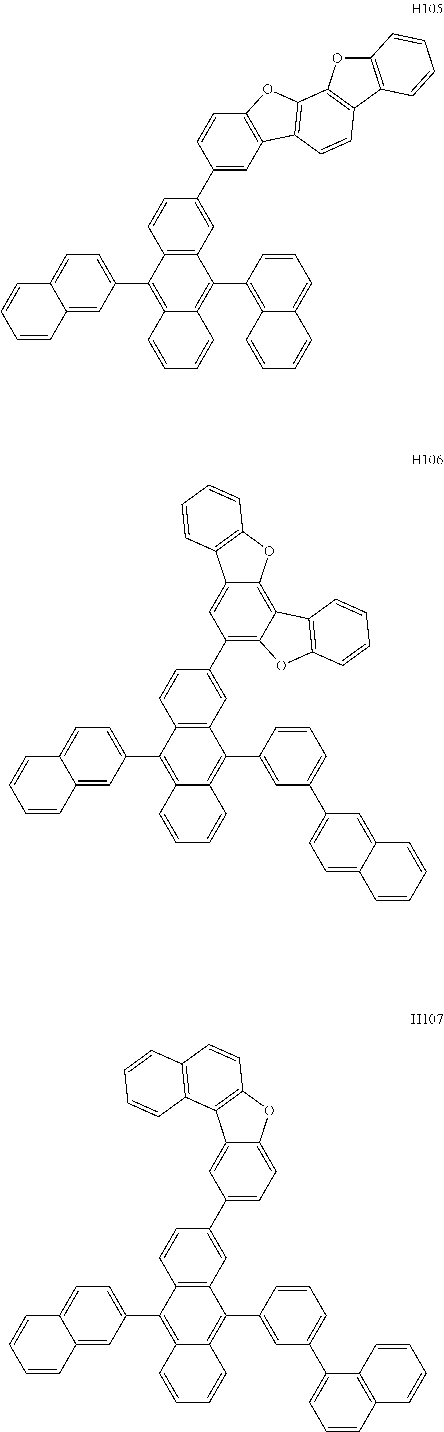 [SMILES: c1ccc2cc(-c3c4ccccc4c(-c4cccc5ccccc45)c4cc(-c5ccc6oc7c(ccc8c9ccccc9oc87)c6c5)ccc34)ccc2c1 ; c1cc(-c2ccc3ccccc3c2)cc(-c2c3ccccc3c(-c3ccc4ccccc4c3)c3ccc(-c4cc5c6ccccc6oc5c5c4oc4ccccc45)cc23)c1 ; c1cc(-c2cccc3ccccc23)cc(-c2c3ccccc3c(-c3ccc4ccccc4c3)c3ccc(-c4ccc5oc6ccc7ccccc7c6c5c4)cc23)c1]

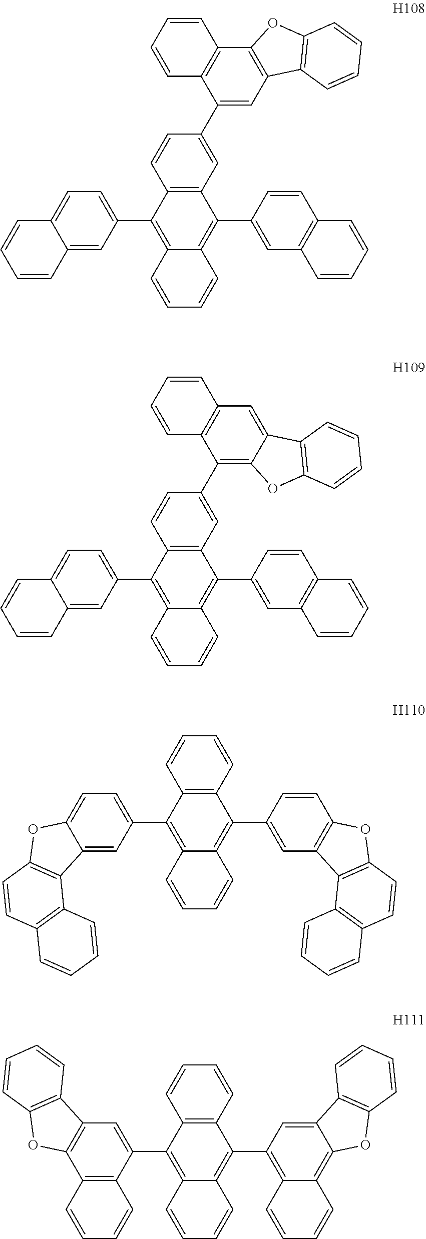 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

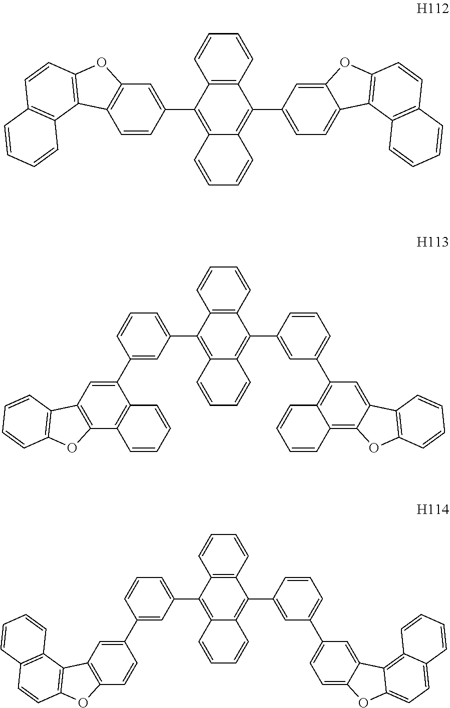 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1]

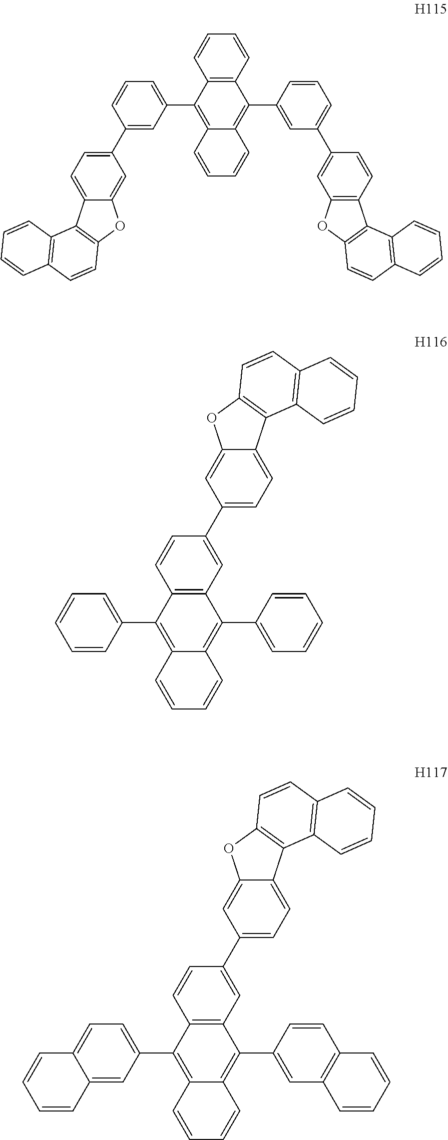 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

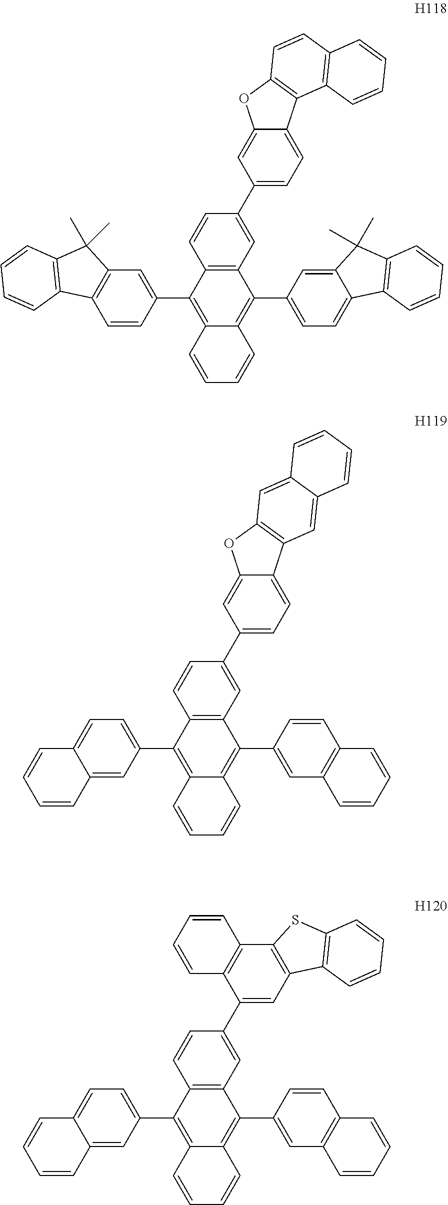 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

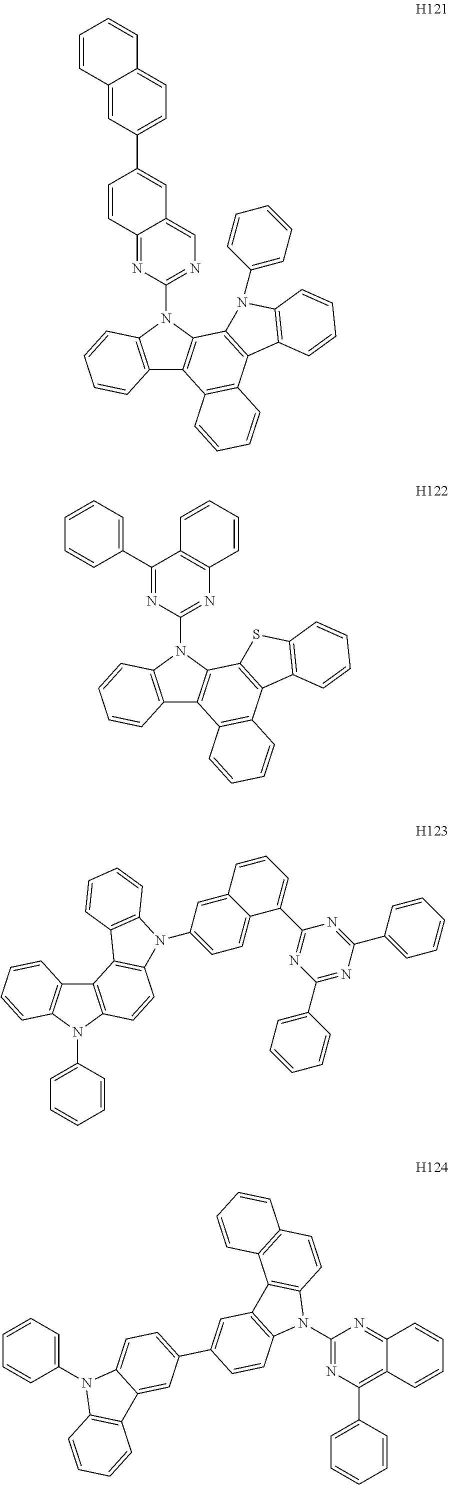 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

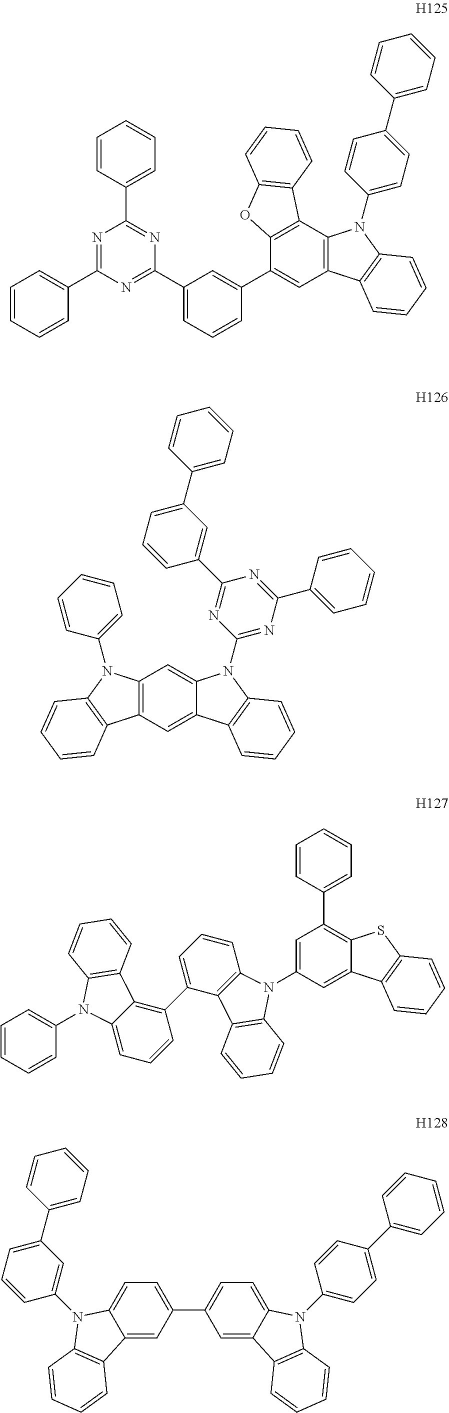 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

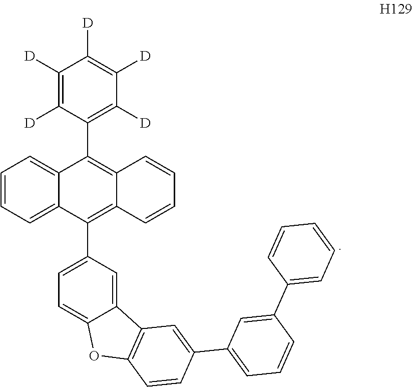 [SMILES: [2H]c1c([2H])c([2H])c(-c2c3ccccc3c(-c3ccc4oc5ccc(-c6cccc(-c7ccccc7)c6)cc5c4c3)c3ccccc23)c([2H])c1[2H]]

In an embodiment, the host may include a silicon-containing compound, a phosphine oxide-containing compound, or any combination thereof.

The host may have various modifications. For example, the host may include only one kind of compound, or may include two or more kinds of different compounds.

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

M(L₄₀₁)_{xc1}(L₄₀₂)_{xc2} [Formula 401]

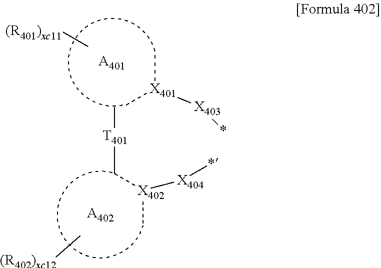

### In Formulae 401 and 402,

M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, in case that xc1 is 2 or more, two or more of L₄₀₁ may be identical to or different from each other,
L₄₀₂ may be an organic ligand, and xc2 may be 0, 1, 2, 3, or 4, wherein, in case that xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—, *—C(═O)—*, *—N(Q₄₁₁)*′, *—C(Q₄₁₁)(Q₄₁₂)-*′, *—C(Q₄₁₁)=C(Q₄₁₂)-*′, *—C(Q₄₁₁)=*′, or *=C(Q₄₁₁)=*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently the same as described in connection with Q₁,
xc11 and xc12 may each independently be an integer from 0 to 10, and
* and *′ in Formula 402 each indicates a binding site to M in Formula 401.

In an embodiment, in Formula 402, X₄₀₁ may be nitrogen and X₄₀₂ may be carbon, or X₄₀₁ and X₄₀₂ may each be nitrogen.

In an embodiment, in Formula 402, in case that xc1 is 2 or more, two of ring A₄₀₁ in two or more of L₄₀₁ may be optionally linked to each other via T₄₀₂, which is a linking group, or two of ring A₄₀₂ in two or more of L₄₀₁ may be optionally linked to each other via T₄₀₃, which is a linking group (see Compounds PD1 to PD4 and PD7). T₄₀₂ and T₄₀₃ may each independently the same as described in connection with T₄₀₁.
in Formula 401, L₄₀₂ may be an organic ligand. In an embodiment, L₄₀₂ may include a halogen group, a diketone group (e.g., an acetylacetonate group), a carboxylic acid group (e.g., a picolinate group), —C(═O), an isonitrile group, a —CN group, a phosphorus group (e.g., a phosphine group, a phosphite group, etc.), or any combination thereof.

The phosphorescent dopant may include, for example, one of Compounds PD1 to PD39, or any combination thereof:

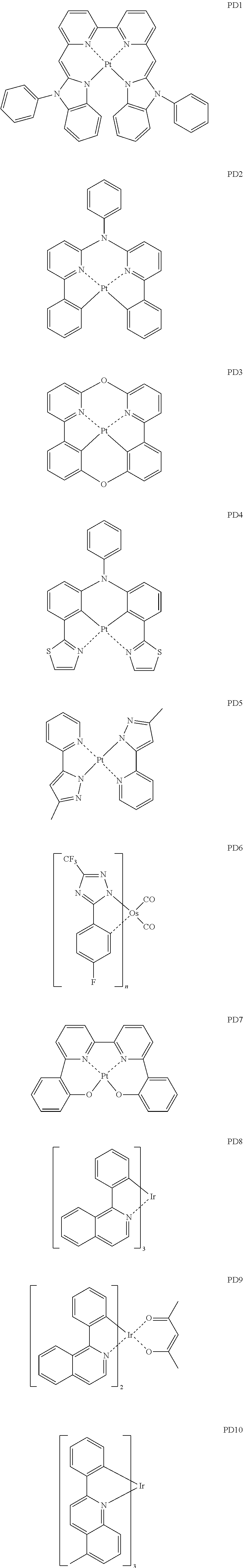

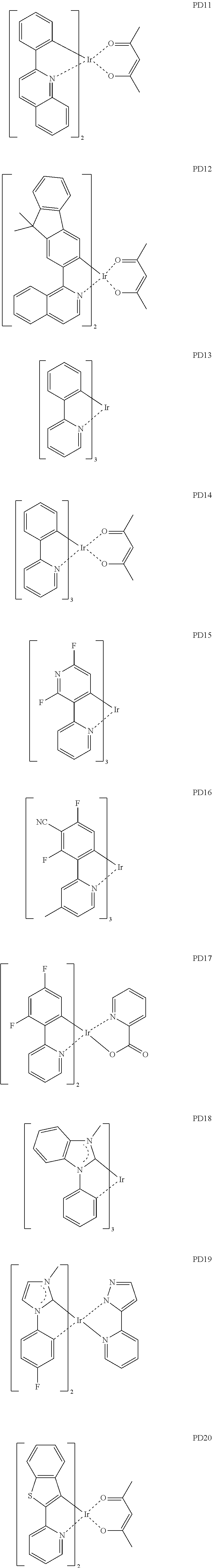

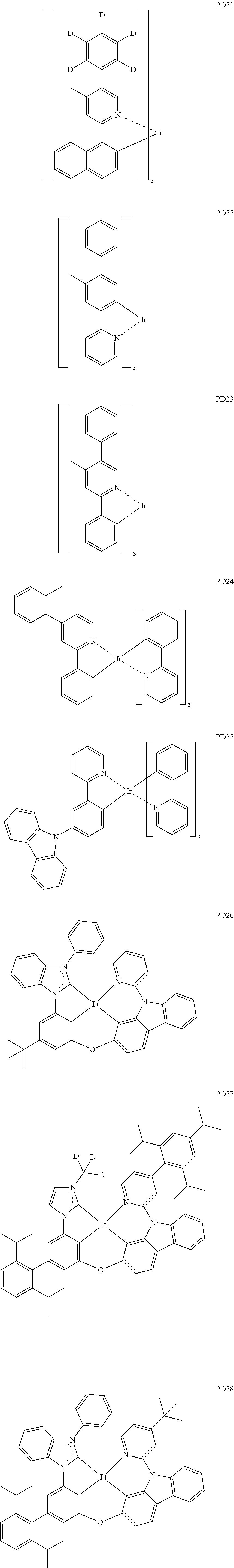

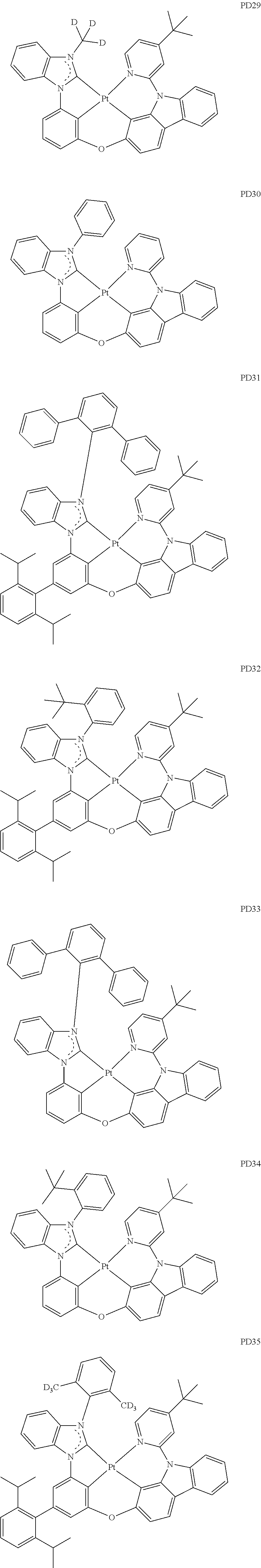

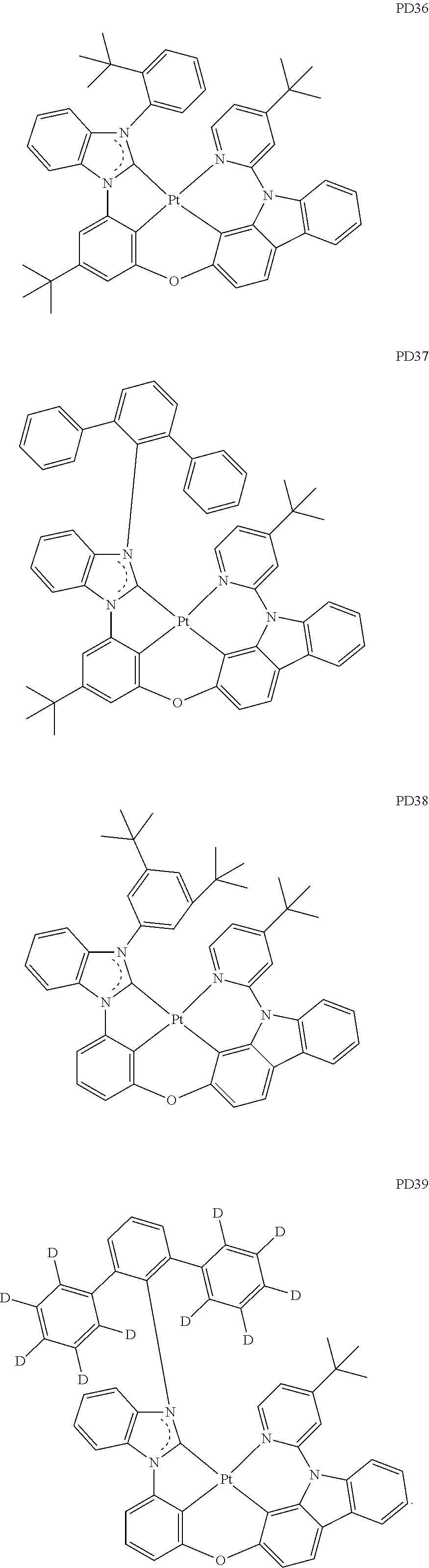

### [Fluorescent Dopant]

The fluorescent dopant may include an amine group-containing compound, a styryl group-containing compound, or any combination thereof.

In an embodiment, the fluorescent dopant may include a compound represented by Formula 501:

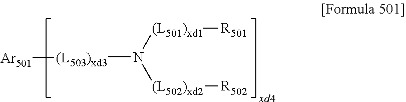

### In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (e.g., an anthracene group, a chrysene group, a pyrene group, etc.) in which three or more monocyclic groups are condensed with each other.

In an embodiment, in Formula 501, xd4 may be 2.

In an embodiment, the fluorescent dopant may include: one of Compounds FD1 to FD37; DPVBi; DPAVBi; or any combination thereof:

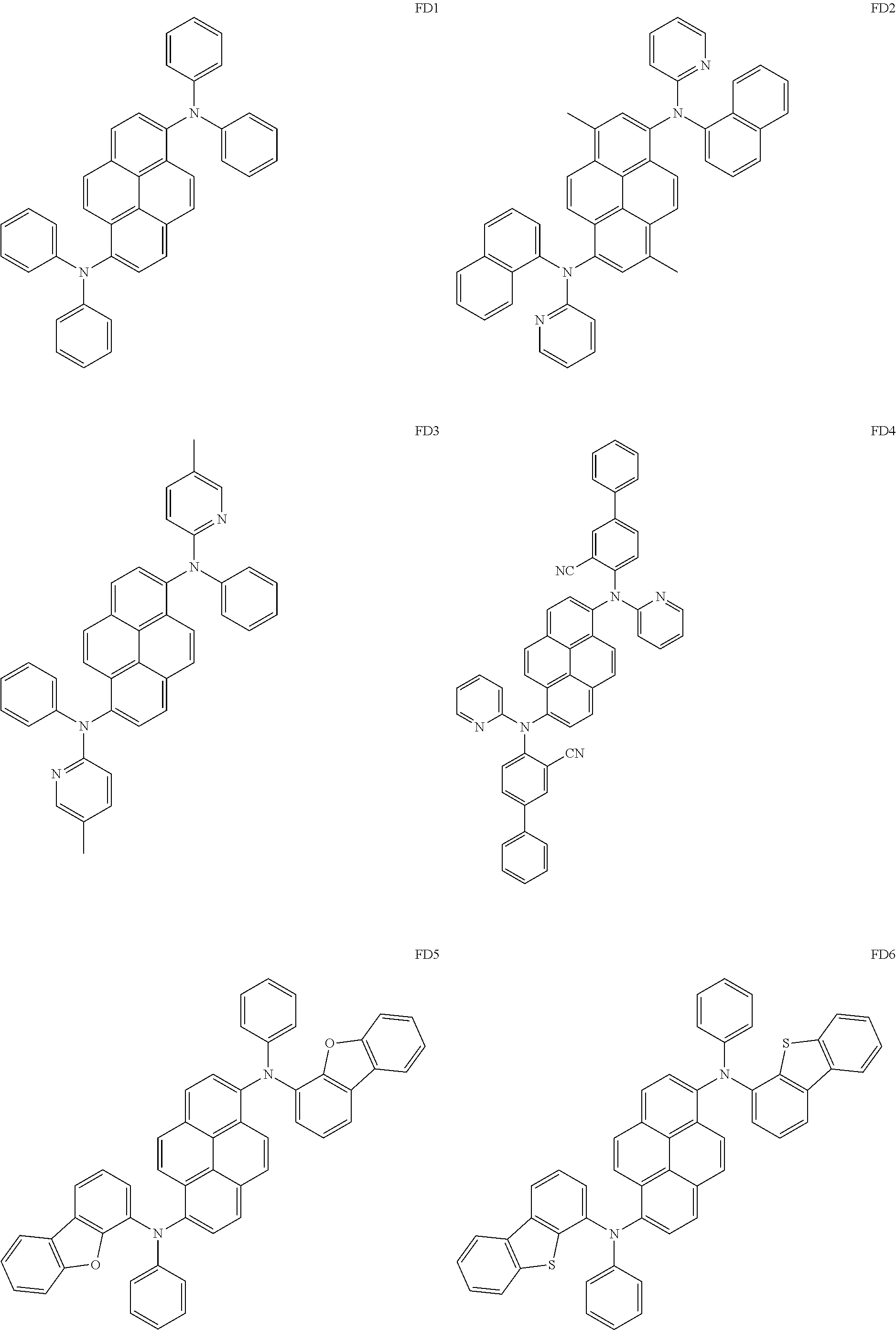

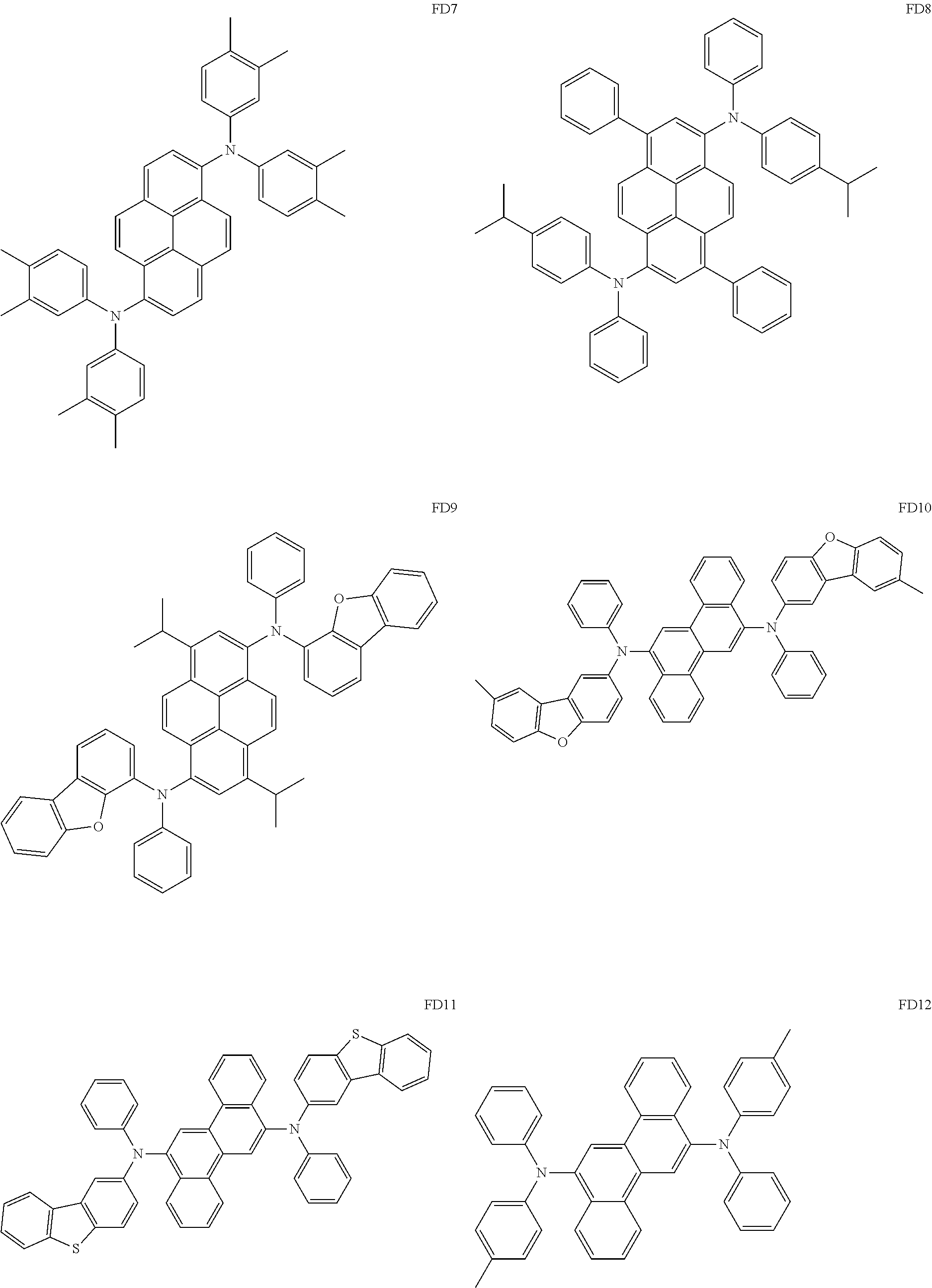

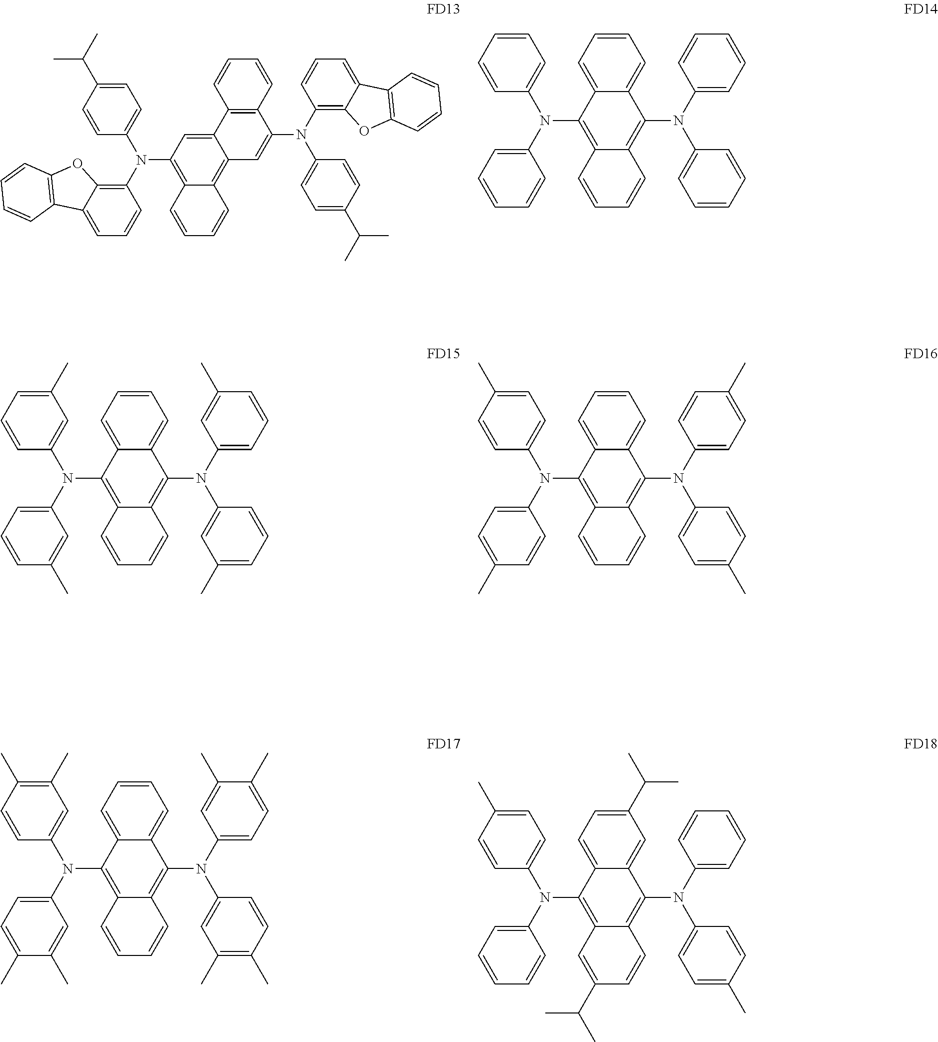

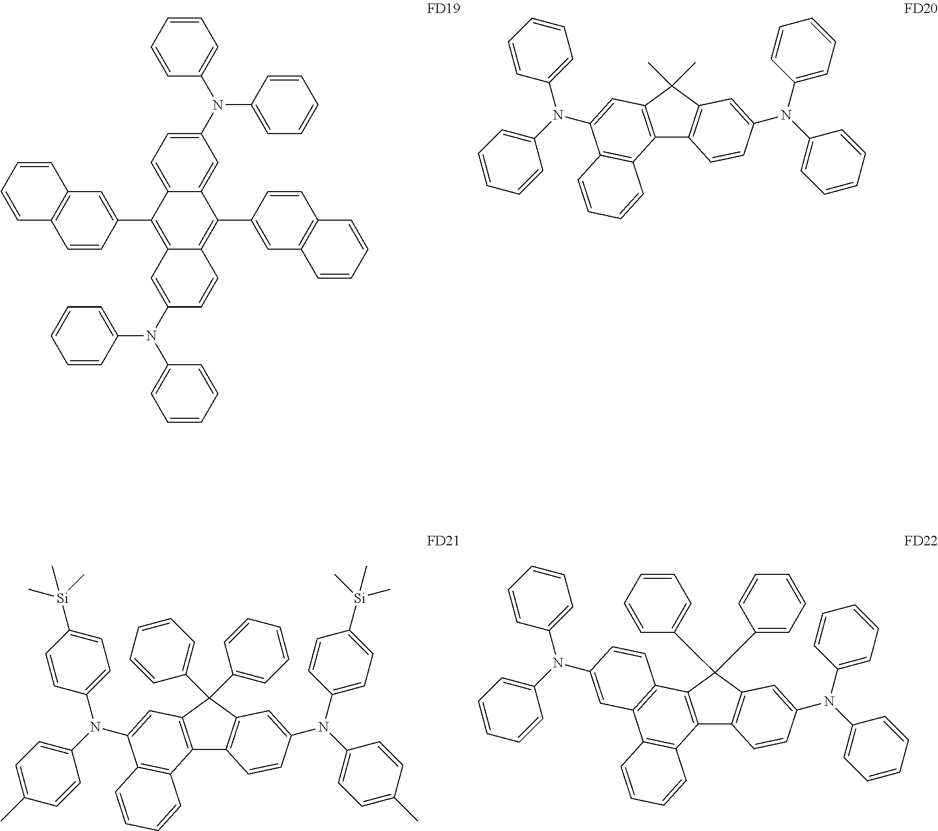

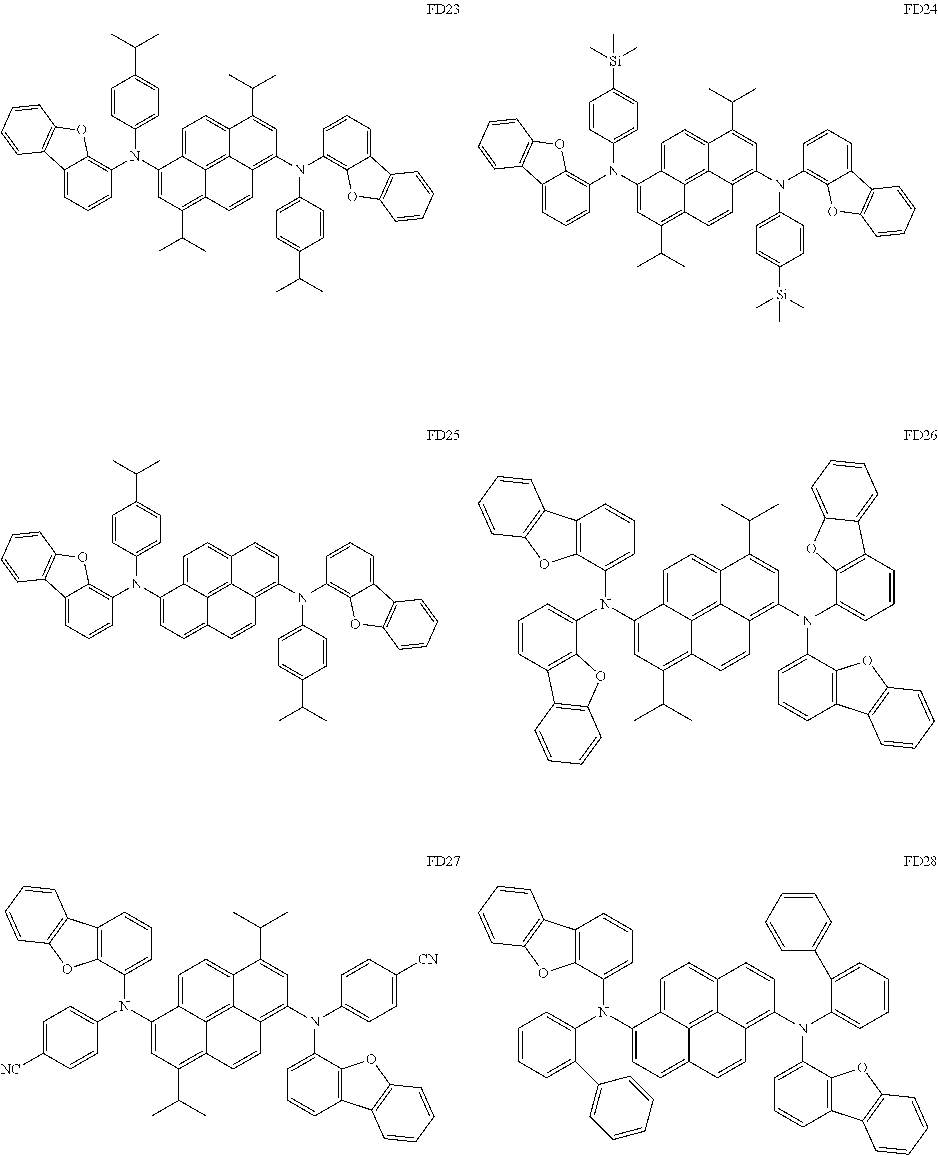

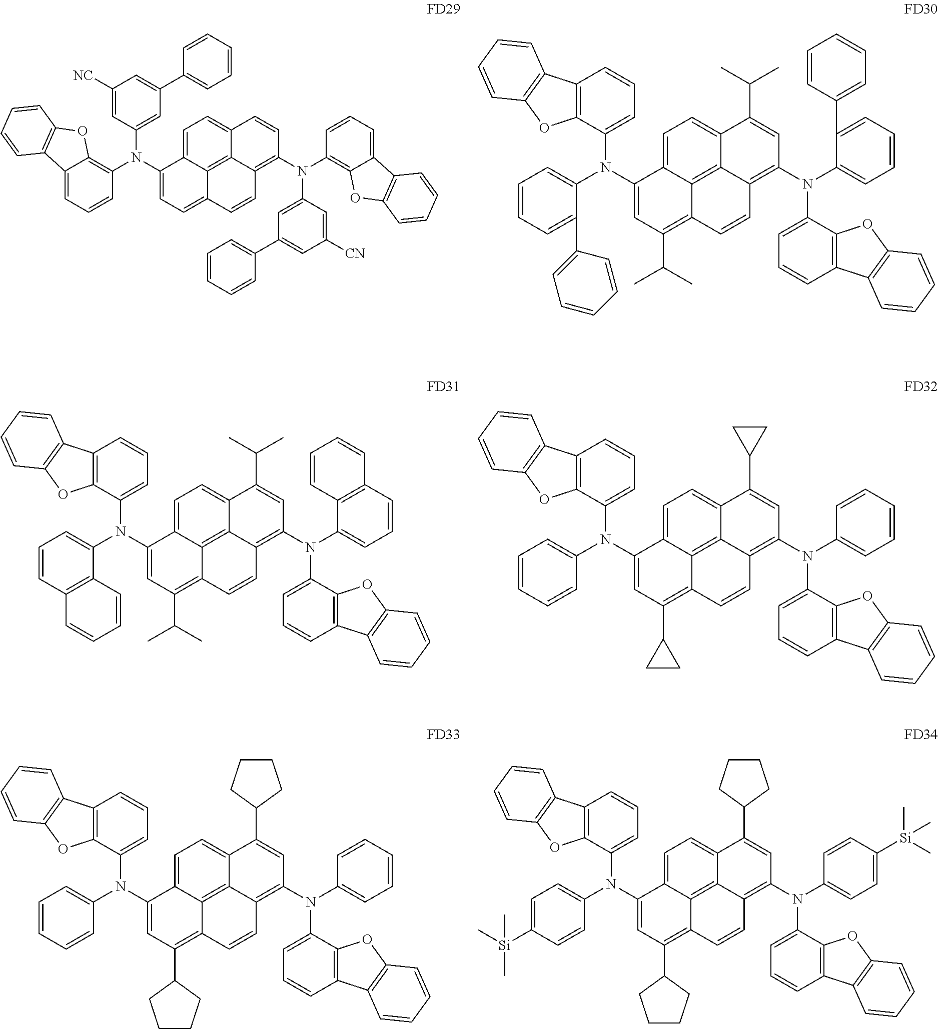

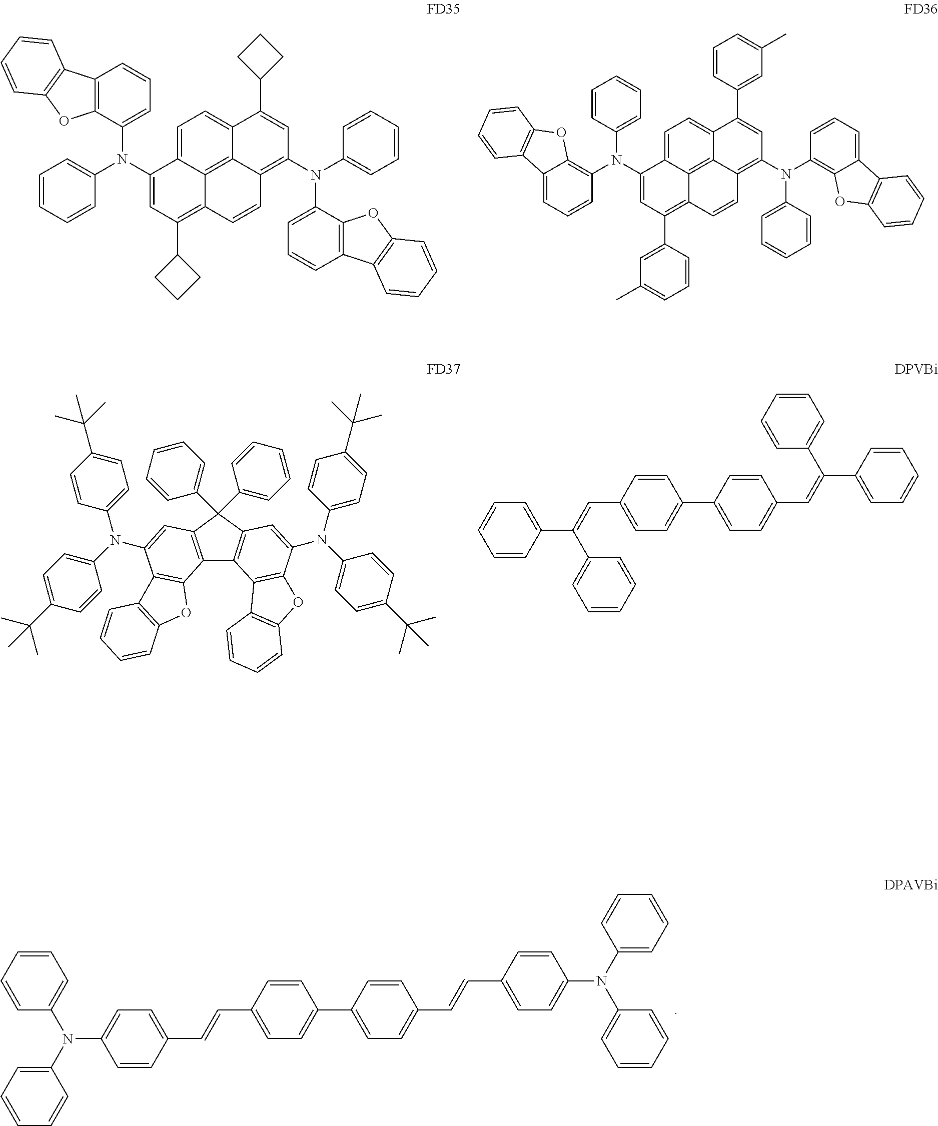

### [Delayed Fluorescence Material]

The emission layer may include a delayed fluorescence material.

The delayed fluorescence material described herein may be selected from compounds capable of emitting delayed fluorescence based on a delayed fluorescence emission mechanism.

A delayed fluorescence material included in the emission layer may serve as a host or a dopant depending on the type of other materials included in the emission layer.

In an embodiment, the difference between a triplet energy level (eV) of a delayed fluorescence material and a singlet energy level (eV) of the delayed fluorescence material may be in a range of about 0 eV to about 0.5 eV. In case that the difference between a triplet energy level (eV) of the delayed fluorescence material and a singlet energy level (eV) of the delayed fluorescence material is within the range described above, up-conversion from the triplet state to the singlet state of the delayed fluorescence material may effectively occur, and thus, the light-emitting device 10 may have improved luminescence efficiency.

In an embodiment, the delayed fluorescence material may include a material including at least one electron donor (e.g., a π electron-rich C₃-C₆₀ cyclic group, such as a carbazole group, etc.) and at least one electron acceptor (e.g., a sulfoxide group, a cyano group, a π electron-deficient nitrogen-containing C₁-C₆₀ cyclic group, etc.), a material including a C₈-C₆₀ polycyclic group in which two or more cyclic groups are condensed while sharing boron (B), and the like.

Examples of a delayed fluorescence material may include at least one of Compounds DF1 to DF14:

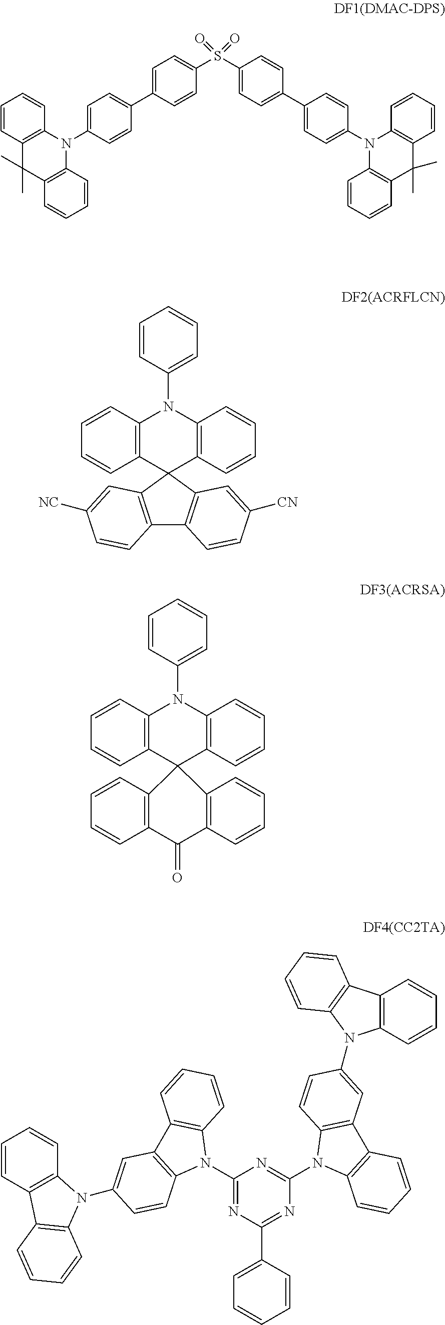 [SMILES: CC1(C)c2ccccc2N(c2ccc(-c3ccc(S(=O)(=O)c4ccc(-c5ccc(N6c7ccccc7C(C)(C)c7ccccc76)cc5)cc4)cc3)cc2)c2ccccc21 ; N#Cc1ccc2c(c1)C1(c3cc(C#N)ccc3-2)c2ccccc2N(c2ccccc2)c2ccccc21 ; O=C1c2ccccc2C2(c3ccccc31)c1ccccc1N(c1ccccc1)c1ccccc12 ; c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1]

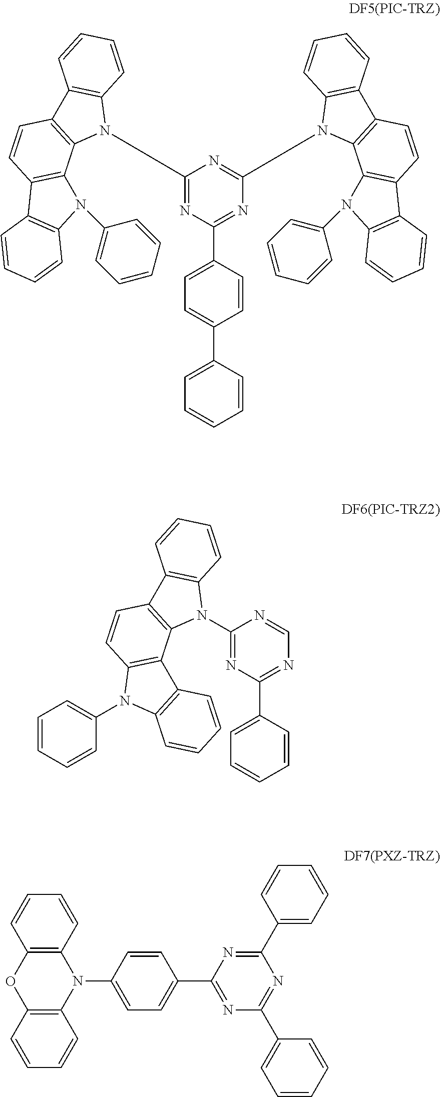 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2ncnc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

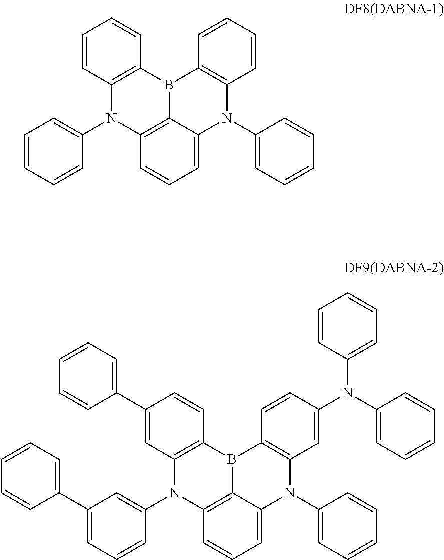 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

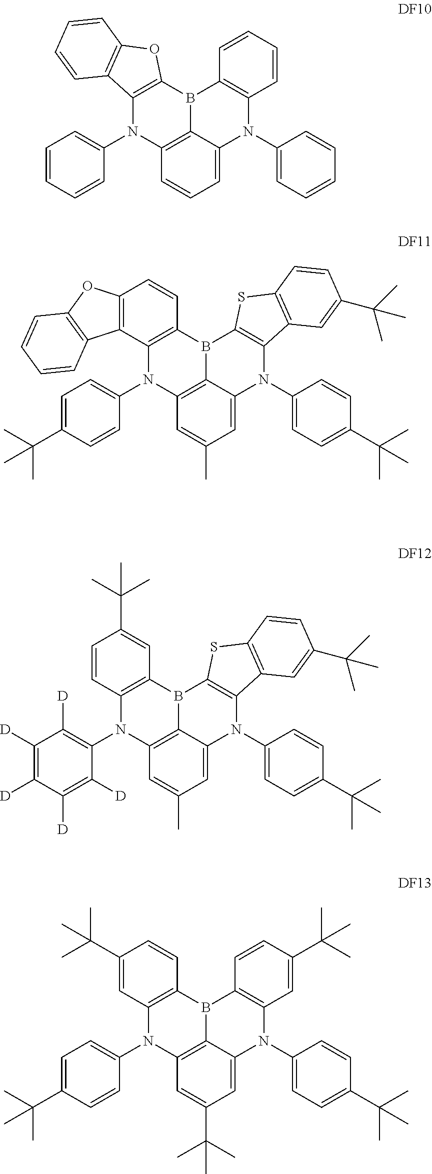

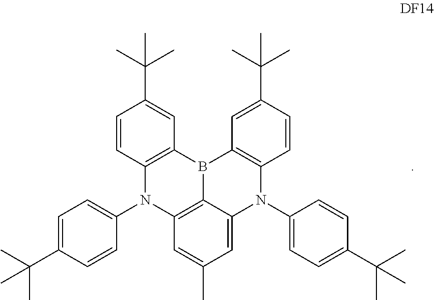 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### [Quantum Dots]

The emission layer may include quantum dots.

In the specification, a quantum dot may be a crystal of a semiconductor compound, and may include any material capable of emitting light of various emission wavelengths according to a size of the crystals. Quantum dots may emit light of various emission wavelengths by adjusting a ratio of elements in a quantum dot compound.

A diameter of the quantum dots may be, for example, in a range of about 1 nm to about 10 nm.

The quantum dots may be synthesized by a wet chemical process, a metal organic chemical vapor deposition process, a molecular beam epitaxy process, or any process similar thereto.

The wet chemical process is a method including mixing a precursor material with an organic solvent and growing quantum dot particle crystals. When the crystals grow, the organic solvent naturally acts as a dispersant coordinated on the surface of the quantum dot crystals and controls the growth of the crystals so that the growth of quantum dot particles may be controlled through a process which costs less and may be more readily performed than vapor deposition methods, such as metal organic chemical vapor deposition (MOCVD) or molecular beam epitaxy (MBE).

The quantum dots may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, MgS, or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or the like; a quaternary compound, such as CdZnSeS, CdZnSeTe, CdZnSTe, CdHgSeS, CdHgSeTe, CdHgSTe, HgZnSeS, HgZnSeTe, HgZnSTe, or the like; or any combination thereof.

Examples of a Group III-V semiconductor compound may include: a binary compound, such as GaN, GaP, GaAs, GaSb, AlN, AlP, AlAs, AlSb, InN, InP, InAs, InSb, or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like; or any combination thereof. In an embodiment, the Group III-V semiconductor compound may further include a Group II element.

Examples of a Group III-V semiconductor compound further including a Group II element may include InZnP, InGaZnP, InAlZnP, and the like.

Examples of a Group III-VI semiconductor compound may include: a binary compound, such as GaS, GaSe, Ga₂Se₃, GaTe, InS, InSe, In₂S₃, In₂Se₃, InTe, or the like; a ternary compound, such as InGaS₃, InGaSe₃, or the like; or any combination thereof.

Examples of a Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, or the like; a ternary compound, such as AgInGaS₂, AgInGaSe₂, or the like; or any combination thereof.

Examples of a Group IV-VI semiconductor compound may include: a binary compound, such as SnS, SnSe, SnTe, PbS, PbSe, PbTe, or the like; a ternary compound, such as SnSeS, SnSeTe, SnSTe, PbSeS, PbSeTe, PbSTe, SnPbS, SnPbSe, SnPbTe, or the like; a quaternary compound, such as SnPbSSe, SnPbSeTe, SnPbSTe, or the like; or any combination thereof.

Examples of a Group IV element or compound may include: a single element material, such as Si, Ge, or the like; a binary compound, such as SiC, SiGe, or the like; or any combination thereof.

Each element included in a multi-element compound, such as a binary compound, a ternary compound, and a quaternary compound, may be present in a particle at a uniform concentration or non-uniform concentration. For example, the formulae above refer to the types of elements included in the compound, wherein the ratio of elements in the compound may vary. For example, AgInₓGa₁₋ₓS₂ (where x is a real number between 0 and 1) may be AgInGaS₂.

In an embodiment, the quantum dots may have a single structure in which the concentration of each element in the quantum dots is uniform, or the quantum dot may have a core-shell dual structure. In an embodiment, in case that the quantum dot has a core-shell structure, a material included in the core and a material included in the shell may be different from each other.

The shell of the quantum dots may serve as a protective layer that prevents chemical degeneration of the core to maintain semiconductor characteristics, and/or may serve as a charging layer that imparts electrophoretic characteristics to the quantum dots. The shell may be a single layer or a multi-layer. An interface between the core and the shell may have a concentration gradient in which the concentration of a material that is present in the shell decreases toward the core.

Examples of the shell of the quantum dots may include a metal oxide, a metalloid oxide, a non-metal oxide, a semiconductor compound; or any combination thereof. Examples of the metal oxide, the metalloid oxide, or the non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like; a ternary compound, such as MgAl₂O₄, CoFe₂O₄, NiFe₂O₄, CoMn₂O₄, or the like; or any combination thereof.

Examples of the semiconductor compound may include as described herein, a Group II-VI semiconductor compound, a Group III-V semiconductor compound, a Group II-VI semiconductor compound, a Group I-III-VI semiconductor compound, a Group IV-VI semiconductor compound, or any combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

Each element included in a multi-element compound, such as a binary compound and a ternary compound, may be present in a particle at a uniform concentration or non-uniform concentration. For example, the formulae above refer to the types of elements included in the compound, wherein the ratio of elements in the compound may vary.

A full width at half maximum (FWHM) of an emission wavelength spectrum of the quantum dots may be less than or equal to about 45 nm. For example, a FWHM of an emission wavelength spectrum of the quantum dots may be less than or equal to about 40 nm. For example, a FWHM of an emission wavelength spectrum of the quantum dots may be less than or equal to about 30 nm. Within these ranges, the color purity or color reproducibility of the quantum dots may be improved. Since light emitted through the quantum dots is emitted in all directions, the wide viewing angle may be improved.

The quantum dots may be in the form of a spherical particle, a pyramidal particle, a multi-arm particle, a cubic nanoparticle, a nanotube particle, a nanowire particle, a nanofiber particle, a nanoplate particle, or the like.

Since the energy band gap may be controlled by adjusting the size of the quantum dots or the ratio of elements in the quantum dot compound, light of various wavelengths may be obtained from a quantum dot-containing emission layer. Accordingly, by using the quantum dots as described above (by using quantum dots of different sizes or by varying the ratio of elements in the quantum dot compound), a light-emitting device that emits light of various wavelengths may be implemented. In detail, the size of the quantum dots may be selected to emit red light, green light, and/or blue light. The size of the quantum dots may be configured to emit white light by a combination of light of various colors.

### [Electron Transport Region in Interlayer 130]

The electron transport region may have a structure consisting of a layer consisting of a single material, a structure consisting of a layer including multiple materials that are different from each other, or a structure including multiple layers including multiple materials that are different from each other.

The electron transport region may include a buffer layer, a hole blocking layer, an electron control layer, an electron transport layer, an electron injection layer, or any combination thereof.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may be stacked from an emission layer in its respective stated order, but the structure of the electron transport region is not limited thereto.

The electron transport region (e.g., a buffer layer, a hole blocking layer, an electron control layer, or an electron transport layer in the electron transport region) may include a metal-free compound including at least one π electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁ [Formula 601]

### In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, in case that xe11 is 2 or more, two or more of Ar₆₀₁ may be linked to each other via a single bond.

In an embodiment, in Formula 601, Ar₆₀₁ may be an anthracene group unsubstituted or substituted with at least one R₁₀ₐ.

In an embodiment, the electron transport region may include a compound represented by Formula 601-1:

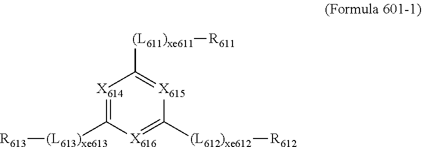

### In Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently the same as described in connection with L₆₀₁,
xe611 to xe613 may each independently the same as described in connection with xe1,
R₆₁₁ to R₆₁₃ may each independently the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formulae 601 and 601-1, xe1 and xe611 to xe613 may each independently be 0, 1, or 2.

The electron transport region may include one of Compounds ET1 to ET47, 2,9-dimethyl-4,7-diphenyl-1,10-phenanthroline (BCP); 4,7-diphenyl-1,10-phenanthroline (Bphen), Alq₃, BAlq, TAZ, NTAZ, or any combination thereof:

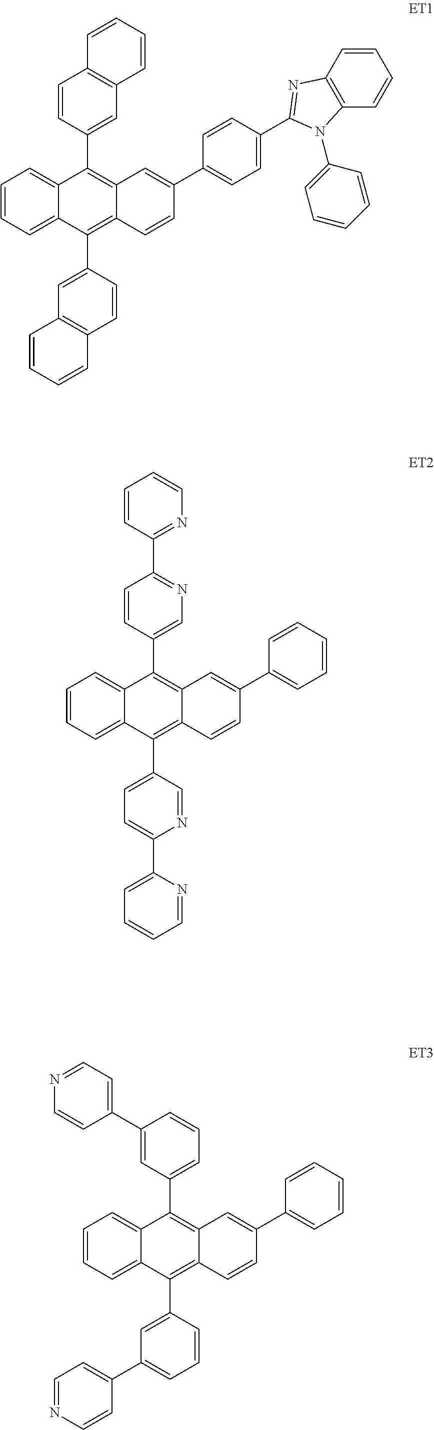 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

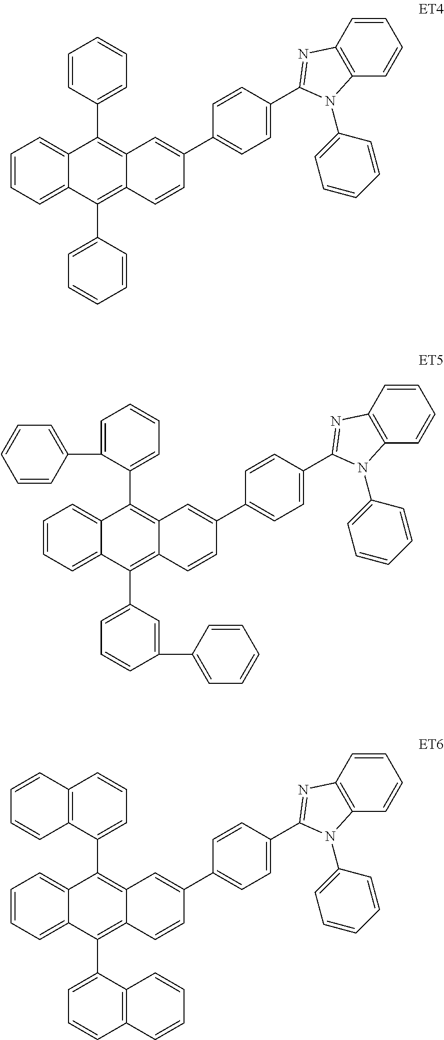 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2cccc(-c3c4ccccc4c(-c4ccccc4-c4ccccc4)c4cc(-c5ccc(-c6nc7ccccc7n6-c6ccccc6)cc5)ccc34)c2)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

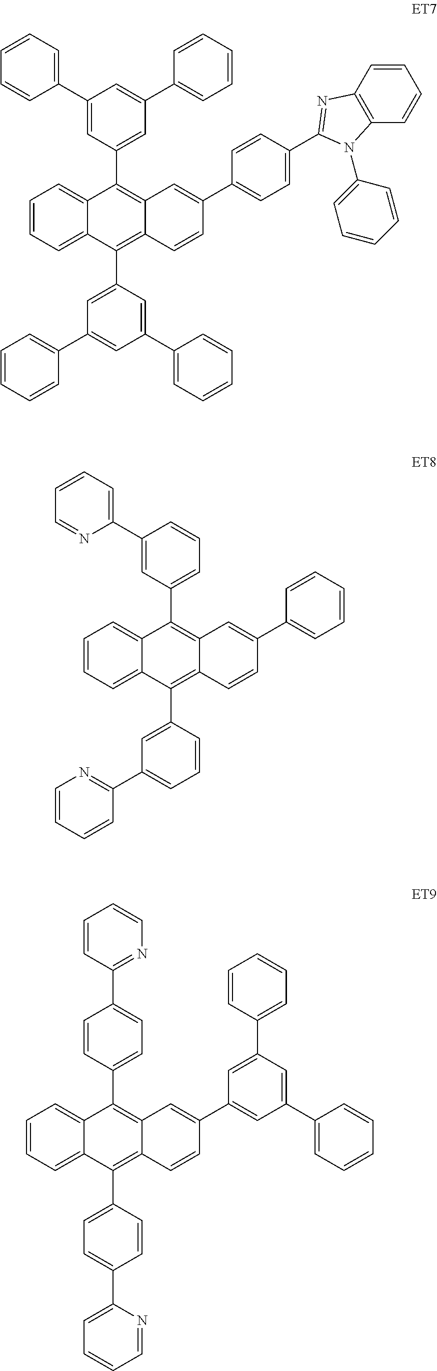 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2ccc3c(-c4cccc(-c5ccccn5)c4)c4ccccc4c(-c4cccc(-c5ccccn5)c4)c3c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

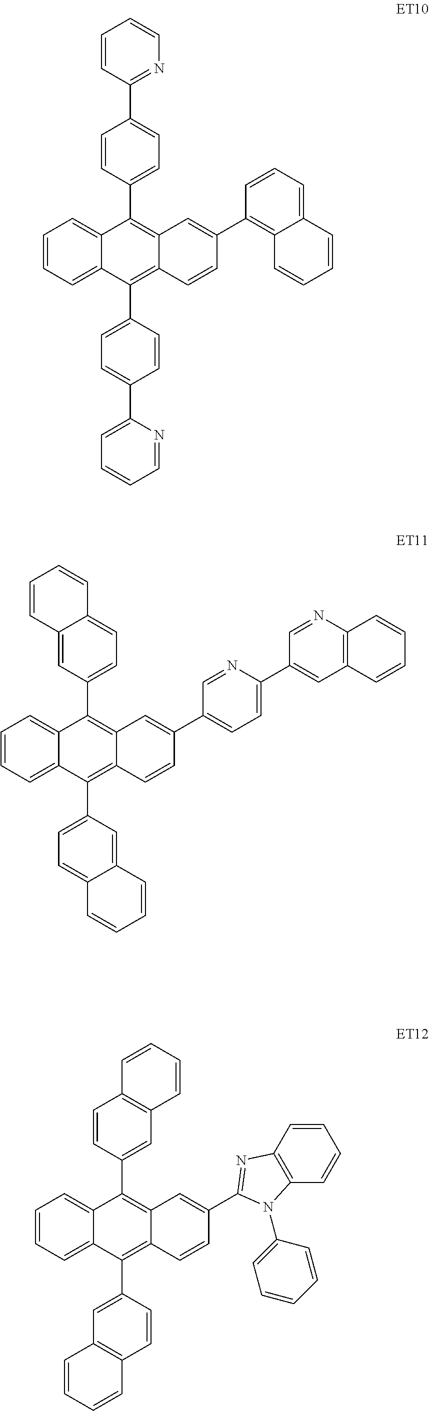 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

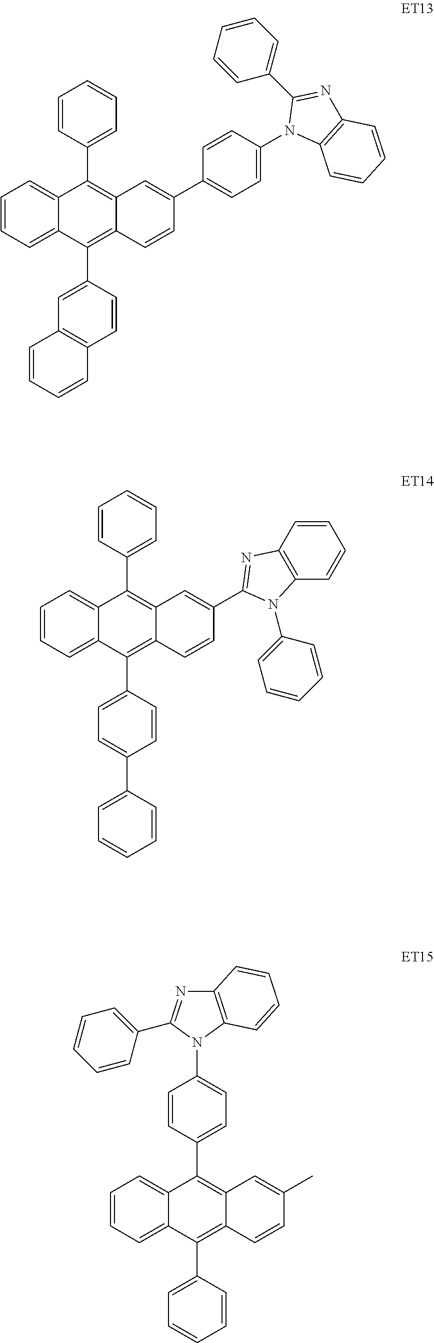 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

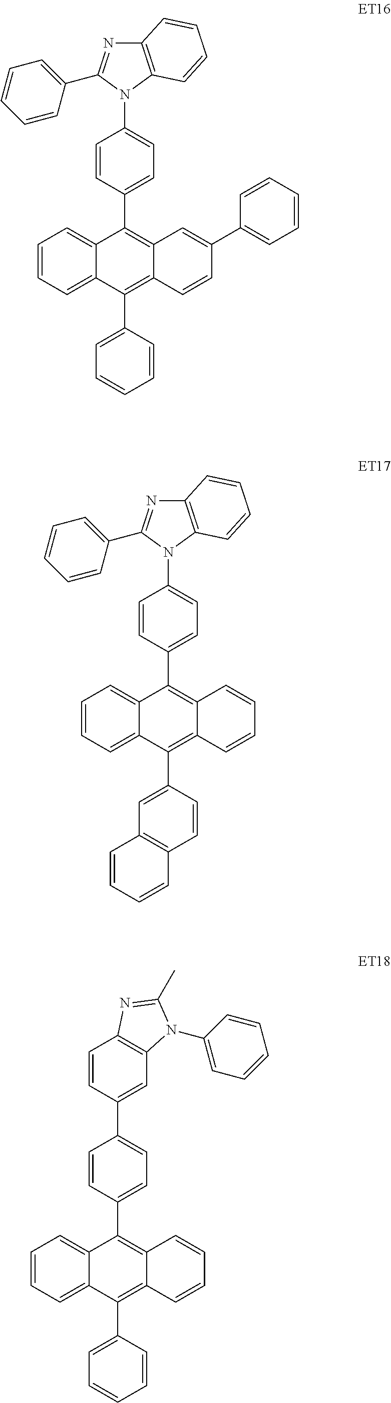 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

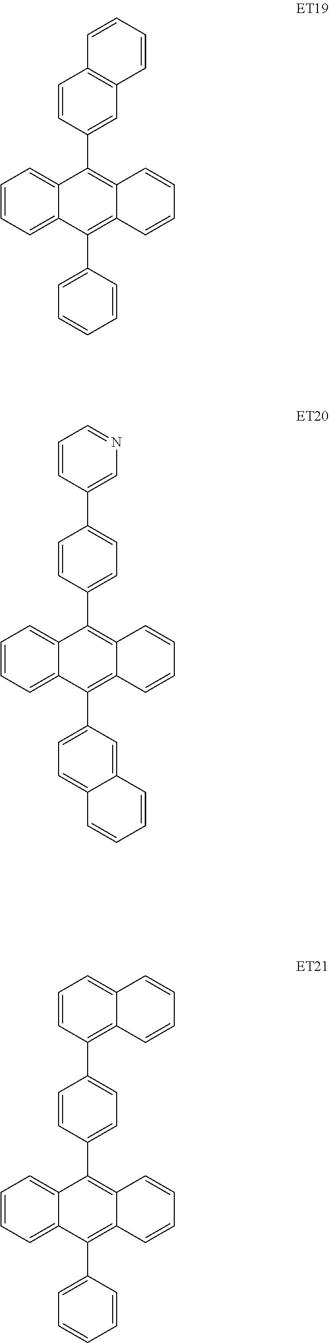

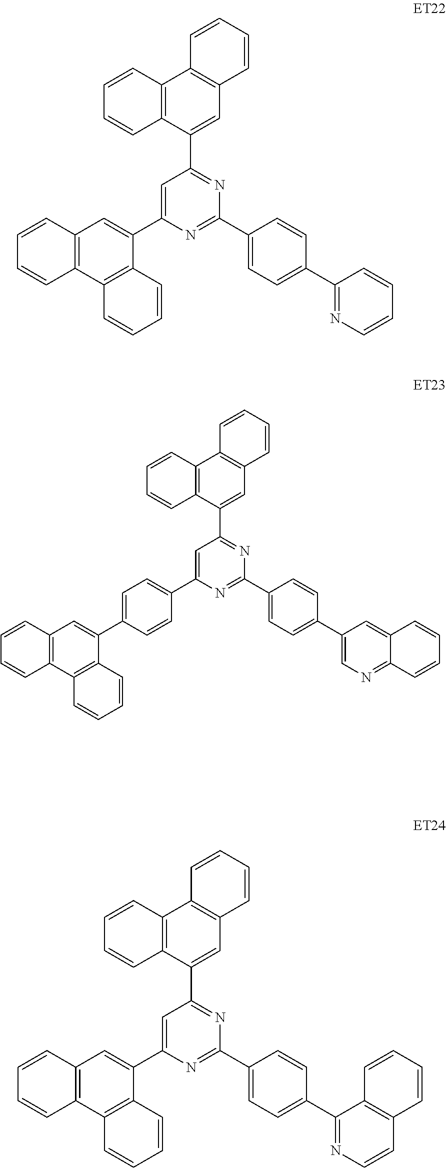 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

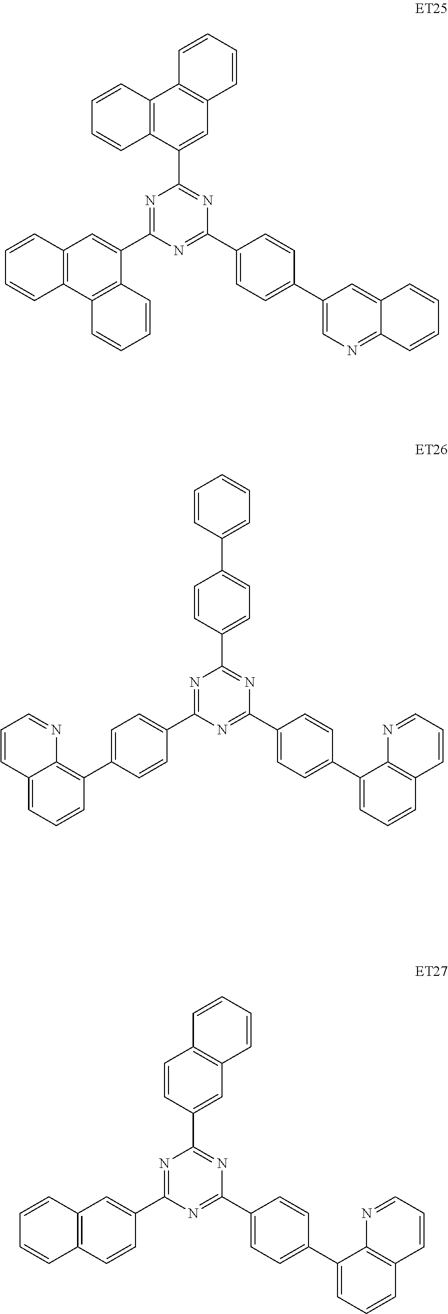 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

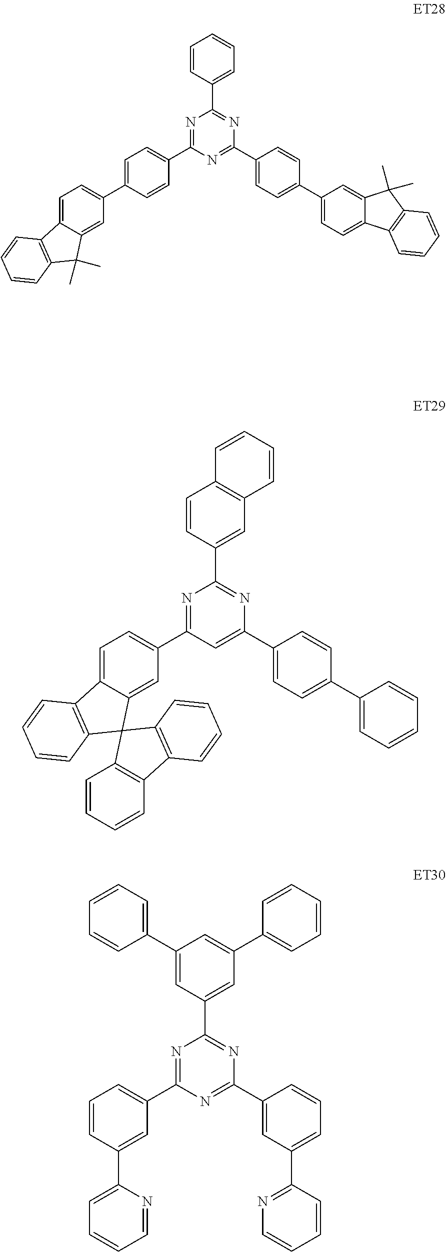 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

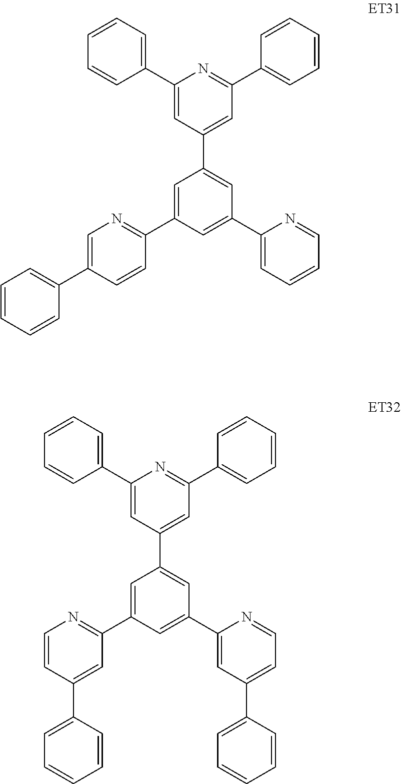 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

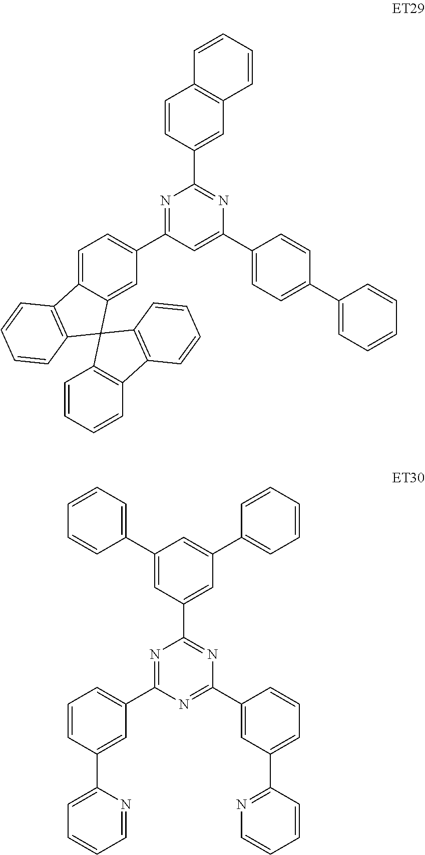 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

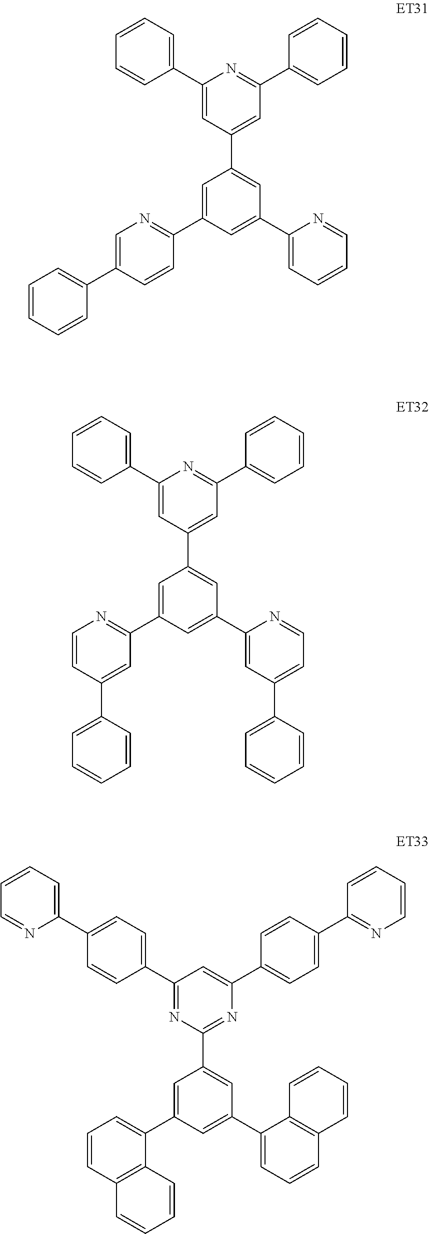 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

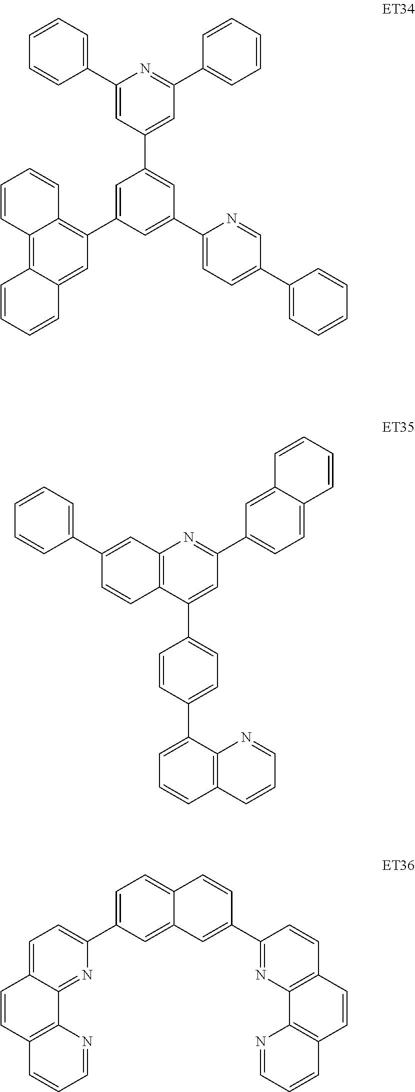 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

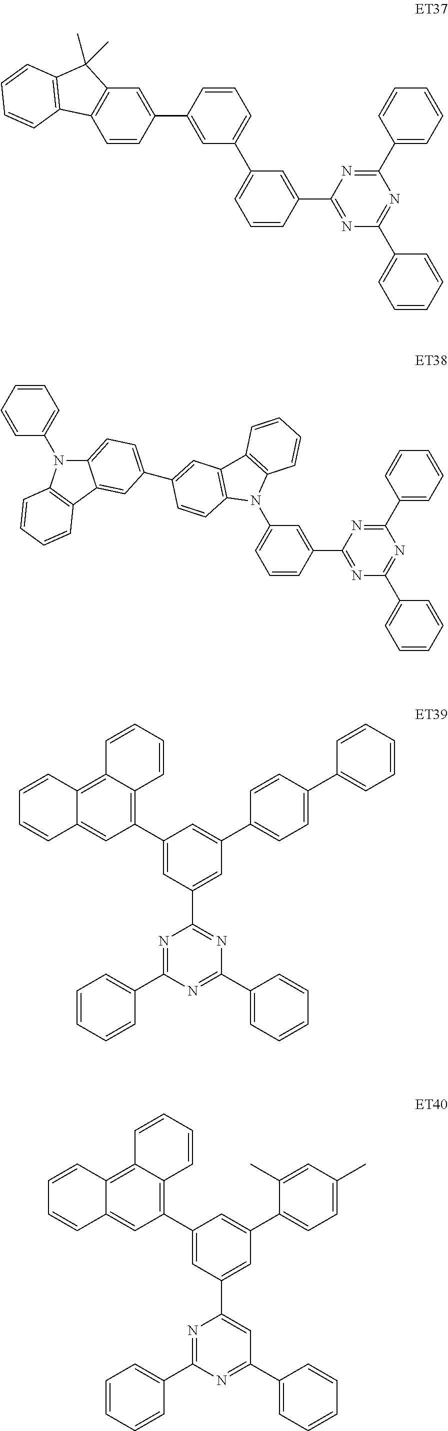 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

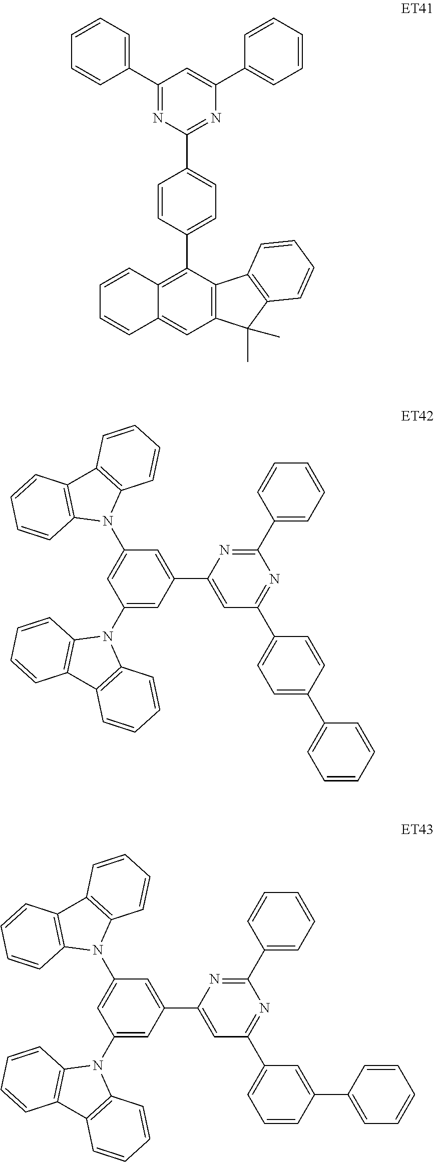 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

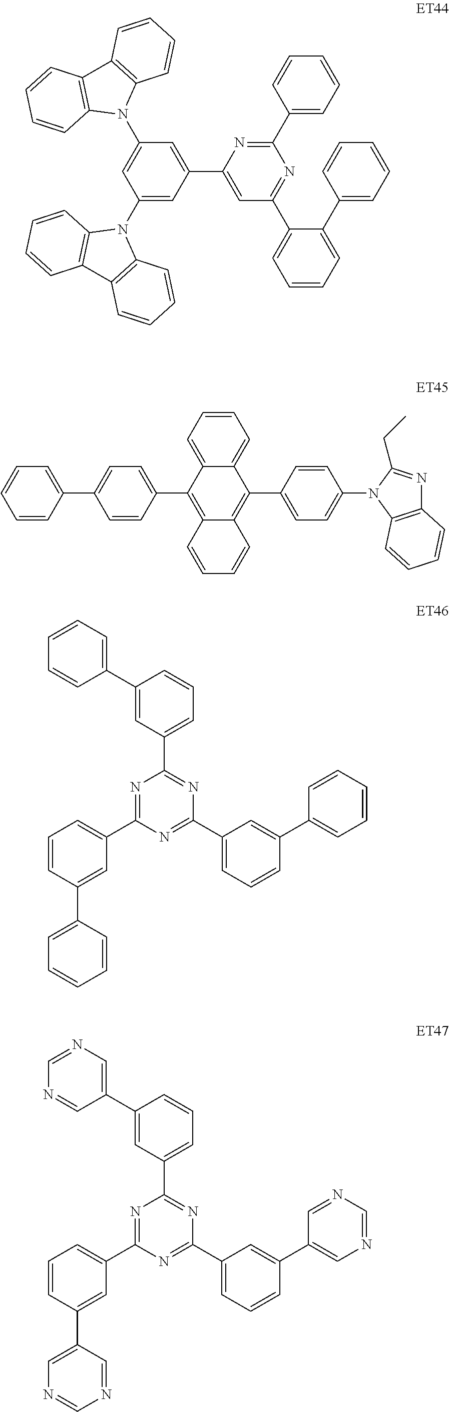 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1 ; c1ccc(-c2cccc(-c3nc(-c4cccc(-c5ccccc5)c4)nc(-c4cccc(-c5ccccc5)c4)n3)c2)cc1 ; c1cc(-c2cncnc2)cc(-c2nc(-c3cccc(-c4cncnc4)c3)nc(-c3cccc(-c4cncnc4)c3)n2)c1]

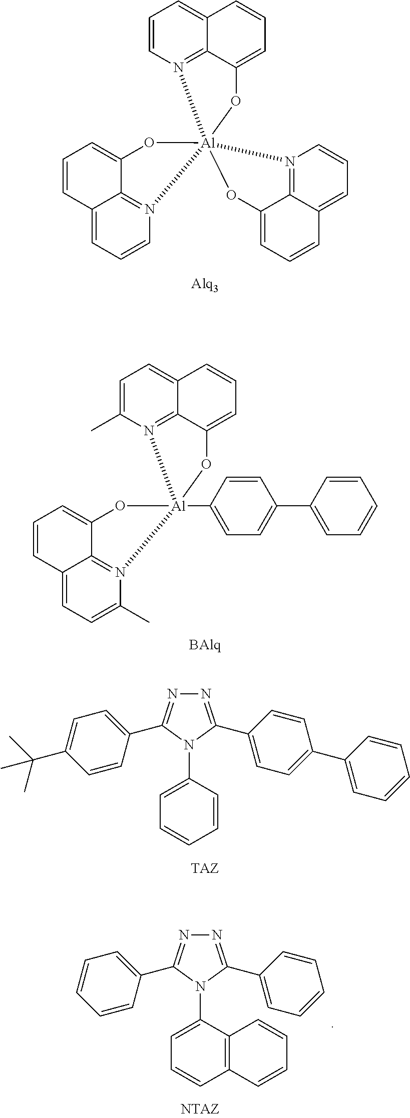

A thickness of the electron transport region may be in a range of about 100 Å to about 5,000 Å. For example, the thickness of the electron transport region may be in a range of about 160 Å to about 4,000 Å. In case that the electron transport region includes a buffer layer, a hole blocking layer, an electron control layer, an electron transport layer, or any combination thereof, a thickness of the buffer layer, the hole blocking layer, or the electron control layer may be in a range of about 20 Å to about 1,000 Å. For example, the thickness of the buffer layer, the hole blocking layer, or the electron control layer may each independently be in a range of about 30 Å to about 300 Å. For example, a thickness of the electron transport layer may be in a range of about 100 Å to about 1,000 Å. For example, the thickness of the electron transport layer may be in a range of about 150 Å to about 500 Å. In case that the thicknesses of the buffer layer, the hole blocking layer, the electron control layer, the electron transport layer, and/or the electron transport region are within the ranges described above, satisfactory electron transporting characteristics may be obtained without a substantial increase in driving voltage.

The electron transport region (e.g., an electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or with the metal ion of the alkaline earth-metal complex may each independently include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

In an embodiment, the metal-containing material may include a Li complex. The Li complex may include, for example, Compound ET-D1 (LiQ) or Compound ET-D2:

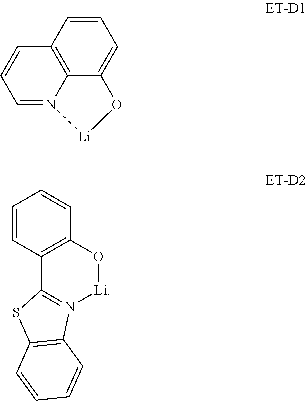

The electron transport region may include an electron injection layer that facilitates the injection of electrons from the second electrode 150.

The electron injection layer may be in direct contact with the second electrode 150.

The electron injection layer may have a structure consisting of a layer consisting of a single material, a structure consisting of a layer including multiple materials that are different from each other, or a structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, etc.), or tellurides of the alkali metal, the alkaline earth metal, and the rare earth metal, or any combination thereof.

The alkali metal-containing compound may include: alkali metal oxide, such as Li₂O, Cs₂O, K₂O, or the like; alkali metal halide, such as LiF, NaF, CsF, KF, LiI, NaI, CsI, KI, or the like; or any combination thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include one of an alkali metal ion, an alkaline earth metal ion, and a rare earth metal ion, and a ligand bonded to the metal ion) for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (e.g., a compound represented by Formula 601).

In an embodiment, the electron injection layer may consist of an alkali metal-containing compound (e.g., alkali metal halide), or the electron injection layer may consist of an alkali metal-containing compound (e.g., alkali metal halide); and an alkali metal, an alkaline earth metal, a rare earth metal, or any combination thereof. For example, the electron injection layer may be a KI:Yb co-deposited layer, an RbI:Yb co-deposited layer, a LiF:Yb co-deposited layer, or the like.

In case that the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. In case that the thickness of the electron injection layer is within the range described above, satisfactory electron injection characteristics may be obtained without a substantial increase in driving voltage.

### [Second Electrode 150]

The second electrode 150 may be arranged on the interlayer 130 having a structure as described above. The second electrode 150 may be a cathode, which is an electron injection electrode. A material for forming the second electrode 150 may be a material having a low work function, such as a metal, an alloy, an electrically conductive compound, or any combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layer structure or a multi-layer structure including multiple layers.

### [Capping Layer]

The light-emitting device 10 may include a first capping layer outside the first electrode 110, and/or a second capping layer the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in the emission layer in the interlayer 130 of the light-emitting device 10 may be extracted toward the outside through the first electrode 110, which may be a transflective electrode or a transmissive electrode, and through the first capping layer. Light generated in the emission layer in the interlayer 130 of the light-emitting device 10 may be extracted toward the outside through the second electrode 150, which may be a transflective electrode or a transmissive electrode, and through the second capping layer.

The first capping layer and the second capping layer may each increase external emission efficiency according to the principle of constructive interference. Accordingly, the light extraction efficiency of the light-emitting device 10 may be increased, so that the luminescence efficiency of the light-emitting device 10 may be improved.

The first capping layer and the second capping layer may each include a material having a refractive index greater than or equal to about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP7, β-NPB, or any combination thereof:

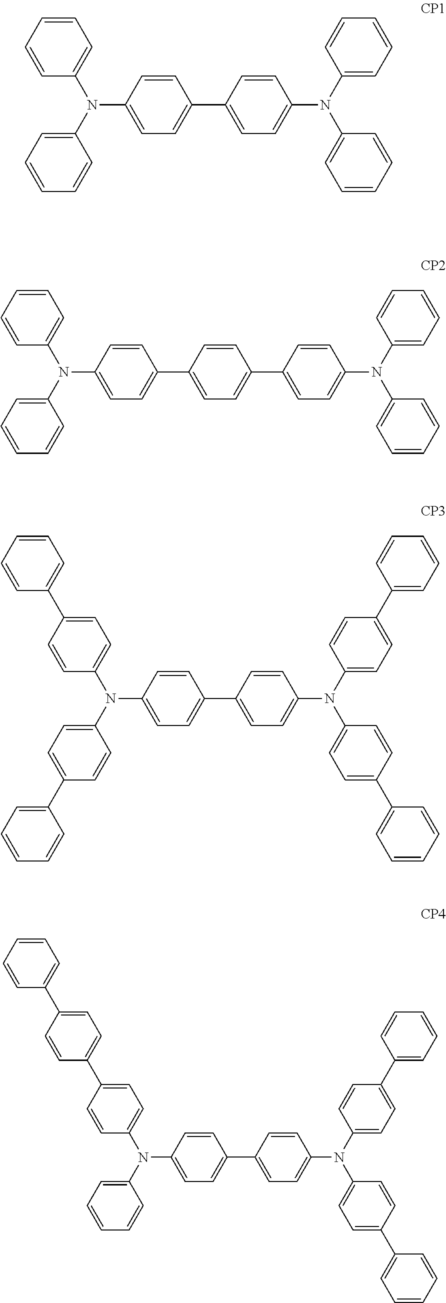 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

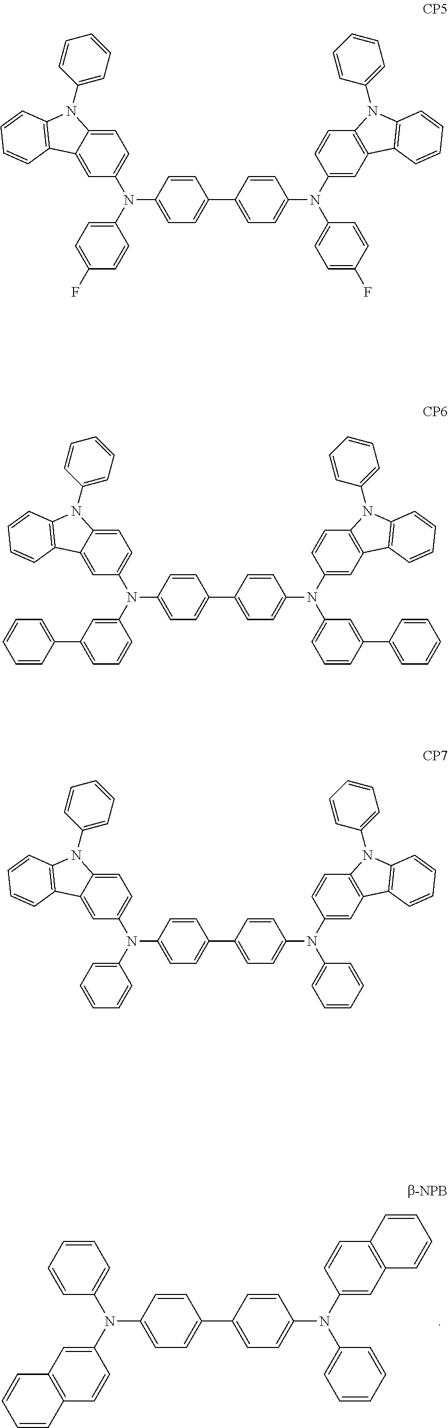 [SMILES: Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various electronic apparatuses. In an embodiment, an electronic apparatus including the light-emitting device may be a light-emitting apparatus, an authentication apparatus, or the like.

The electronic apparatus (e.g., a light-emitting apparatus) may further include, in addition to the light-emitting device, a color filter, a color conversion layer, or color conversion units such as a color filter and a color conversion layer. The color filter and/or the color conversion layer may be arranged in at least one traveling direction of light emitted from the light-emitting device. In an embodiment, the light emitted from the light-emitting device may be blue light or white light. The light-emitting device may be the same as described herein. In an embodiment, the color conversion layer may include quantum dots. The quantum dots may be, for example, the quantum dots as described herein.

The electronic apparatus may include a first substrate. The first substrate may include multiple subpixel areas, the color filter may include multiple color filter areas respectively corresponding to the subpixel areas, and the color conversion layer may include multiple color conversion areas respectively corresponding to the subpixel areas.

A pixel defining film may be arranged between the subpixel areas to define each subpixel area.

The color filter may further include multiple color filter areas and light-shielding patterns arranged between the color filter areas, and the color conversion layer may further include multiple color conversion areas and light-shielding patterns arranged between the color conversion areas.

The color filter areas (or the color conversion areas) may include: a first area emitting first color light; a second area emitting second color light; and/or a third area emitting third color light, wherein the first color light, the second color light, and/or the third color light may have different maximum emission wavelengths. For example, the first color light may be red light, the second color light may be green light, and the third color light may be blue light. In an embodiment, the color filter areas (or the color conversion areas) may include quantum dots. For example, the first area may include red quantum dots, the second area may include green quantum dots, and the third area may not include quantum dots. The quantum dots may be a quantum dot as described herein. The first area, the second area, and/or the third area may each further include a scatterer.

In an embodiment, the light-emitting device may emit first light, the first area may absorb the first light to emit first-1 color light, the second area may absorb the first light to emit second-1 color light, and the third area may absorb the first light to emit third-1 color light. The first-1 color light, the second-1 color light, and the third-1 color light may have different maximum emission wavelengths from one another. For example, the first light may be blue light, the first-1 color light may be red light, the second-1 color light may be green light, and the third-1 color light may be blue light.

The electronic apparatus may further include a thin-film transistor, in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, and the like.

The active layer may include crystalline silicon, amorphous silicon, an organic semiconductor, an oxide semiconductor, and the like.

The electronic apparatus may further include a sealing portion for sealing the light-emitting device. The sealing portion may be arranged between the color filter and/or the color conversion layer and the light-emitting device. The sealing portion may allow light from the light-emitting device to be extracted to the outside, and may simultaneously prevent ambient air and moisture from penetrating into the light-emitting device. The sealing portion may be a sealing substrate including a transparent glass substrate or a plastic substrate. The sealing portion may be a thin-film encapsulation layer including an organic layer and/or an inorganic layer. In case that the sealing portion is a thin-film encapsulation layer, the electronic apparatus may be flexible.

Various functional layers may be additionally arranged on the sealing portion, in addition to the color filter and/or the color conversion layer, according to the use of the electronic apparatus. Examples of the functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (e.g., fingertips, pupils, etc.).

The authentication apparatus may further include, in addition to the light-emitting device as described above, a biometric information collector.

The electronic apparatus may be applied to various displays, light sources, lighting, personal computers (e.g., a mobile personal computer), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (e.g., meters for a vehicle, an aircraft, and a vessel), projectors, and the like.

### [Electronic Equipment]

The light-emitting device may be included in various electronic equipment.

In an embodiment, the electronic equipment including the light-emitting device may be one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard.

The light-emitting device may have excellent luminescence efficiency and long lifespan, and thus, the electronic equipment including the light-emitting device may have characteristics such as high luminance, high resolution, and low power consumption.

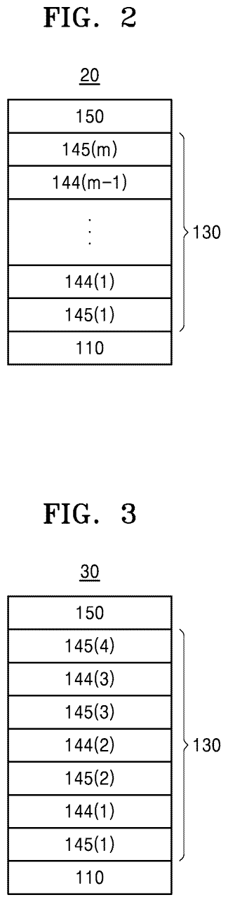

### [Descriptions of FIGS. 2 and 3]

FIGS. 2 and 3 are each a schematic cross-sectional view of a tandem light-emitting device 20 or 30 according to an embodiment. The light-emitting device 20 or 30 may include a first electrode 110, an interlayer 130, and a second electrode 150.

Referring to FIG. 2, the interlayer 130 of the light-emitting device 20 may include m emitting units, for example, first to m^{th} emitting units 145(1), . . . , and 145(m), and m−1 charge generation units, for example, first to m−1^{th} charge generation units 144(1), . . . , and 144(m−1), arranged between adjacent emitting units. m may be an integer of 2 or more. For example, m may be an integer in a range of 2 to 10. For example, m may be an integer in a range of 2 to 6. For example, m may be an integer in a range of 2 to 4.

Among the m emitting units, an emitting unit which is m^{th} closest to the first electrode may be the m^{th} emitting unit 145(m). For example, among the m emitting units, an emitting unit which is closest to the first electrode may be the first emitting unit 145(1), an emitting unit which is farthest from the first electrode (an emitting unit adjacent to the second electrode) may be the m^{th} emitting unit 145(m), and the first emitting unit 145(1) to the m^{th} emitting unit 145(m) may be sequentially arranged. For example, the m−1^{th} charge generation unit 144(m−1) may be arranged between the m−1^{th} emitting unit 145(m−1) and the m^{th} emitting unit 145(m).

In an embodiment, at least one of the m emitting units may emit blue light having a maximum emission wavelength in a range of about 410 nm to about 490 nm. In an embodiment, at least one of the m emitting units may emit green light having a maximum emission wavelength in a range of about 490 nm to about 580 nm.

In an embodiment, each of the m emitting units may include an emission layer, a hole transport region, and an electron transport region. The hole transport region may include at least one of a hole injection layer, a hole transport layer, a buffer layer, an emission auxiliary layer, and an electron blocking layer, and the electron transport region may include at least one of a hole blocking layer, an electron transport layer, and an electron injection layer. The emission layer, the hole transport region, and the electron transport region in each of the m emitting units of the light-emitting device 20 of FIG. 2 may be the same as the emission layer, the hole transport region, and the electron transport region of the light-emitting device 10 of FIG. 1.

In an embodiment, each of the m−1 charge generation units may include a p-type charge generation layer and an n-type charge generation layer.

In an embodiment, the light-emitting device may include a first pixel emitting first light, a second pixel emitting second light, and a third pixel emitting third light, and the hole transport region of the first emitting unit may include a hole injection layer and a hole transport layer. In this regard, the hole mobility of the hole transport layer may be greater than the hole mobility of the hole injection layer, and the light-emitting device may have a CCT, expressed by Equation 1 described above, in a range of 0 to 5.

In an embodiment, the light-emitting device may include a first pixel emitting first light, a second pixel emitting second light, and a third pixel emitting third light, and the hole transport region of each of the second emitting unit to the m^{th} emitting unit may include a hole transport layer. In this regard, the hole mobility of the hole transport layer of each of the second emitting unit to the m^{th} emitting unit may be greater than the hole mobility of the p-type charge generation layer of each of the first charge generation unit to the m−1^{th} charge generation unit, which is adjacent to the hole transport layer, and the light-emitting device may have a CCT, expressed by Equation 1 described above, in a range of 0 to 5.

In an embodiment, the light-emitting device may include a first pixel emitting first light, a second pixel emitting second light, and a third pixel emitting third light, the hole transport region of the first emitting unit may include a hole injection layer and a hole transport layer, and the hole transport region of each of the second emitting unit to the m^{th} emitting unit may include a hole transport layer. In this regard, the hole mobility of the hole transport layer of the first emitting unit may be greater than the hole mobility of the hole injection layer of the first emitting unit, the hole mobility of the hole transport layer of each of the second emitting unit to the m^{th} emitting unit may be greater than the hole mobility of the p-type charge generation layer of each of the first charge generation unit to the m−1^{th} charge generation unit, which is adjacent to the hole transport layer, and the light-emitting device may have a CCT, expressed by Equation 1 described above, in a range of 0 to 5.

The light-emitting device including the m emitting units may include a color conversion unit, such as a color conversion layer and/or a color filter, and the first pixel, the second pixel, and the third pixel may be distinguished by the color conversion unit.

In an embodiment, in case that m is 2, the first electrode, the first emitting unit, the first charge generation unit, and the second emitting unit may be arranged in this stated order. In this regard, the first emitting unit may emit first color light, the second emitting unit may emit second color light, and the maximum emission wavelength of the first color light and the maximum emission wavelength of the second color light may be identical to or different from each other.

In an embodiment, in case that m is 3, the first electrode, the first emitting unit, the first charge generation unit, the second emitting unit, the second charge generation unit, and the third emitting unit may be arranged in this stated order. In this regard, the first emitting unit may emit first color light, the second emitting unit may emit second color light, the third emitting unit may emit third color light, and the maximum emission wavelength of the first color light, the maximum emission wavelength of the second color light, and the maximum emission wavelength of the third color light may be identical to or different from one another.

In an embodiment, in case that m is 4, the first electrode, the first emitting unit, the first charge generation unit, the second emitting unit, the second charge generation unit, the third emitting unit, the third charge generation unit, and the fourth emitting unit may be arranged in this stated order. In this regard, the first emitting unit may emit first color light, the second emitting unit may emit second color light, the third emitting unit may emit third color light, the fourth emitting unit may emit fourth color light, and the maximum emission wavelength of the first color light, the maximum emission wavelength of the second color light, the maximum emission wavelength of the third color light, and the maximum emission wavelength of the fourth color light may be identical to or different from one another.

In an embodiment, the maximum emission wavelength of light emitted from at least one emitting unit among the m emitting units may be different from the maximum emission wavelength of light emitted from at least one emitting unit among the remaining emitting units.

FIG. 3 shows the light-emitting device 30 in an embodiment that m is 4 in the light-emitting device of FIG. 2. Referring to FIG. 3, the light-emitting device 30 may include three charge generation units, for example, first to third charge generation units 144(1), 144(2), and 144(3), between four emitting units, for example, first to fourth emitting units 145(1), 145(2), 145(3), and 145(4).

In an embodiment, the first emitting unit 145(1) may include a first emission layer, the second emitting unit 145(2) may include a second emission layer, the third emitting unit 145(3) may include a third emission layer, the fourth emitting unit 145(4) may include a fourth emission layer, each of the first emission layer, the second emission layer, and the third emission layer may emit blue light, and the fourth emission layer may emit green light.

In an embodiment, each of the first emitting unit 145(1) to the fourth emitting unit 145(4) may include a hole transport region between the first electrode 110 and each of the first emission layer to the fourth emission layer. The hole transport region may be the same as the hole transport region described herein.

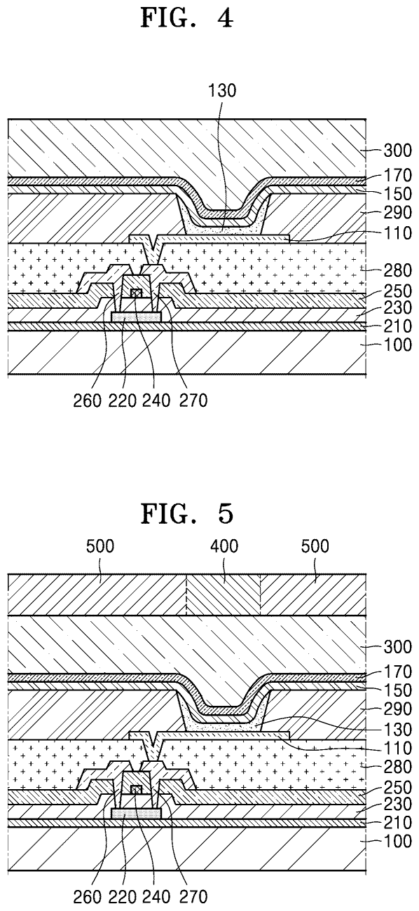

### [Descriptions of FIGS. 4 and 5]

FIG. 4 is a schematic cross-sectional view of a light-emitting apparatus according to an embodiment.

The light-emitting apparatus according to an embodiment may include a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device may include a first electrode 110, an interlayer 130, and a second electrode 150.

The first electrode 110 may be arranged on the passivation layer 280. The passivation layer 280 may not completely cover the drain electrode 270 and may expose a portion of the drain electrode 270. The first electrode 110 may be electrically connected to the exposed portion of the drain electrode 270.

A pixel defining film 290 including an insulating material may be arranged on the first electrode 110. The pixel defining film 290 may expose a region of the first electrode 110, and the interlayer 130 may be formed in the exposed region of the first electrode 110. The pixel defining film 290 may be a polyimide-based organic film or a polyacrylic organic film. Although not shown in FIG. 4, at least some layers of the interlayer 130 may extend beyond the upper portion of the pixel defining film 290 to be arranged in the form of a common layer.

The second electrode 150 may be arranged on the interlayer 130, and a capping layer 170 may be additionally formed on the second electrode 150. The capping layer 170 may be formed to cover the second electrode 150.

The encapsulation portion 300 may be arranged on the capping layer 170. The encapsulation portion 300 may be arranged on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy-based resin (e.g., aliphatic glycidyl ether (AGE), etc.), or any combination thereof; or any combination of the inorganic film and the organic film.

FIG. 5 is a schematic cross-sectional view of a light-emitting apparatus according to another embodiment.

The light-emitting apparatus of FIG. 5 may differ from the light-emitting apparatus of FIG. 4, at least in that a light-shielding pattern 500 and a functional region 400 are additionally arranged on the encapsulation portion 300. The functional region 400 may be a color filter area, a color conversion area, or a color conversion unit such as a combination of the color filter area and the color conversion area. In an embodiment, the light-emitting device included in the light-emitting apparatus of FIG. 5 may be a tandem light-emitting device.

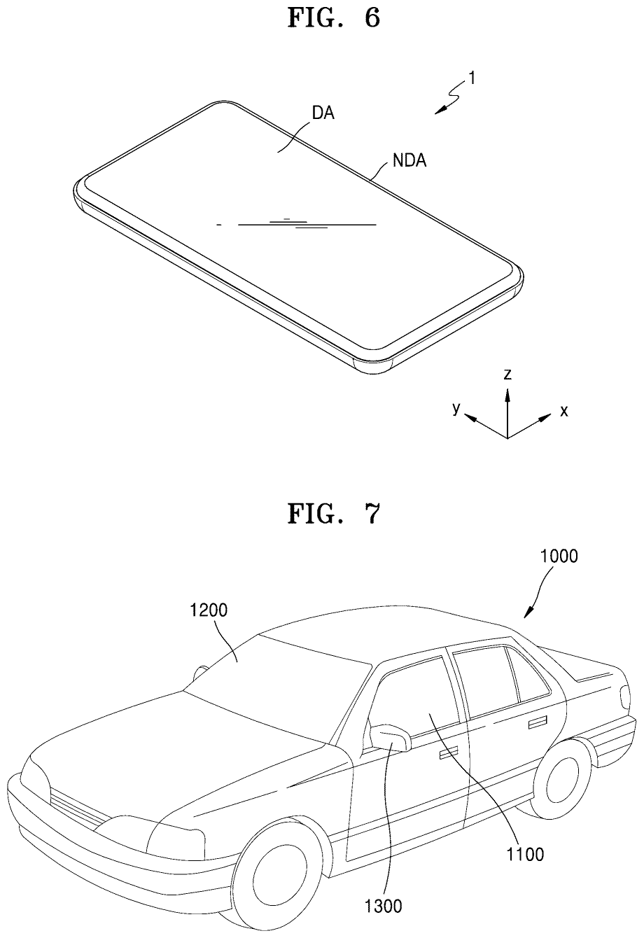

### [Description of FIG. 6]

FIG. 6 is a schematic perspective view of electronic equipment 1 including a light-emitting device according to an embodiment. The electronic equipment 1 may be, as an apparatus that displays a moving image or still image, portable electronic equipment, such as a mobile phone, a smartphone, a tablet personal computer (PC), a mobile communication terminal, an electronic notebook, an electronic book, a portable multimedia player (PMP), a navigation, or a ultra-mobile PC (UMPC), as well as various products, such as a television, a laptop, a monitor, a billboard, or an Internet of things (IoT). The electronic equipment 1 may be such a product above or a part thereof. The electronic equipment 1 may be a wearable device, such as a smart watch, a watch phone, a glasses-type display, or a head mounted display (HMD), or a part of the wearable device. However, embodiments are not limited thereto. For example, the electronic equipment 1 may include a dashboard of a vehicle, a center fascia of a vehicle, a center information display arranged on a dashboard of a vehicle, a room mirror display replacing a side mirror of a vehicle, an entertainment display for the rear seat of a vehicle or a display arranged on the back of the front seat, or a head up display (HUD) installed in the front of a vehicle or projected on a front window glass, a computer generated hologram augmented reality head up display (CGH AR HUD). FIG. 6 illustrates an embodiment that the electronic equipment 1 is a smartphone.

The electronic equipment 1 may include a display area DA and a non-display area NDA outside the display area DA. A display device may implement an image through a two-dimensional array of multiple pixels that are arranged in the display area DA.

The non-display area NDA may be an area that does not display an image, and may surround the display area DA. On the non-display area NDA, a driver for providing electrical signals or power to display devices arranged on the display area DA may be arranged. On the non-display area NDA, a pad, which is an area to which an electronic element or a printed circuit board may be electrically connected, may be arranged.

In the electronic equipment 1, a length in an x-axis direction and a length in a y-axis direction may be different from each other. In an embodiment, as shown in FIG. 6, the length in the x-axis direction may be less than the length in the y-axis direction. In an embodiment, the length in the x-axis direction may be the same as the length in the y-axis direction. In an embodiment, the length in the x-axis direction may be greater than the length in the y-axis direction.

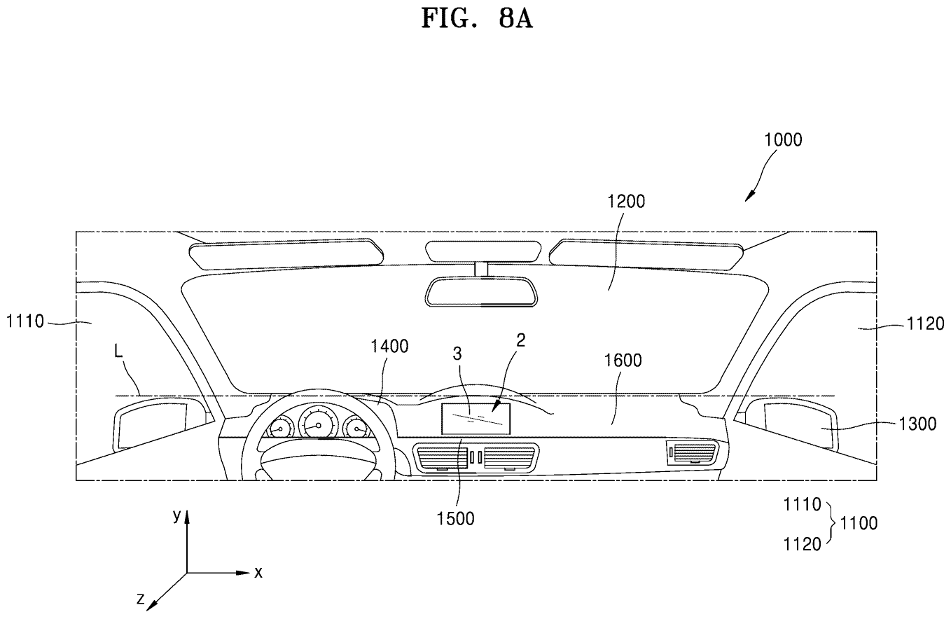

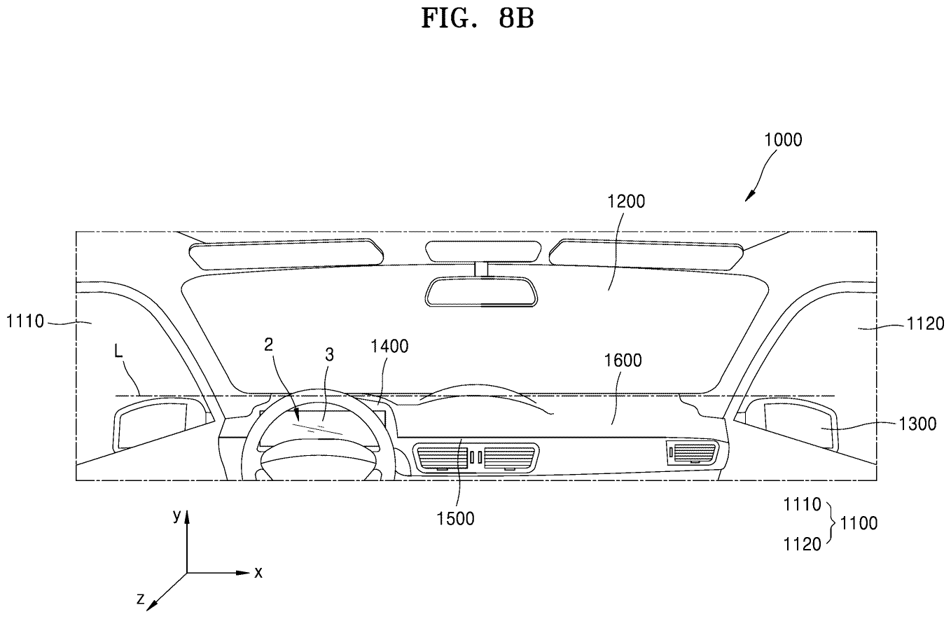

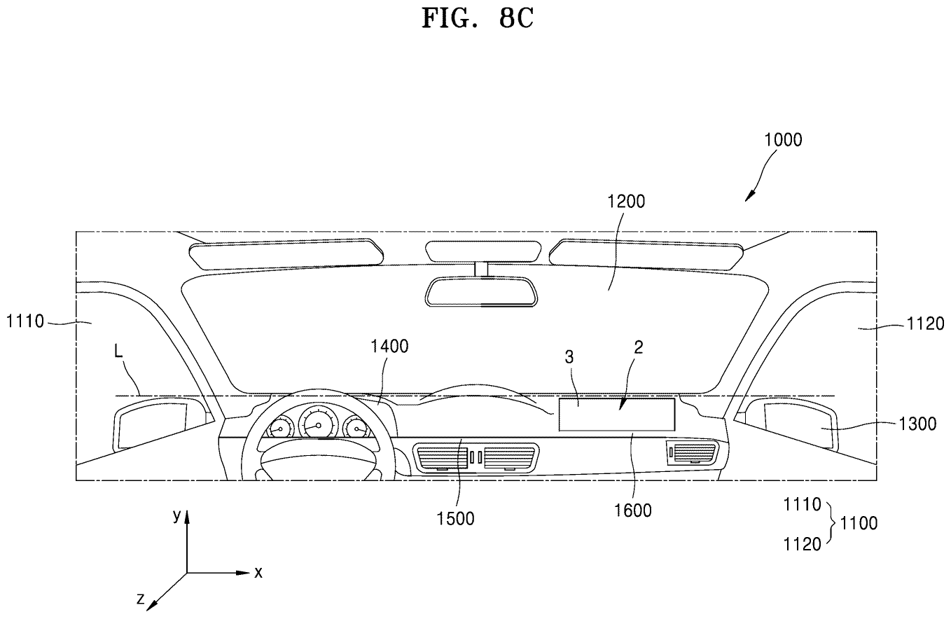

### [Descriptions of FIGS. 7 and 8A to 8C]

FIG. 7 is a perspective view of an exterior of a vehicle 1000 as electronic equipment including a light-emitting device according to an embodiment. FIGS. 8A to 8C are each a schematic diagram of an interior of a vehicle 1000 according to embodiments.

Referring to FIGS. 7, 8A, 8B, and 8C, the vehicle 1000 may refer to various apparatuses for moving a subject to be transported, such as a person, an object, or an animal, from a departure point to a destination point. Examples of the vehicle 1000 may include a vehicle traveling on a road or a track, a vessel moving over a sea or river, an airplane flying in the sky using the action of air, and the like.

The vehicle 1000 may travel on a road or a track. The vehicle 1000 may move in a given direction according to the rotation of at least one wheel. Examples of the vehicle 1000 may include a three-wheeled or four-wheeled vehicle, a construction machine, a two-wheeled vehicle, a prime mover device, a bicycle, and a train running on a track.

The vehicle 1000 may include a vehicle body having an interior and an exterior, and a chassis that is a portion excluding the body in which mechanical apparatuses for driving are installed. The exterior of the vehicle body may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear wheels, left and right wheels, and the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on the side of the vehicle 1000. In an embodiment, the side window glass 1100 may be installed in a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400. The second side window glass 1120 may be arranged adjacent to the passenger seat dashboard 1600.

In an embodiment, the side window glasses 1100 may be spaced apart from each other in an x direction or in a −x direction. In an embodiment, the first side window glass 1110 and the second side window glass 1120 may be spaced apart from each other in the x direction or in the −x direction. For example, an imaginary straight line L connecting the side window glasses 1100 may extend in the x direction or in the −x direction. In an embodiment, the imaginary straight line L connecting the first side window glass 1110 and the second side window glass 1120 to each other may extend in the x direction or in the −x direction.

The front window glass 1200 may be installed on the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In an embodiment, multiple side mirrors 1300 may be provided. One of the side mirrors 1300 may be arranged outside the first side window glass 1110. Another one of the side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator light, a high beam indicator, a warning lamp, a seat belt warning lamp, an odometer, a tachograph, an automatic shift selector indicator lamp, a door open warning lamp, an engine oil warning lamp, and/or a low fuel warning light.

The center fascia 1500 may include a control panel on which multiple buttons for adjusting an audio device, an air conditioning device, and a seat heater are arranged. The center fascia 1500 may be arranged on one side of the cluster 1400.

The passenger seat dashboard 1600 may be spaced apart from the cluster 1400 with the center fascia 1500 arranged therebetween. In an embodiment, the cluster 1400 may be arranged to correspond to a driver seat (not shown), and the passenger seat dashboard 1600 may be arranged to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display device 2 may include a display panel 3, and the display panel 3 may display an image. The display device 2 may be arranged inside the vehicle 1000. In an embodiment, the display device 2 may be arranged between the side window glasses 1100 facing each other. The display device 2 may be arranged in at least one of the cluster 1400, the center fascia 1500, and the passenger seat dashboard 1600.

The display device 2 may include an organic light-emitting display device, an inorganic light-emitting display device, a quantum dot display device, or the like. Hereinafter, as the display device 2 according to an embodiment, an organic light-emitting display device including the light-emitting device according to the disclosure will be described as an example, but various types of display devices as described herein may be used in embodiments.

Referring to FIG. 8A, the display device 2 may be arranged in the center fascia 1500. In an embodiment, the display device 2 may display navigation information. In an embodiment, the display device 2 may display information regarding audio setting, video setting, or vehicle settings.

Referring to FIG. 8B, the display device 2 may be arranged in the cluster 1400. The cluster 1400 may display driving information and the like through the display device 2. For example, the cluster 1400 may digitally implement driving information. The digital cluster 1400 may digitally display vehicle information and driving information as images. For example, a needle and a gauge of a tachometer and various warning lights or icons may be displayed by a digital signal.

Referring to FIG. 8C, the display device 2 may be arranged in the passenger seat dashboard 1600. The display device 2 may be embedded in the passenger seat dashboard 1600 or arranged on the passenger seat dashboard 1600. In an embodiment, the display device 2 arranged on the passenger seat dashboard 1600 may display an image related to information displayed on the cluster 1400 and/or information displayed on the center fascia 1500. In an embodiment, the display device 2 arranged on the passenger seat dashboard 1600 may display information that is different from information displayed on the cluster 1400 and/or information displayed on the center fascia 1500.

### [Manufacturing Method]

The layers constituting the hole transport region, the emission layer, and the layers constituting the electron transport region may be formed in a selected region by using various methods such as vacuum deposition, spin coating, casting, Langmuir-Blodgett (LB) deposition, ink-jet printing, laser-printing, laser-induced thermal imaging, and the like.

In case that the layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only a ring-forming atoms and having 3 to 60 carbon atoms, and the term “C₁-C₆₀ heterocyclic group” as used herein may be a cyclic group that has 1 to 60 carbon atoms and further has, in addition to a carbon atom, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms of a C₁-C₆₀ heterocyclic group may be in a range of 3 to 61.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has 3 to 60 carbon atoms and may not include *—N═*′ as a ring-forming moiety, and the term “π electron-deficient nitrogen-containing C₁-C₆₀ cyclic group” as used herein may be a heterocyclic group that has 1 to 60 carbon atoms and may include *—N═*′ as a ring-forming moiety.

### In an Embodiment,

a C₃-C₆₀ carbocyclic group may be T₁ Group or a group in which two or more T1 Group are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 Group, a group in which two or more T2 Groups are condensed with each other, or a group in which at least oneT2 Group and at least one T1 Group are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T1 Group, a group in which two or more T1 Groups are condensed with each other, a T3 Group, a group in which two or more T3 Groups are condensed with each other, or a group in which at least one T3 Group and at least one T1 Group are condensed with each other (e.g., a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),
a π electron-deficient nitrogen-containing C₁-C₆₀ cyclic group may be T4 Group T4, a group in which two or more T4 Groups are condensed with each other, a group in which at least one T4 Group and at least one T1 Group are condensed with each other, a group in which at least one T4 Group and at least one T3 Group are condensed with each other, or a group in which at least one T4 Group, at least one T1 Group, and at least one T3 Group are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
wherein T1 Group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
T2 Group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
T3 Group may be a furan group, a thiophene group, a 1H-pyrrole group, a silole group, or a borole group, and
T4 Group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may each be a group condensed to any cyclic group, a monovalent group, or a polyvalent group (e.g., a divalent group, a trivalent group, a tetravalent group, etc.) according to the structure of a formula for which the corresponding term is used. In an embodiment, the “benzene group” may be a benzo group, a phenyl group, a phenylene group, or the like, which may be readily understood by those of ordinary skill in the art according to the structure of a formula including the “benzene group.”

Examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein may be a linear or branched aliphatic hydrocarbon monovalent group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁)(wherein A₁₀₁ may be C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group of 1 to 10 carbon atoms, further including, in addition to carbon atoms, at least one heteroatom, as ring-forming atoms, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in the ring thereof and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group of 1 to 10 carbon atoms, further including, in addition to carbon atoms, at least one heteroatom, as ring-forming atoms, and having at least one carbon-carbon double bond in the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. In case that the C₆-C₆₀ aryl group and the C₆-C₆₀ arylene group each include two or more rings, the respective two or more rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom as ring-forming atoms. The term “C₁-C₆₀ heteroarylene group” as used herein may be a divalent group having a heterocyclic aromatic system of 1 to 60 carbon atoms, further including, in addition to carbon atoms, at least one heteroatom as ring-forming atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. In case that the C₁-C₆₀ heteroaryl group and the C₁-C₆₀ heteroarylene group each include two or more rings, the respective two or more rings may be condensed with each other.

The term “monovalent non-aromatic condensed polycyclic group” as used herein may be a monovalent group (e.g., having 8 to 60 carbon atoms) having two or more rings condensed to each other, only carbon atoms as ring-forming atoms, and no aromaticity in its entire molecular structure. Examples of a monovalent non-aromatic condensed polycyclic group may include an indenyl group, a fluorenyl group, a spiro-bifluorenyl group, a benzofluorenyl group, an indenophenanthrenyl group, an indenoanthracenyl group, and the like. The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group (e.g., having 1 to 60 carbon atoms) having two or more rings condensed to each other, further including, in addition to a carbon atom, at least one heteroatom, as ring-forming atoms, and having non-aromaticity in its entire molecular structure. Examples of a monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O(A₁₀₂)(wherein A₁₀₂ may be a C₆-C₆₀ aryl group), and the term “C₆-C₆₀ arylthio group” as used herein may be a group represented by —S(A₁₀₃)(wherein A₁₀₃ may be a C₆-C₆₀ aryl group).

The term “C₇-C₆₀ arylalkyl group” as used herein may be a group represented by -(A₁₀₄)(A₁₀₅)(wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by (A₁₀₆)(A₁₀₇)(wherein A₁₀₆ may be a C₁-C₅₉ alkylene group, and A₁₀₇ may be a C₁-C₅₉ heteroaryl group).

### In the Specification, the Group “R₁₀ₐ” May be:

Deuterium(-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —CI; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein may be any atom other than a carbon atom or a hydrogen atom. Examples of a heteroatom may include O, S, N, P, Si, B, Ge, Se, or any combination thereof.

The term “third-row transition metal” as used herein may be hafnium (Hf), tantalum (Ta), tungsten (W), rhenium (Re), osmium (Os), iridium (Ir), platinum (Pt), gold (Au), or the like.

The term “Ph” as used herein refers to a phenyl group, the term “Me” as used herein refers to a methyl group, the term “Et” as used herein refers to an ethyl group, the terms “tert-Bu” or “Bu^{t}” as used herein each refer a tert-butyl group, and the term “OMe” as used herein refers to a methoxy group.

The term “biphenyl group” as used herein may be a “phenyl group substituted with a phenyl group.” For example, the “biphenyl group” may be a substituted phenyl group having a C₆-C₆₀ aryl group as a substituent.

The term “terphenyl group” as used herein may be a “phenyl group substituted with a biphenyl group.” For example, the “terphenyl group” may be a substituted phenyl group having, as a substituent, a C₆-C₆₀ aryl group substituted with a C₆-C₆₀ aryl group.

The symbols *, *′, and *″ as used herein, unless defined otherwise, each refer to a binding site to a neighboring atom in a corresponding formula or moiety.

In the specification, the terms “x-axis”, “y-axis”, and “z-axis” are not limited to three axes in an orthogonal coordinate system (e.g., a Cartesian coordinate system), and may be interpreted in a broader sense that the aforementioned three axes in an orthogonal coordinate system. For example, the x-axis, y-axis, and z-axis may describe axes that are orthogonal to each other, or may describe axes that are in different directions that are not orthogonal to each other.

Hereinafter, a light-emitting device according to an embodiment will be described in detail with reference to the following the Test Examples and the Examples.

### EXAMPLES

### Measurement of Current Density Versus Voltage

For hole-only devices of Test Examples 1 to 5, current density versus voltage graphs were measured using an SR-3AR IVL measuring instrument (TOPCON) at room temperature (25° C.).

### Test Example 1

A hole-only device including Compound A (HTM-334, available from Merck) was manufactured, and the structure thereof is as follows.

ITO/Ag/ITO (80 Å/800 Å/80 Å)/Compound A (HTM-334):HAT-CN (95:5, volume ratio)(100 Å)/Compound A (HTM-334)(1000 Å)/HAT-CN (100 Å)/Ag:Mg (9:1, volume ratio)(100 Å)

### Test Example 2

A hole-only device including Compound B (LHT-3625, available from Deoksan Neolux) was manufactured, and the structure thereof is as follows.

ITO/Ag/ITO (80 Å/800 Å/80 Å)/Compound A (HTM-334):HAT-CN (95:5, volume ratio)(100 Å)/Compound B (LHT-3625)(1000 Å)/HAT-CN (100 Å)/Ag:Mg (9:1, volume ratio)(100 Å)

### Test Example 3

A hole-only device including Compound D (LHT-7209, available from Deoksan Neolux) was manufactured, and the structure thereof is as follows.

ITO/Ag/ITO (80 Å/800 Å/80 Å)/Compound A (HTM-334):HAT-CN (95:5, volume ratio)(100 Å)/Compound D (LHT-7209)(1000 Å)/HAT-CN (100 Å)/Ag:Mg (9:1, volume ratio)(100 Å)

### Test Example 4

A hole-only device including Compound E (HTM-604, available from Merck) was manufactured, and the structure thereof is as follows.

ITO/Ag/ITO (80 Å/800 Å/80 Å)/Compound A (HTM-334):HAT-CN (95:5, volume ratio)(100 Å)/Compound E (HTM-604)(1000 Å)/HAT-CN (100 Å)/Ag:Mg (9:1, volume ratio)(100 Å)

### Test Example 5

A hole-only device including Compound C (LHT-7257, available from Deoksan Neolux) was manufactured, and the structure thereof is as follows.

ITO/Ag/ITO (80 Å/800 Å/80 Å)/Compound A (HTM-334):HAT-CN (95:5, volume ratio)(100 Å)/Compound C (LHT-7257)(1000 Å)/HAT-CN (100 Å)/Ag:Mg (9:1, volume ratio)(100 Å)

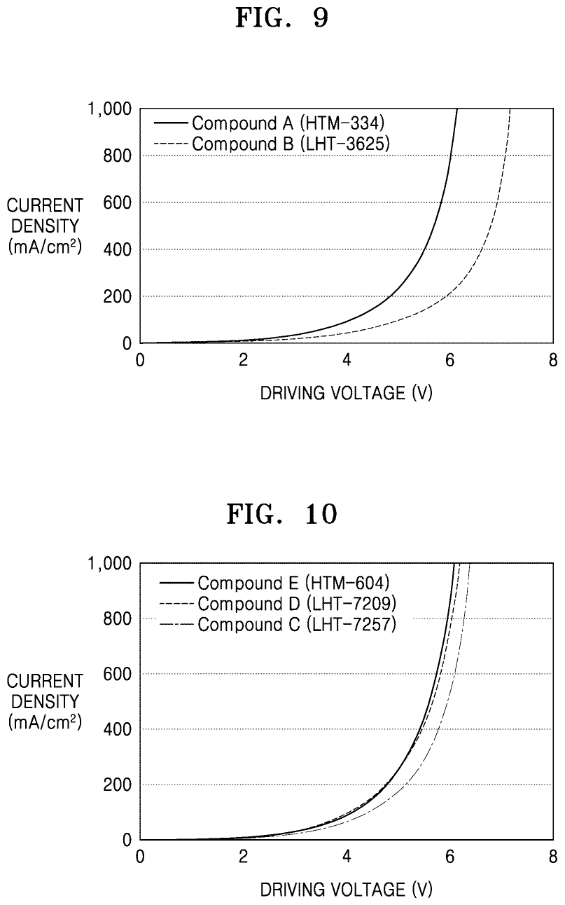

The current density versus voltage graph measured in Test Examples 1 and 2 is shown in FIG. 9. Referring to FIG. 9, the current density of Compound A (HTM-334) is higher than the current density of Compound B (LHT-3625) for the same driving voltage. From this, it may be inferred that Compound A (HTM-334) has higher hole mobility than Compound B (LHT-3625).

The current density versus voltage graph measured in Test Examples 3 to 5 is shown in FIG. 10. Referring to FIG. 10, the current densities of Compound D (LHT-7209) and Compound E (HTM-604) is higher than the current density of Compound C (LHT-7257) for the same driving voltage. From this, it may be inferred that Compound D (LHT-7209) and Compound E (HTM-604) have higher hole mobility than Compound C (LHT-7257).

### DEVICE EXAMPLES

### Example 1

A 15 Ω/cm² ITO/Ag/ITO (80 Å/800 Å/80 Å) glass substrate (available from Corning Inc.) was sonicated using isopropyl alcohol and pure water for 5 minutes each, cleaned by irradiation of ultraviolet rays and exposure of ozone thereto for 15 minutes, and loaded onto a vacuum deposition apparatus. Compound B (LHT-3625) and HATCN were co-deposited at a volume ratio of 9:1 on the ITO/Ag/ITO anode pattern of the glass substrate to form a hole injection layer having a thickness of 50 Å, Compound A (HTM-334) was deposited to form a hole transport layer having a thickness of 200 Å, and TCTA was deposited on the hole transport layer to form an electron blocking layer having a thickness of 50 Å. BH1 and BD were co-deposited at a volume ratio of 98:2 on the electron blocking layer to a thickness of 75 Å, and BH2 and BD were co-deposited at a volume ratio of 98:2 thereon to a thickness of 75 Å, thereby forming an emission layer. T2T was deposited on the emission layer to form a hole blocking layer having a thickness of 50 Å. TPM-TAZ was deposited on the hole blocking layer to form an electron transport layer having a thickness of 250 Å. Yb was deposited on the electron transport layer to form an electron injection layer having a thickness of 10 Å, and Ag and Mg were co-deposited at a weight ratio of 9:1 to form a cathode having a thickness of 100 Å. Compound CPL was deposited on the cathode to form a capping layer having a thickness of 500 Å, thereby completing the manufacture of a light-emitting device.

### Comparative Example 1

A light-emitting device was manufactured in the same manner as in Example 1, except that the hole injection layer was formed by co-depositing TCPC and HATCN at a volume ratio of 9:1 to a thickness of 50 Å, and that the hole transport layer was formed by depositing TCPC to a thickness of 200 Å.

### Comparative Example 2

A light-emitting device was manufactured in the same manner as in Example 1, except that the hole injection layer was formed by co-depositing Compound A (HTM-334) and HATCN at a volume ratio of 9:1 to a thickness of 50 Å, and that the hole transport layer was formed by depositing Compound B (LHT-3625) to a thickness of 200 Å.

### Example 2

A 15 Ω/cm² ITO/Ag/ITO (80 Å/800 Å/80 Å) glass substrate (available from Corning Inc.) was sonicated using isopropyl alcohol and pure water for 5 minutes each, cleaned by irradiation of ultraviolet rays and exposure of ozone thereto for 15 minutes, and loaded onto a vacuum deposition apparatus.

Compound B (LHT-3625) and HATCN were co-deposited at a volume ratio of 9:1 on the ITO/Ag/ITO anode pattern of the glass substrate to form a hole injection layer having a thickness of 50 Å, Compound A (HTM-334) was deposited to form a hole transport layer having a thickness of 200 Å, and TCTA was deposited on the hole transport layer to form an electron blocking layer having a thickness of 50 Å. BH1 and BD were co-deposited at a volume ratio of 98:2 on the electron blocking layer to a thickness of 75 Å, and BH2 and BD were co-deposited at a volume ratio of 98:2 thereon to a thickness of 75 Å, thereby forming an emission layer. T2T was deposited on the emission layer to form a hole blocking layer having a thickness of 50 Å. TPM-TAZ was deposited on the hole blocking layer to form an electron transport layer having a thickness of 250 Å, thereby forming a first emitting unit.

Compound BCP and Li were co-deposited at a volume ratio of 99:1 on the first emitting unit to form an n-type charge generation layer having a thickness of 40 Å, and TCPC and HATCN were co-deposited at a volume ratio of 9:1 on the n-type charge generation layer to form a p-type charge generation layer having a thickness of 70 Å, thereby forming a first charge generation unit.

TAPC was deposited on the first charge generation unit to form a hole transport layer having a thickness of 600 Å, and TCTA was deposited on the hole transport layer to form an electron blocking layer having a thickness of 50 Å. BH1 and BD were co-deposited at a volume ratio of 98:2 on the electron blocking layer to a thickness of 75 Å, and BH2 and BD were co-deposited at a volume ratio of 98:2 thereon to a thickness of 75 Å, thereby forming an emission layer. T2T was deposited on the emission layer to form a hole blocking layer having a thickness of 50 Å. TPM-TAZ was deposited on the hole blocking layer to form an electron transport layer having a thickness of 250 Å, thereby forming a second emitting unit.

Compound BCP and Li were co-deposited at a volume ratio of 99:1 on the second emitting unit to form an n-type charge generation layer having a thickness of 40 Å, and TCPC and HATCN were co-deposited at a volume ratio of 9:1 on the n-type charge generation layer to form a p-type charge generation layer having a thickness of 70 Å, thereby forming a second charge generation unit.

TAPC was deposited on the second charge generation unit to form a hole transport layer having a thickness of 500 Å, and TCTA was deposited on the hole transport layer to form an electron blocking layer having a thickness of 50 Å. BH1 and BD were co-deposited at a volume ratio of 98:2 on the electron blocking layer to a thickness of 75 Å, and BH2 and BD were co-deposited at a volume ratio of 98:2 thereon to a thickness of 75 Å, thereby forming an emission layer. T2T was deposited on the emission layer to form a hole blocking layer having a thickness of 50 Å. TPM-TAZ was deposited on the hole blocking layer to form an electron transport layer having a thickness of 250 Å, thereby forming a third emitting unit.

Compound BCP and Li were co-deposited at a volume ratio of 99:1 on the third emitting unit to form an n-type charge generation layer having a thickness of 40 Å, and TCPC and HATCN were co-deposited at a volume ratio of 9:1 on the n-type charge generation layer to form a p-type charge generation layer having a thickness of 70 Å, thereby forming a third charge generation unit.

TCTA was deposited on the third charge generation unit to form a hole transport layer having a thickness of 300 Å, and GH and GD were co-deposited at a volume ratio of 93:7 on the hole transport layer to form an emission layer having a thickness of 280 Å. GH is a mixed host including GH1 and GH2 at a ratio of 1:1. T2T was deposited on the emission layer to form a hole blocking layer having a thickness of 50 Å. TPM-TAZ and LiQ were co-deposited at a volume ratio of 1:1 on the hole blocking layer to form an electron transport layer having a thickness of 520 Å, thereby forming a fourth emitting unit.

Yb was deposited on the fourth emitting unit to form an electron injection layer having a thickness of 10 Å, and Ag and Mg were co-deposited at a weight ratio of 9:1 to form a cathode having a thickness of 100 Å. Compound CPL was deposited on the cathode to form a capping layer having a thickness of 500 Å. A color conversion layer using quantum dots was formed on the capping layer, and a color filter layer was formed on the color conversion layer, thereby completing the manufacture of a light-emitting device.

### Comparative Example 3

A light-emitting device was manufactured in the same manner as in Example 2, except that the hole injection layer of the first emitting unit was formed by co-depositing TCPC and HATCN at a volume ratio of 9:1 to a thickness of 50 Å, and that the hole transport layer of the first emitting unit was formed by depositing TCPC to a thickness of 200 Å.

### Comparative Example 4

A light-emitting device was manufactured in the same manner as in Example 2, except that the hole injection layer of the first emitting unit was formed by co-depositing Compound A (HTM-334) and HATCN at a volume ratio of 9:1 to a thickness of 50 Å, and that the hole transport layer of the first emitting unit was formed by depositing Compound B (LHT-3625) to a thickness of 200 Å.

### Example 3

A light-emitting device was manufactured in the same manner as in Example 2, except that the hole injection layer of the first emitting unit was formed by co-depositing Compound A (HTM-334) and HATCN at a volume ratio of 9:1 to a thickness of 50 Å, that the hole transport layer of the first emitting unit was formed by depositing Compound A (HTM-334) to a thickness of 200 Å, that Compound C (LHT-7257, Deoksan Neolux) was used instead of TCTC in the p-type charge generation layers of the first charge generation unit, the second charge generation unit, and the third charge generation unit, and that Compound D (LHT-7209, Deoksan Neolux) was used instead of Compound TAPC in the hole transport layers of the second emitting unit, the third emitting unit, and the fourth emitting unit.

### Example 4

A light-emitting device was manufactured in the same manner as in Example 3, except that Compound E (HTM-604, Merck) was used instead of Compound D (LHT-7209, Deoksan Neolux) in the hole transport layers of the second emitting unit, the third emitting unit, and the fourth emitting unit.

### Comparative Example 5

A light-emitting device was manufactured in the same manner as in Example 3, except that Compound C (LHT-7257) was used instead of Compound D (LHT-7209, Deoksan Neolux) in the hole transport layers of the second emitting unit, the third emitting unit, and the fourth emitting unit.

### Comparative Example 6

A light-emitting device was manufactured in the same manner as in Example 3, except that Compound D (LHT-7209, Deoksan Neolux) was used instead of Compound C (LHT-7257, Deoksan Neolux) in the p-type charge generation layers of the first charge generation unit, the second charge generation unit, and the third charge generation unit, and that Compound C (LHT-7257, Deoksan Neolux) was used instead of Compound D (LHT-7209, Deoksan Neolux) in the hole transport layers of the second emitting unit, the third emitting unit, and the fourth emitting unit.

### Comparative Example 7

A light-emitting device was manufactured to have the same configuration as the light-emitting device of Comparative Example 5, except that the device characteristics were evaluated at the same time and using the same equipment as the device of Example 4.

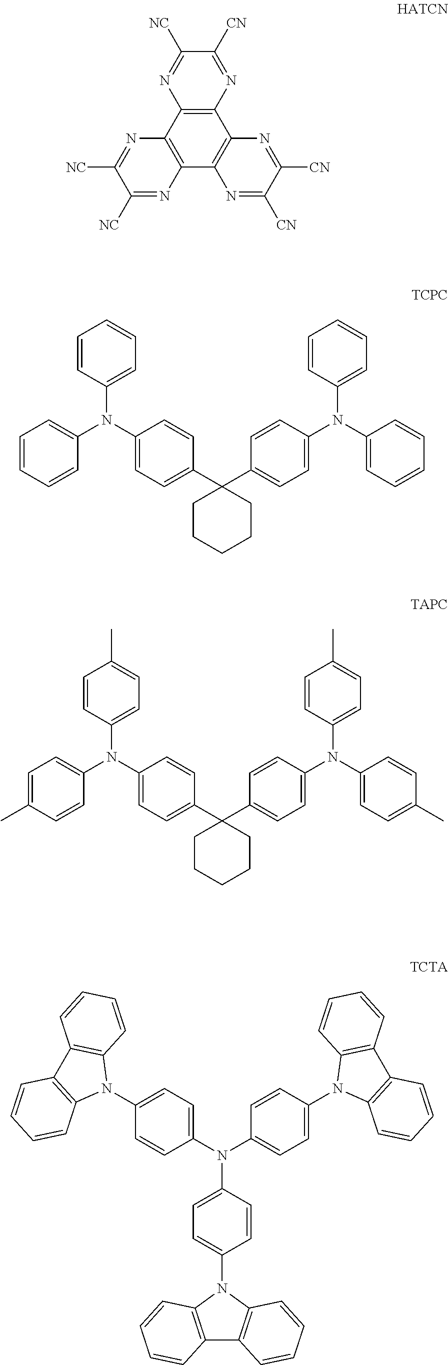

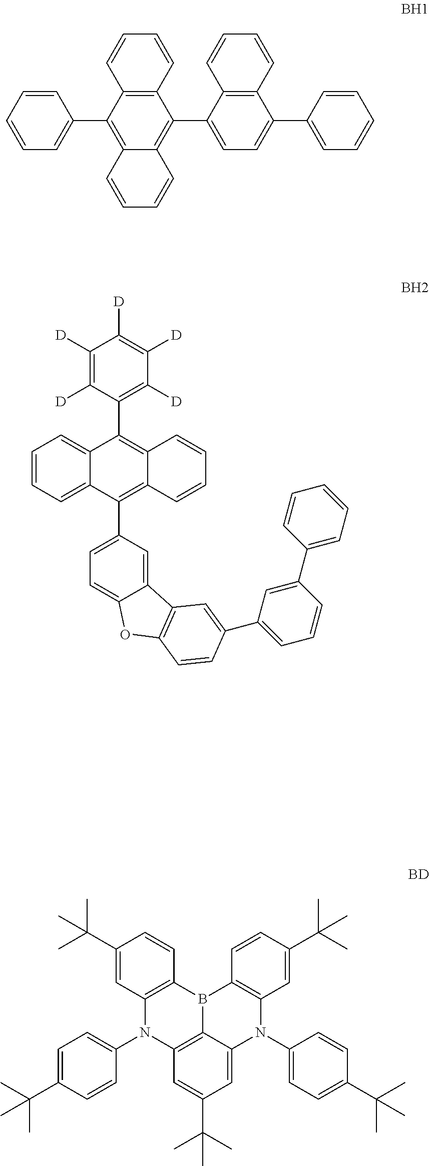

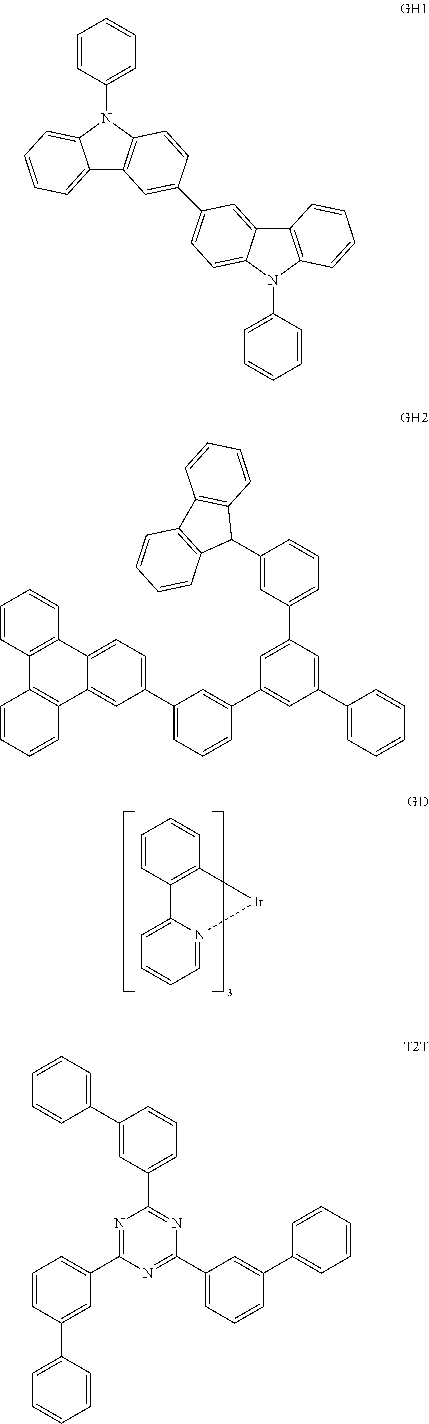

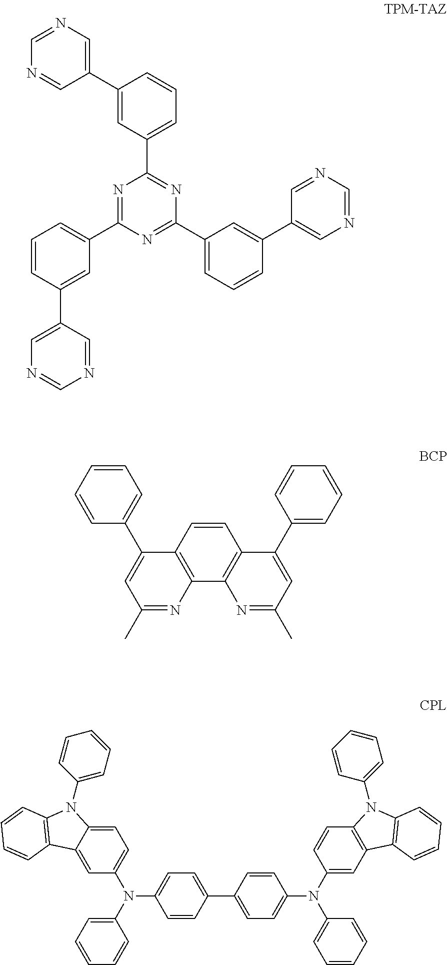 [SMILES: c1cc(-c2cncnc2)cc(-c2nc(-c3cccc(-c4cncnc4)c3)nc(-c3cccc(-c4cncnc4)c3)n2)c1 ; Cc1cc(-c2ccccc2)c2ccc3c(-c4ccccc4)cc(C)nc3c2n1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Measurement of Specific Resistance Between Anodes

Within test patterns of the light-emitting devices of Examples 1 to 4 and Comparative Examples 1 to 7, a voltage was applied between an anode and a cathode of a pixel to drive the pixel, and the current between the anode of the pixel being driven and an anode of another pixel, which was adjacent to the pixel being driven but was not driven itself, was measured. The resistance between the adjacent anodes was obtained from the current-voltage formula, and the resistance was converted to a specific resistance value by dividing the resistance by the area and thickness of each anode to eliminate factors due to the size of pixel. The size of anode in the test patterns was 2 mm×2 mm, and the thickness thereof was 2,000 Å for a single device and 4,000 Å for a tandem device.

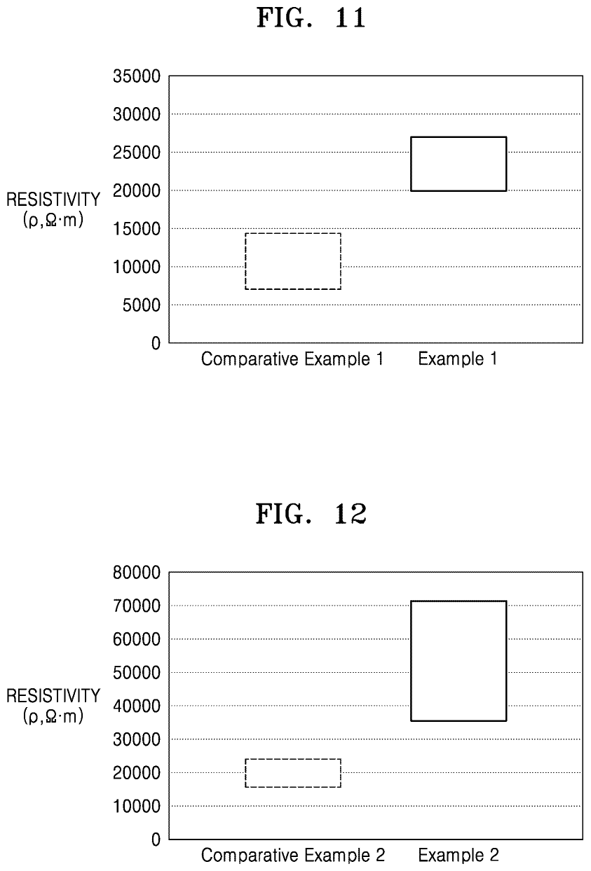

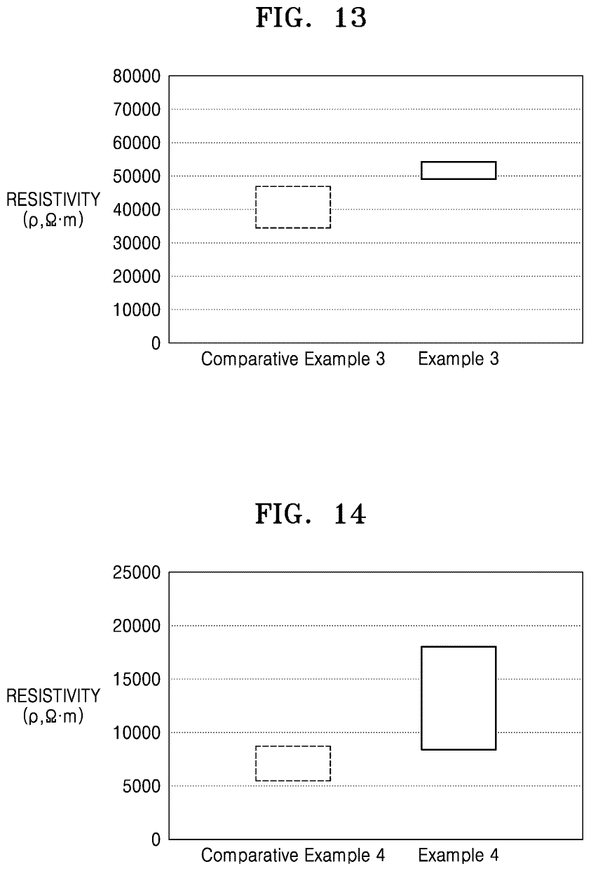

FIGS. 11 to 14 each show ranges of specific resistance converted from the current measured for test patterns of Examples 1 to 4 and Comparative Examples 1 to 7, and Table 2 shows average values of the specific resistances.

Since an anode is separated for each subpixel of a light-emitting device, the current measured between the adjacent anodes is expected to be lateral leakage current generated along the interface between anode and a hole injection layer, which is a common layer on the anode.

Referring to FIGS. 11 to 14 and Table 2, the specific resistances obtained in Examples 1 to 4 were in a range of about 1.25 to about 3 times the corresponding specific resistances obtained in Comparative Examples 1 to 7. From this, it may be seen that the lateral leakage current along the upper surface of anode was reduced in the light-emitting devices of Examples 1 to 4, as compared with the light-emitting devices of Comparative Examples 1 to 7.

### Measurement of Device Characteristics

The driving voltage, current efficiency, and lifespan (LT90) at 4,200 nit of each of the light-emitting devices manufactured in Examples 1 to 4 and Comparative Examples 1 to 7 were measured using Keithley SMU 236 and luminance meter PR650, and the results are shown in Table 2. The lifespan (T90) was measured as the time taken for the luminance to reach 90% of the initial luminance at 35° C. or 40° C.

Referring to Table 2, the light-emitting devices of Examples 1 to 4, to which the disclosure is applied, has driving voltage, current efficiency, and lifespan characteristics that are comparable to or superior to those of the structurally corresponding light-emitting devices of Comparative Examples 1 to 7. The light-emitting device of Example 1 corresponds to the light-emitting devices of Comparative Examples 1 and 2, the light-emitting device of Example 2 corresponds to the light-emitting devices of Comparative Examples 3 and 4, the light-emitting device of Example 3 corresponds to the light-emitting devices of Comparative Examples 5 and 6, and the light-emitting device of Example 4 corresponds to the light-emitting device of Comparative Example 7.

TABLE 2

| | Average | | | |
|---|---|---|---|---|
| | specific | | | |
| | resistance | Driving | Efficiency | |
| | (Ω · m) | voltage (V) | (cd/A) | Lifespan (T90) |
| Example 1 | 23745 | 4.1 | 9.9 | 88 (40° C.) |
| Comparative | 7799 | 4.0 | 9.5 | 85 (40° C.) |
| Example 1 | | | | |
| Comparative | 7195 | 4.2 | 8.4 | 70 (40° C.) |
| Example 2 | | | | |
| Example 2 | 48508 | 16.2 | 22.8 | 280 (40° C.) |
| Comparative | 22956 | 16.1 | 22.9 | 280 (40° C.) |
| Example 3 | | | | |
| Comparative | 19412 | 16.4 | 19.8 | 200 (40° C.) |
| Example 4 | | | | |
| Example 3 | 5114 | 15.5 | 19.8 | 116 (35° C.) |
| Comparative | 4003 | 15.6 | 19.42 | 112 (35° C.) |
| Example 5 | | | | |
| Comparative | 3352 | 15.9 | 17.5 | 104 (35° C.) |
| Example 6 | | | | |
| Example 4 | 10983 | 15.7 | 20.2 | 105 (35° C.) |
| Comparative | 8123 | 15.6 | 19.6 | 99 (35° C.) |
| Example 7 | | | | |

### Measurement of CCT

The CCT of each of the light-emitting devices of Example 2 and Comparative Example 2 was measured. To this end, first, white light was emitted to correspond to a fourth gradation among 256 black and white gradations or gray scales, and the luminance of the white light of the fourth gradation was measured. The luminance of the fourth gradation may be determined by the equation (maximum luminance)×(4/255)\hat{ }2.2. The luminance of the fourth gradation of the white light measured in the light-emitting devices of Example 2 and Comparative Example 2 was 0.4 nit.

The theoretical luminance of each of red light, green light, and blue light required to generate white light of the fourth gradation was calculated. The light-emitting device of Example 2 was driven to have current corresponding to the theoretical luminance values of red light, green light, and blue light for emitting white light of the fourth gradation, and the luminance of the device emitting only red light, green light, or blue light was measured. The percentages (%) of the measured luminance values relative to the theoretical luminance values of red light, green light, and blue light are shown in Table 3. The pixel resolutions in the light-emitting devices of Example 2 and Comparative Example 2 were 140 PPI.

TABLE 3

| Light-emitting | Luminance percentage (%) (found/calcd.) | | | |
|---|---|---|---|---|
| device | Red | Green | Blue | CCT (%) |
| Example 2 | 95 | 100 | 92 | 1.60 |
| Comparative | 94 | 95 | 91 | 5.07 |
| Example 2 | | | | |

In case that the calculated and found luminance values for each color are the same, for example, in case that the luminance percentage is 100, the CCT becomes 0, and the smaller the luminance percentage, the greater the CCT.

Referring to Table 3, the CCT of the light-emitting device of Example 2 is 1.6, which is a value corresponding to about 30% of the CCT of 5.07 of the light-emitting device of Comparative Example 2. The decrease in the CCT value of the light-emitting device of Example 2 is believed to be due to the strengthening of the vertical component current from the anode to the cathode and the decrease in the lateral leakage current around the anode and the hole injection layer.

According to embodiments, by setting hole mobility of a hole transport layer to be higher than hole mobility of a hole injection layer and setting a HOMO level of the hole transport layer to be lower than a HOMO level of the hole injection layer, a light-emitting device having reduced lateral leakage current may be provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light-emitting device comprising a plurality of subpixels, wherein
the plurality of subpixels comprise a first pixel emitting first light, a second pixel emitting second light, and a third pixel emitting third light,
the first light, the second light, and the third light have different maximum emission wavelengths from each other,
each of the plurality of subpixels comprises:
a first electrode;
a second electrode facing the first electrode; and
an interlayer between the first electrode and the second electrode,
the interlayer comprises:
an emission layer;
a hole injection layer arranged between the first electrode and the emission layer; and
a hole transport layer arranged between the hole injection layer and the emission layer,
hole mobility of the hole transport layer is greater than hole mobility of the hole injection layer,
highest occupied molecular orbital (HOMO) energy of the hole transport layer is less than or equal to HOMO energy of the hole injection layer, and
the HOMO energy is measured by cyclic voltammetry and expressed as a negative number.

2. The light-emitting device of claim 1, wherein a difference between the HOMO energy of the hole transport layer and the HOMO energy of the hole injection layer is in a range of about 0 eV to about 0.3 eV.

3. The light-emitting device of claim 1, wherein a current density of a hole-only device comprising the hole transport layer and not comprising the hole injection layer is lower than a current density of a hole-only device comprising the hole injection layer and not comprising the hole transport layer at a same driving voltage.

4. The light-emitting device of claim 1, wherein the first light is red light, the second light is green light, and the third light is blue light.

5. The light-emitting device of claim 1, wherein the hole injection layer further comprises a p-dopant.

6. The light-emitting device of claim 1, wherein the emission layer is separated for each of the plurality of subpixels.

7. The light-emitting device of claim 1, wherein the interlayer further comprises:
m emitting units that are stacked; and
m−1 charge generation units each arranged between adjacent ones of the m emitting units,
m is an integer of 2 or more,
a first emitting unit to an m^{th} emitting unit are sequentially stacked from a side of the first electrode,
a first charge generation unit to an m−1th charge generation unit are sequentially stacked from the side of the first electrode,
the first emitting unit comprises the emission layer, the hole injection layer, and the hole transport layer,
each of the first charge generation unit to the m−1^{th} charge generation unit comprises a p-type charge generation layer and an n-type charge generation layer, and
the light-emitting device further comprises a color conversion unit on the second electrode.

8. The light-emitting device of claim 7, wherein
a second emitting unit to the m^{th} emitting unit comprise a second hole transport layer to an m^{th} hole transport layer, respectively,
the p-type charge generation layers of the first charge generation unit to the m−1^{th} charge generation unit are in direct contact with the second hole transport layer to the m^{th} hole transport layer, respectively,
hole mobility of each of the second hole transport layer to the m^{th} hole transport layer is greater than hole mobility of each of the p-type charge generation layers, and
HOMO energy of each of the second hole transport layer to the m^{th} hole transport layer is less than or equal to HOMO energy of each of the p-type charge generation layers.

9. A light-emitting device comprising a plurality of subpixels, wherein
the plurality of subpixels comprise a first pixel emitting first light, a second pixel emitting second light, and a third pixel emitting third light,
the first light, the second light, and the third light have different maximum emission wavelengths from each other,
each of the plurality of subpixels comprises:
a first electrode;
a second electrode facing the first electrode; and
an interlayer between the first electrode and the second electrode,
the interlayer comprises:
an emission layer;
a hole injection layer arranged between the first electrode and the emission layer; and
a hole transport layer arranged between the hole injection layer and the emission layer,
hole mobility of the hole transport layer is greater than hole mobility of the hole injection layer; and
a color crosstalk (CCT) of the light-emitting device is in a range of 0 to 5, the CCT being calculated by Equation 1:
$$CCT ( \% ) = \frac{{Lum}_{1 + 2 + 3} - ( {Lum}_{1} + {Lum}_{2} + {Lum}_{3} )}{{Lum}_{1 + 2 + 3}} \times 100 \qquad [ Equation 1 ]$$
wherein, in Equation 1,
Lum₁₊₂₊₃ is a luminance of white light of a specific gradation in case that all of the first pixel, the second pixel, and the third pixel emit light so that the light-emitting device emits the white light of the specific gradation, wherein the first pixel emits the first light having a first luminance under a first driving condition, the second pixel emits the second light having a second luminance under a second driving condition, and the third pixel emits the third light having a third luminance under a third driving condition,
Lum₁ is a luminance of the first light emitted by the light-emitting device in case that the second pixel and the third pixel do not emit light and the first pixel emits light under the first driving condition,
Lum₂ is a luminance of the second light emitted by the light-emitting device in case that the first pixel and the third pixel do not emit light and the second pixel emits light under the second driving condition, and
Lum₃ is a luminance of the third light emitted by the light-emitting device in case that the first pixel and the second pixel do not emit light and the third pixel emits light under the third driving condition.

10. The light-emitting device of claim 9, wherein the specific gradation is one of a first gradation level to a tenth gradation level among 256 gradation levels.

11. The light-emitting device of claim 9, wherein the white light has a luminance in a range of about 0.2 nit to about 0.6 nit at the specific gradation.

12. The light-emitting device of claim 9, wherein the light-emitting device has a resolution in a range of about 100 pixels per inch (PPI) to about 1,000 PPI.

13. The light-emitting device of claim 9, wherein
highest occupied molecular orbital (HOMO) energy of the hole transport layer is less than or equal to HOMO energy of the hole injection layer, and
the HOMO energy is measured by cyclic voltammetry and expressed as a negative number.

14. A light-emitting device comprising a plurality of subpixels, wherein
the plurality of subpixels comprise a first pixel emitting first light, a second pixel emitting second light, and a third pixel emitting third pixel,
the first light, the second light, and the third light have different maximum emission wavelengths from each other,
each of the plurality of subpixels comprises:
a first electrode;
a second electrode facing the first electrode;
an interlayer between the first electrode and the second electrode; and
a color conversion unit on the second electrode,
the interlayer comprises:
m emitting units that are stacked; and
m−1 charge generation units each arranged between adjacent ones of the m emitting units,
m is an integer of 2 or more,
a first emitting unit to an m^{th} emitting unit are sequentially stacked from a side of the first electrode,
a first charge generation unit to an m−1^{th} charge generation unit are sequentially stacked from the side of the first electrode,
the first emitting unit to the m^{th} emitting unit comprise a first hole transport layer to an m^{th} hole transport layer, respectively,
each of the first charge generation unit to the m−1^{th} charge generation unit comprises a p-type charge generation layer and an n-type charge generation layer,
the p-type charge generation layers of the first charge generation unit to the m−1^{th} charge generation unit are in direct contact with the second hole transport layer to the m^{th} hole transport layer, respectively,
hole mobility of each of the second hole transport layer to the m^{th} hole transport layer is greater than hole mobility of each of the p-type charge generation layers, and
highest occupied molecular orbital (HOMO) energy of each of the second hole transport layer to the m^{th} hole transport layer is less than or equal to HOMO energy of each of the p-type charge generation layers.

15. The light-emitting device of claim 14, wherein
a color crosstalk (CCT) of the light-emitting device is in a range of 0 to 5, the CCT being calculated by Equation 1:
$$CCT ( \% ) = \frac{{Lum}_{1 + 2 + 3} - ( {Lum}_{1} + {Lum}_{2} + {Lum}_{3} )}{{Lum}_{1 + 2 + 3}} \times 100 \qquad [ Equation 1 ]$$
wherein, in Equation 1,
Lum₁₊₂₊₃ is a luminance of white light of a specific gradation in case that all of the first pixel, the second pixel, and the third pixel emit light so that the light-emitting device emits the white light of the specific gradation, wherein the first pixel emits the first light having a first luminance under a first driving condition, the second pixel emits the second light having a second luminance under a second driving condition, and the third pixel emits the third light having a third luminance under a third driving condition,
Lum₁ is a luminance of the first light emitted by the light-emitting device in case that the second pixel and the third pixel do not emit light and the first pixel emits light under the first driving condition,
Lum₂ is a luminance of the second light emitted by the light-emitting device in case that the first pixel and the third pixel do not emit light and the second pixel emits light under the second driving condition, and
Lum₃ is a luminance of the third light emitted by the light-emitting device in case that the first pixel and the second pixel do not emit light and the third pixel emits light under the third driving condition.

16. The light-emitting device of claim 14, wherein at least one of the m emitting units emits light having a maximum emission wavelength in a range of about 410 nm to about 490 nm.

17. The light-emitting device of claim 14, wherein at least one of the m emitting units emits light having a maximum emission wavelength in a range of about 490 nm to about 580 nm.

18. The light-emitting device of claim 14, wherein
m is 4,
three of the m emitting units emit light having a maximum emission wavelength in a range of about 410 nm to about 490 nm, and
one of the m emitting units emits light having a maximum emission wavelength in a range of about 490 nm to about 580 nm.

19. An electronic apparatus comprising the light-emitting device of claim 1 and a thin-film transistor, wherein
the thin-film transistor comprises a source electrode and a drain electrode, and
the first electrode of the light-emitting device is electrically connected to at least one of the source electrode and the drain electrode of the thin-film transistor.

20. Electronic equipment comprising the light-emitting device of claim 1, wherein the electronic equipment is one of a flat panel display, a curved display, a computer monitor, a medical monitor, a television, a billboard, an indoor light, an outdoor light, a light for signal, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, and a signboard.
